(19) United States
(12) Patent Application Publication
(10) Pub. No.: US 2026/0182034 A1
(43) Pub. Date: Jun. 25, 2026

(54) Display Substrate, Manufacturing Method Therefor, and Display Apparatus

(71) Applicants: Chengdu BOE Optoelectronics Technology Co., Ltd., Chengdu, Sichuan (CN); BOE Technology Group Co., Ltd., Beijing (CN)

(72) Inventors: Hongbo MA, Beijing (CN); Tiaomei ZHANG, Beijing (CN)

(21) Appl. No.: 18/713,187

(22) PCT Filed: Apr. 18, 2023
(86) PCT No.: PCT/CN2023/089067

§ 371 Date: May 24, 2024

(51) Int. Cl. H10D 86/60

(52) U.S. Cl. CPC H10D 86/60

(57) ABSTRACT

A display substrate includes a base substrate and a drive circuit layer provided on the base substrate. The drive circuit layer at least includes multiple circuit units, and at least one circuit unit includes a pixel circuit at least including a first transistor, a second transistor, a third transistor, a fourth transistor, and a first capacitor. The first transistor has a gate electrode electrically connected to a first scan signal line and a first electrode electrically connected to a first initial signal line The second transistor has a gate electrode electrically connected to a second scan signal line The first initial signal line the first scan signal line and the second scan signal line extend in at least partially a same direction and are at a same side of the first transistor, the first initial signal line is between the first scan signal line and the second scan signal line.

### CROSS-REFERENCE TO RELATED APPLICATIONS

The present application is a U.S. National Phase Entry of International Application PCT/CN2023/089067 having an international filing date of Apr. 18, 2023, and entitled “Display Substrate, Manufacturing Method Therefor, and Display Apparatus”, contents of which should be construed as being incorporated herein by reference.

### TECHNICAL FIELD

The present disclosure relates to, but is not limited to, display technologies, and particularly to a display substrate, a method for manufacturing the display substrate, and a display apparatus.

### BACKGROUND

Organic Light Emitting Diodes (OLED's) and Quantum dot Light Emitting Diodes (QLED's) are active light emitting display devices and have advantages of self-illumination, wide viewing angle, high contrast ratio, low power consumption, very high reaction speed, lightness and thinness, bendability, and low cost, etc. With continuous development of display technologies, a flexible display apparatus (Flexible Display) with an OLED or a QLED as a light emitting device and using a Thin Film Transistor (TFT) for performing signal controlling has become a mainstream product in the current display field.

### SUMMARY

The following is a summary of subject matter described herein in detail. This summary is not intended to limit the protection scope of claims.

Embodiments of the present disclosure provide a display substrate, a method for manufacturing the display substrate, and a display apparatus.

In one aspect, an embodiments of the present disclosure provides a display substrate, including: a base substrate and a drive circuit layer provided on the base substrate, the drive circuit layer at least including a plurality of circuit units, at least one circuit unit including a pixel circuit; the pixel circuit at least includes a first transistor, a second transistor, a third transistor, a fourth transistor and a first capacitor. A gate electrode of the first transistor is electrically connected to a first scan signal line, a first electrode of the first transistor is electrically connected to a first initial signal line, and a second electrode of the first transistor is electrically connected to a gate electrode of the third transistor; a gate electrode of the second transistor is electrically connected to a second scan signal line, a first electrode of the second transistor is electrically connected to the gate electrode of the third transistor, and a second electrode of the second transistor is electrically connected to a second electrode of the third transistor. A gate electrode of the fourth transistor is electrically connected to a third scan signal line, a first electrode of the fourth transistor is electrically connected to a data signal line, and a second electrode of the fourth transistor is electrically connected to a second end of the first capacitor; a first end of the first capacitor is electrically connected to the gate electrode of the third transistor. The first initial signal line, the first scan signal line, and the second scan signal line extend in at least partially a same direction and are located at a same side of the first transistor, and the first initial signal line is located between the first scan signal line and the second scan signal line.

In some exemplary implementation modes, the first initial signal line, the first scan signal line and the second scan signal line are disposed in a same layer.

In some exemplary implementation modes, an active layer of the first transistor includes a first region, a second region, and a channel region located between the first region and the second region, the first region of the active layer of the first transistor is connected to the first initial signal line. The drive circuit layer further includes: at least one first power supply line; an orthographic projection of the at least one first power supply line on the base substrate covers an orthographic projection of the first region of the active layer of the first transistor on the base substrate.

In some exemplary implementation modes, the pixel circuit further includes a second capacitor; the second capacitor at least includes a second plate as a second end of the second capacitor and a fourth plate as a first end of the second capacitor, an orthographic projection of the second plate on the base substrate overlaps at least partially with an orthographic projection of the fourth plate on the base substrate. The first capacitor at least includes a first plate as the first end of the first capacitor and a third plate as a second end of the first capacitor, an orthographic projection of the first plate on the base substrate overlaps at least partially with an orthographic projection of the third plate on the base substrate. The second capacitor at least includes a second plate and a fourth plate, an orthographic projection of the second plate on the base substrate overlaps at least partially with an orthographic projection of the fourth plate on the base substrate. The fourth plate is connected to a first power supply line, the second plate is connected to the third plate, and the first plate is used as the gate electrode of the third transistor.

In some exemplary implementation modes, the first plate and the second plate are disposed in a same layer, and the third plate and the fourth plate are disposed in a same layer.

In some exemplary implementation modes, the third plate is provided with a second plate connection line extending towards the fourth plate, and the fourth plate is provided with a second groove recessed in a direction away from the third plate; the second plate connection line is provided in the second groove, and an end portion of the second plate connection line away from the third plate is connected to the second plate through a via and a connection electrode.

In some exemplary implementation modes, the drive circuit layer further includes at least one first power supply connection line extending in a first direction, at least one first power supply line extending in a second direction, the first direction intersects the second direction; the at least one first power supply line is connected to the at least one first power supply connection line to form a mesh structure for transmitting a first power supply signal.

In some exemplary implementation modes, the drive circuit layer further includes at least one second power supply connection line extending in the first direction, at least one second power supply line extending in the second direction, the first direction intersects the second direction; the at least one second power supply line is connected to the at least one second power supply connection line to form a mesh structure for transmitting a second power supply signal; a second power supply connection line is located at a side of a first power supply connection line away from the second capacitor.

In some exemplary implementation modes, the at least one first power supply connection line and the at least one second power supply connection line are disposed in a same layer, the at least one first power supply line and the at least one second power supply line are disposed in a same layer, and the at least one first power supply line is located at a side of the at least one first power supply connection line away from the base substrate.

In some exemplary implementation modes, the first capacitor and the second capacitor are located at a same side of the first transistor and the second transistor, the second capacitor is located at a side of the first capacitor away from the first transistor and the second transistor, and an orthographic projection of the third transistor on the base substrate overlaps at least partially with an orthographic projection of the first capacitor on the base substrate.

In some exemplary implementation modes, fourth plates of second capacitors of pixel circuits of circuit units adjacent in a first direction are interconnected to form an integral structure.

In some exemplary implementation modes, the at least one circuit unit further includes a first shielding electrode, an orthographic projection of the first shielding electrode on the base substrate overlaps at least partially with an orthographic projection of a first active layer between two gate electrodes of the first transistor in the present circuit unit on the base substrate, and also overlaps at least partially with an orthographic projection of a second active layer between two gate electrodes of a second transistor in an adjacent circuit unit on the base substrate.

In some exemplary implementation modes, the first shielding electrode includes a first shielding end and a second shielding end; an orthographic projection of the first shielding end on the base substrate overlaps at least partially with the orthographic projection of the first active layer between the two gate electrodes of the first transistor in the present circuit unit on the base substrate, the first shielding end is electrically connected to a first power supply line. An orthographic projection of the second shielding end on the base substrate overlaps at least partially with the orthographic projection of the second active layer between the two gate electrodes of the second transistor in the adjacent circuit unit on the base substrate, and the second shielding end is electrically connected to the first power supply line.

In some exemplary implementation modes, the first shielding electrode and the fourth plate of the second capacitor are interconnected to form an integral structure.

In some exemplary implementation modes, the pixel circuit further includes a fifth transistor, a gate electrode of the fifth transistor is electrically connected to a first light emitting signal line, a first electrode of the fifth transistor is electrically connected to a first power supply line, and a second electrode of the fifth transistor is electrically connected to a first electrode of the third transistor; the first light emitting signal line is located at a side of the second scan signal line away from the first initial signal line.

In some exemplary implementation modes, a film layer where the first light emitting signal line is located is located on a side of a film layer where the first initial signal line is located close to the base substrate; or, the first light emitting signal line and the first initial signal line are disposed in a same layer.

In some exemplary implementation modes, the pixel circuit further includes a sixth transistor, a gate electrode of the sixth transistor is electrically connected to a second light emitting signal line, a first electrode of the sixth transistor is electrically connected to the second electrode of the third transistor, and a second electrode of the sixth transistor is electrically connected to a light emitting device. The second light emitting signal line is located at a side of the first light emitting signal line away from the first initial signal line. The second light emitting signal line and the first light emitting signal line are disposed in a same layer.

In some exemplary implementation modes, the pixel circuit further includes a ninth transistor. A gate electrode of the ninth transistor is electrically connected to a fifth scan signal line, a first electrode of the ninth transistor is electrically connected to a first reference signal line, and a second electrode of the ninth transistor is electrically connected to the second plate of the second capacitor and the third plate of the first capacitor; the fifth scan signal line and the second scan signal line output a same scan signal. The fourth transistor and the ninth transistor are located at a side of the second capacitor away from the first capacitor. An active layer of the fourth transistor and an active layer of the ninth transistor are interconnected to form an integral structure.

In some exemplary implementation modes, active layers of at least two ninth transistors adjacent in a first direction are connected to each other by a first active connection line to form an integral structure.

In some exemplary implementation modes, the pixel circuit further includes a seventh transistor and an eighth transistor; a gate electrode of the seventh transistor is electrically connected to a fourth scan signal line, a first electrode of the seventh transistor is electrically connected to a second initial signal line, and a second electrode of the seventh transistor is electrically connected to a light emitting device. A gate electrode of the eighth transistor is electrically connected to the fourth scan signal line, a first electrode of the eighth transistor is electrically connected to a second reference signal line, and a second electrode of the eighth transistor is electrically connected to a first electrode of the third transistor.

In some exemplary implementation modes, in a direction perpendicular to the display substrate, the drive circuit layer includes a semiconductor layer, a first conductive layer, a second conductive layer, a third conductive layer, and a fourth conductive layer sequentially disposed on the base substrate. Active layers of the first transistor, the second transistor, and the third transistor are located in the semiconductor layer. Gate electrodes of the first transistor, the second transistor, and the third transistor, the first plate, and the second plate are located in the first conductive layer. The third plate and the fourth plate are located in the second conductive layer. The first initial signal line, the first scan signal line, and the second scan signal line are located in the third conductive layer.

In another aspect, an embodiment of the present disclosure provides a display apparatus, which includes the aforementioned display substrate.

In another aspect, an embodiment of the present disclosure provides a method for manufacturing a display substrate, including: forming a drive circuit layer on a base substrate, the drive circuit layer at least includes a plurality of circuit units, and at least one circuit unit includes a pixel circuit; the pixel circuit at least includes: a first transistor, a second transistor, a third transistor, a fourth transistor, and a first capacitor. A gate electrode of the first transistor is electrically connected to a first scan signal line, a first electrode of the first transistor is electrically connected to a first initial signal line, and a second electrode of the first transistor is electrically connected to a gate electrode of the third transistor; a gate electrode of the second transistor is electrically connected to a second scan signal line, a first electrode of the second transistor is electrically connected to the gate electrode of the third transistor, and a second electrode of the second transistor is electrically connected to a second electrode of the third transistor. A gate electrode of the fourth transistor is electrically connected to a third scan signal line, a first electrode of the fourth transistor is electrically connected to a data signal line, and a second electrode of the fourth transistor is electrically connected to a second end of the first capacitor; a first end of the first capacitor is electrically connected to the gate electrode of the third transistor. The first initial signal line, the first scan signal line, and the second scan signal line extend in at least partially a same direction and are located at a same side of the first transistor, and the first initial signal line is located between the first scan signal line and the second scan signal line.

In another aspect, an embodiment of the present disclosure provides a display substrate, including: a base substrate and a drive circuit layer provided on the base substrate, the drive circuit layer at least including a plurality of circuit units, at least one circuit unit of the plurality of circuit units including a pixel circuit which at least includes a first transistor, a second transistor, a third transistor, a fourth transistor and a first capacitor. A gate electrode of the first transistor is electrically connected to a first scan signal line, a first electrode of the first transistor is electrically connected to a first initial signal line, and a second electrode of the first transistor is electrically connected to a gate electrode of the third transistor; a gate electrode of the second transistor is electrically connected to a second scan signal line, a first electrode of the second transistor is electrically connected to the gate electrode of the third transistor, and a second electrode of the second transistor is electrically connected to a second electrode of the third transistor. A gate electrode of the fourth transistor is electrically connected to a third scan signal line, a first electrode of the fourth transistor is electrically connected to a data signal line, and a second electrode of the fourth transistor is electrically connected to a second end of the first capacitor; a first end of the first capacitor is electrically connected to the gate electrode of the third transistor. The second transistor is located at a side of the first transistor in a first direction, the third transistor and the fourth transistor are located at a same side of the first transistor and the second transistor in a second direction, the first direction intersects the second direction. The first initial signal line, the first scan signal line, and the second scan signal line all extend in the first direction and are located at a side of the first transistor away from the third transistor in the second direction. The first initial signal line is located between the first scan signal line and the second scan signal line.

In some exemplary implementation modes, an orthographic projection of the first scan signal line on the base substrate partially overlaps with orthographic projections of the gate electrode of the first transistor and the gate electrode of the second transistor on the base substrate.

In some exemplary implementation modes, the pixel circuit further includes a second capacitor; the second capacitor at least includes a second plate as a second end of the second capacitor and a fourth plate as a first end of the second capacitor, an orthographic projection of the second plate on the base substrate overlaps at least partially with an orthographic projection of the fourth plate on the base substrate. The first capacitor at least includes a first plate as the first end of the first capacitor and a third plate as a second end of the first capacitor, an orthographic projection of the first plate on the base substrate overlaps at least partially with an orthographic projection of the third plate on the base substrate. The fourth plate is connected to a first power supply line, the second plate is connected to the third plate, and the first plate is used as the gate electrode of the third transistor.

In some exemplary implementation modes, the third plate is provided with a second plate connection line extending towards the fourth plate, and the fourth plate is provided with a second groove recessed in a direction away from the third plate; the second plate connection line is provided in the second groove, and an end portion of the second plate connection line away from the third plate is connected to the second plate through a via and a connection electrode.

In some exemplary implementation modes, the at least one circuit unit further includes a first shielding electrode; the first shielding electrode includes: a first shielding end and a second shielding end; an orthographic projection of the first shielding end on the base substrate overlaps at least partially with an orthographic projection of a first active layer between two gate electrodes of the first transistor in the present circuit unit on the base substrate, and the first shielding end is electrically connected to a first power supply line. An orthographic projection of the second shielding end on the base substrate overlaps at least partially with an orthographic projection of a second active layer between two gate electrodes of a second transistor in an adjacent circuit unit on the base substrate, and the second shielding end is electrically connected to the first power supply line.

In some exemplary implementation modes, the pixel circuit further includes a fifth transistor and a sixth transistor. A gate electrode of the fifth transistor is electrically connected to a first light emitting signal line, a first electrode of the fifth transistor is electrically connected to a first power supply line, and a second electrode of the fifth transistor is electrically connected to a first electrode of the third transistor. A gate electrode of the sixth transistor is electrically connected to a second light emitting signal line, a first electrode of the sixth transistor is electrically connected to a second electrode of the third transistor, and a second electrode of the sixth transistor is electrically connected to a light emitting device. The first light emitting signal line is located at a side of the second scan signal line in the second direction, and the second light emitting signal line is located at a side of the first light emitting signal line in the second direction.

In some exemplary implementation modes, the first light emitting signal line, the second light emitting signal line, and the first initial signal line are disposed in a same layer.

Other aspects of the present disclosure may be comprehended after the drawings and the detailed descriptions are read and understood.

### BRIEF DESCRIPTION OF DRAWINGS

Accompanying drawings are used for providing further understanding of technical solutions of the present disclosure, constitute a part of the specification, and are used for explaining the technical solutions of the present disclosure together with embodiments of the present disclosure, but do not constitute limitations on the technical solutions of the present disclosure. Shapes and sizes of one or more components in the drawings do not reflect actual scales, and are only intended to schematically describe contents of the present disclosure.

FIG. 1 is a schematic diagram of a structure of a display apparatus.

FIG. 2 is a schematic diagram of a planar structure of a display substrate.

FIG. 3 is a schematic diagram of a partial sectional structure of a display substrate.

FIG. 4 is an equivalent circuit diagram of a pixel circuit according to at least one embodiment of the present disclosure.

FIG. 5 is an example diagram of a working timing of the pixel circuit shown in FIG. 4.

FIG. 6 is a schematic diagram of a planar structure of a display substrate according to at least one embodiment of the present disclosure.

FIG. 7 is a schematic partial cross-sectional view along a Q-Q′ direction in FIG. 6.

FIG. 8 is a schematic diagram of a display substrate after a semiconductor layer is formed in FIG. 6.

FIG. 9A is a schematic view of a display substrate after a first conductive layer is formed in FIG. 6.

FIG. 9B is a schematic view of the first conductive layer in FIG. 9A.

FIG. 10A is a schematic diagram of a display substrate after a second conductive layer is formed in FIG. 6.

FIG. 10B is a schematic view of the second conductive layer in FIG. 10A.

FIG. 11 is a schematic view of a display substrate after a third insulation layer is formed in FIG. 6.

FIG. 12A is a schematic diagram of a display substrate after a third conductive layer is formed in FIG. 6.

FIG. 12B is a schematic view of the third conductive layer in FIG. 12A.

FIG. 13 is a schematic view of a display substrate after a fourth insulation layer is formed in FIG. 6.

FIG. 14 is a schematic view of a fourth conductive layer in FIG. 6;

FIG. 15 is a schematic diagram of a planar structure of another display substrate according to at least one embodiment of the present disclosure.

FIG. 16A is a schematic view of a display substrate after a first conductive layer is formed in FIG. 15.

FIG. 16B is a schematic view of the first conductive layer in FIG. 16A.

FIG. 17A is a schematic diagram of a display substrate after a second conductive layer is formed in FIG. 15.

FIG. 17B is a schematic view of the second conductive layer in FIG. 17A.

FIG. 18 is a schematic diagram of a display substrate after a third insulation layer is formed in FIG. 15.

FIG. 19A is a schematic view of a display substrate after a third conductive layer is formed in FIG. 15.

FIG. 19B is a schematic view of the third conductive layer in FIG. 19A.

FIG. 20 is a schematic diagram of a display substrate after a fourth insulation layer is formed in FIG. 15.

FIG. 21 is a schematic view of a fourth conductive layer in FIG. 15;

FIG. 22 is a schematic diagram of a planar structure of another display substrate according to at least one embodiment of the present disclosure.

FIG. 23 is a schematic diagram of a display substrate after a first conductive layer is formed in FIG. 22.

FIG. 24A is a schematic diagram of a display substrate after a second conductive layer is formed in FIG. 22.

FIG. 24B is a schematic view of the second conductive layer in FIG. 24A.

FIG. 25 is a schematic diagram of a display substrate after a third insulation layer is formed in FIG. 22.

FIG. 26A is a schematic view of a display substrate after a third conductive layer is formed in FIG. 22.

FIG. 26B is a schematic view of the third conductive layer in FIG. 26A.

FIG. 27 is a schematic diagram of a display substrate after a fourth insulation layer is formed in FIG. 22.

FIG. 28 is a schematic view of a fourth conductive layer in FIG. 22.

FIG. 29 is a schematic diagram of a display apparatus according to at least one embodiment of the present disclosure.

### DETAILED DESCRIPTION

The embodiments of the present disclosure will be described below with reference to the drawings in detail. Implementation modes may be implemented in multiple different forms. Those of ordinary skills in the art may easily understand such a fact that implementation modes and contents may be transformed into other forms without departing from the purpose and scope of the present disclosure. Therefore, the present disclosure should not be construed as being limited to the contents recorded in the following implementation modes only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one implementation mode of the present disclosure is not necessarily limited to the size, and a shape and a size of one or more components in the drawings do not reflect an actual scale. In addition, the accompanying drawings schematically illustrate ideal examples, and an implementation mode of the present disclosure is not limited to shapes, numerical values, or the like shown in the drawings.

Ordinal numerals “first”, “second”, “third”, etc., in the specification are set not to form limits in numbers but only to avoid confusion between constituent elements. In the present disclosure, “plurality” represents two or more than two.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the constituent elements, not to indicate or imply that involved devices or elements are required to have specific orientations and be structured and operated with the specific orientations but only to easily and simply describe the present specification, and thus should not be understood as limitations on the present disclosure. The positional relationships between the constituent elements are changed as appropriate according to a direction according to which the constituent elements are described. Therefore, appropriate replacements based on situations are allowed, which is not limited to the expressions in the specification.

In the specification, unless otherwise specified and defined explicitly, terms “mount”, “mutually connect”, “connect”, and “couple” should be understood in a broad sense. For example, a connection may be a fixed connection, a detachable connection, or an integral connection; it may be a mechanical connection or an electrical connection; it may be a direct connection, an indirect connection through a middleware, or an internal communication inside two elements. Those of ordinary skills in the art may understand meanings of the aforementioned terms in the present disclosure according to situations. Among them, an “electrical connection” includes a case where constituent elements are connected together through an element with a certain electrical effect. The “element with a certain electrical effect” is not particularly limited as long as electrical signals between the connected constituent elements may be transmitted. Examples of the “element with the certain electrical effect” not only include electrodes and wirings, but further include switching elements such as transistors, resistors, inductors, capacitors, other elements with one or more functions, etc.

In the specification, a transistor refers to an element which at least includes three terminals, i.e., a gate, a drain, and a source. The transistor has a channel region between the drain (drain electrode terminal, drain region, or drain electrode) and the source (source electrode terminal, source region, or source electrode), and a current can flow through the drain, the channel region, and the source. In the specification, the channel region refers to a region through which a current mainly flows.

In the specification, to distinguish two electrodes of a transistor except a gate, one of the electrodes is referred to as a first electrode and the other electrode is referred to as a second electrode. The first electrode may be a source electrode or a drain electrode, and the second electrode may be a drain electrode or a source electrode. In addition, the gate of the transistor is referred to as a control electrode. In a case that transistors with opposite polarities are used, or in a case that a direction of a current is changed during operation of a circuit, or the like, functions of the “source” and the “drain” are sometimes interchangeable. Therefore, the “source” and the “drain” are interchangeable in the specification.

In the specification, “parallel” refers to a state in which an angle formed by two straight lines is −10° or more and 10° or less, and thus further includes a state in which the angle is −5° or more and 5° or less. In addition, “perpendicular” refers to a state in which an angle formed by two straight lines is 80° or more and 100° or less, and thus further includes a state in which the angle is 85° or more and 95° or less.

A triangle, rectangle, trapezoid, pentagon, or hexagon, etc. in the specification is not strictly defined, and it may be an approximate triangle, rectangle, trapezoid, pentagon, or hexagon, etc. There may be some small deformations caused by tolerance, and there may be a chamfer, an arc edge, and deformation, etc.

In the present disclosure, “about” and “substantially” refer to that a boundary is not defined strictly and a case within a range of process and measurement errors is allowed. In the present disclosure, “substantially the same” refers to a case where numerical values differ by less than 10%.

In the present disclosure, “A extends along a B direction” means that A may include a main body portion and a secondary portion connected to the main body portion, the main body portion is a line, a line segment, or a strip-shaped body, the main body portion extends along the B direction, and a length of the main body portion extending along the B direction is greater than a length of the secondary portion extending along another direction. In following description, “A extends along a B direction” means “a main body portion of A extends along a B direction”.

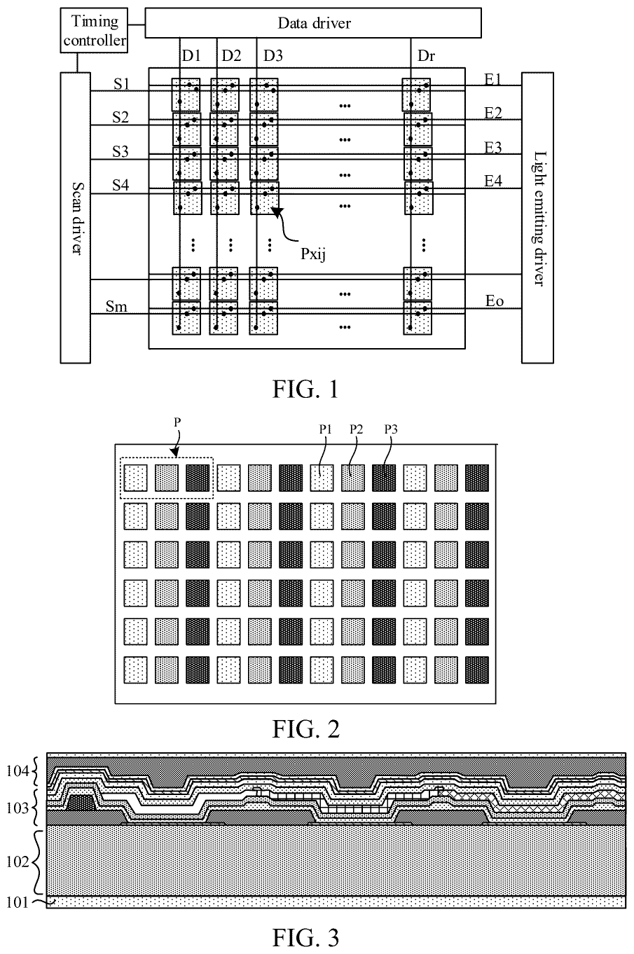

FIG. 1 is a schematic diagram of a structure of a display apparatus. In some examples, as shown in FIG. 1, the display apparatus may include a timing controller, a data driver, a scan driver, a light emitting driver and a pixel array. The timing controller may be connected to the data driver, the scan driver, and the light emitting driver respectively. The data driver is respectively connected to a plurality of data signal lines (e.g., D1 to Dr), the scan driver may be respectively connected to a plurality of scan signal lines (e.g., S1 to Sm), and the light emitting driver may be respectively connected to a plurality of light emitting signal lines (e.g., E1 to Eo). The pixel array may include a plurality of sub-pixels Pxij, where i and j may be natural numbers. At least one sub-pixel Pxij may include a circuit unit and a light emitting unit, the circuit unit may at least include a pixel circuit, and the pixel circuit may be connected to a scan signal line, a light emitting signal line and a data signal line respectively. The light emitting unit may include a light emitting device, and the light emitting device may be electrically connected to the pixel circuit of the circuit unit.

In some examples, the timing controller may provide the data driver with a gray-scale value and a control signal which are suitable for a specification of the data driver, provide the scan driver with a clock signal, a scan start signal and the like which are suitable for a specification of the scan driver, and provide the light emitting driver with a clock signal, an emission stop signal and the like which are suitable for a specification of the light emitting driver. The data driver may generate data voltages to be provided to the data signal lines D1, D2, D3, . . . , and Dn using the grayscale value and the control signal that are received from the timing controller. For example, the data driver may sample the grayscale value using the clock signal and apply a data voltage corresponding to the grayscale value to the data signal lines D1 to Dr by taking a pixel row as a unit, wherein r may be a natural number. The scan driver may generate a scan signal to be provided to the scan signal lines S1, S2, S3, . . . and Sm by a clock signal, the scan start signal, and the like received from the timing controller. For example, the scan driver may provide sequentially a scan signal with a turn-on level pulse to the scan signal lines S1 to Sm, where m may be a nature number. For example, the scan driver may be constructed in a form of a shift register and may generate a scan signal in a manner in which the scan start signal provided in a form of an on-level pulse is transmitted to a next-stage circuit sequentially under control of the clock signal, wherein m may be a natural number. The light emitting driver may receive the clock signal, the emission stop signal, etc., from the timing controller to generate an emission signal to be provided to the light emitting signal lines E1, E2, E3, . . . , and Eo. For example, the light emitting driver may sequentially provide the emission signal with an off-level pulse to the light emitting signal lines E1 to Eo. For example, the light emitting driver may be constructed in a form of a shift register and generate the emission signal in a manner of sequentially transmitting the emission stop signal provided in a form of an off-level pulse to a next-stage circuit under control of the clock signal, wherein o may be a natural number. In some examples, the pixel array may be provided on the display substrate.

FIG. 2 is a schematic diagram of a planar structure of a display substrate. In some examples, the display substrate may include a display area and a bezel area located at a periphery of the display area. As shown in FIG. 2, the display area of the display substrate may include a plurality of pixel units P arranged in a matrix. At least one pixel unit P may include a first sub-pixel P1 emitting light of a first color, a second sub-pixel P2 emitting light of a second color, and a third sub-pixel P3 emitting light of a third color. Each sub-pixel may include a circuit unit and a light emitting unit, and the circuit unit may at least include a pixel circuit, the pixel circuit may be electrically connected to a scan signal line, a data signal line and a light emitting signal line respectively, and the pixel circuit may be configured to receive a data voltage transmitted by the data signal line under control of the scan signal line and the light emitting signal line, and output a corresponding current to the light emitting unit. The light emitting unit may at least include a light emitting device, the light emitting device may be electrically connected to a pixel circuit of a sub-pixel where the light emitting device is located, and the light emitting device may be configured to emit light with corresponding brightness in response to a current output by the pixel circuit of the sub-pixel where the light emitting device is located.

In some examples, the pixel circuit may include multiple transistors and at least one capacitor. For example, the pixel circuit may be a circuit having a 3T1C, 4T1C, 5T1C, 5T2C, 6T1C, 7T1C, or 8T1C structure. Among them, in the above circuit structure, T refers to a thin film transistor, C refers to a capacitor, a number before T represents a quantity of thin film transistors in the circuit, and a number before C represents a quantity of capacitors in the circuit.

In some examples, the first sub-pixel P1 may be a red (R) sub-pixel emitting red light, the second sub-pixel P2 may be a blue (B) sub-pixel emitting blue light, and the third sub-pixel P3 may be a green (G) sub-pixel emitting green light. In some examples, a shape of the light emitting device may be a rectangle, a rhombus, a pentagon, or a hexagon. When one pixel unit includes three sub-pixels, light emitting devices of the three sub-pixels may be arranged side by side horizontally, side by side vertically, or in a delta-shaped arrangement. When one pixel unit includes four sub-pixels, light emitting devices of the four sub-pixels may be arranged side by side horizontally, side by side vertically, or in a square arrangement. However, the embodiment is not limited thereto.

FIG. 3 is a schematic diagram showing a partial sectional structure of a display substrate. FIG. 3 illustrates structures of three sub-pixels of the display substrate. In some examples, as shown in FIG. 3, in a direction perpendicular to the display substrate, the display area of the display substrate may include a base substrate 101, a drive circuit layer 102 provided on the base substrate 101, a light emitting structure layer 103 provided on a side of the drive circuit layer 102 away from the base substrate 101, and an encapsulation structure layer 104 provided on a side of the light emitting structure layer 103 away from the base substrate 101. In some possible implementation modes, the display substrate may include another film layer, such as a touch structure layer, and the present disclosure is not limited herein.

In some examples, the base substrate 101 may be a flexible substrate or may be a base substrate. The drive circuit layer 101 may include a plurality of circuit units which may at least include a pixel circuit which may include a plurality of transistors and at least one capacitor. The light emitting structure layer 103 may include a plurality of light emitting units, and a light emitting unit may at least include a light emitting device. The encapsulation structure layer 104 may include a first encapsulation layer, a second encapsulation layer, and a third encapsulation layer which are stacked. The first encapsulation layer and the third encapsulation layer may be made of an inorganic material, and the second encapsulation layer may be made of an organic material. The second encapsulation layer may be disposed between the first encapsulation layer and the third encapsulation layer to form a laminated structure of inorganic material/organic material/inorganic material, which may ensure that external water vapor cannot enter the light emitting structure layer 103.

In some examples, the light emitting device may be any of a Light Emitting Diode (LED), an Organic Light Emitting Diode (OLED), a Quantum Dot Light Emitting Diode (QLED), a micro LED (including: mini-LED or micro-LED), and the like. For example, the light emitting device may be an OLED, and the light emitting device may emit red light, green light, blue light, or white light, etc. under drive of a pixel circuit corresponding to the light emitting element. A color of light emitted from the light emitting device may be determined as required. In some examples, the light emitting device may include an anode, a cathode, and an organic light emitting layer disposed between the anode and the cathode. The anode of the light emitting device can be electrically connected to a corresponding pixel circuit, the organic light emitting layer is connected to the anode, and the cathode is connected to the organic light emitting layer. The organic light emitting layer can emits light of corresponding color under drive of the anode and the cathode. However, the embodiment is not limited thereto.

In some examples, the organic emitting layer may include an Emitting Layer (EML) and any one or more of following layers: a Hole Injection Layer (HIL), a Hole Transport Layer (HTL), an Electron Block Layer (EBL), a Hole Block Layer (HBL), an Electron Transport Layer (ETL) and an Electron Injection Layer (EIL).

This embodiment provides a display substrate, including a base substrate and a drive circuit layer provided on the base substrate, wherein the drive circuit layer at least includes a plurality of circuit units. At least one circuit unit includes a pixel circuit. The pixel circuit at least includes a first transistor, a second transistor, a third transistor, a fourth transistor, and a first capacitor. A gate electrode of the first transistor is electrically connected to a first scan signal line, a first electrode of the first transistor is electrically connected to a first initial signal line, and a second electrode of the first transistor is electrically connected to a gate electrode of the third transistor. A gate electrode of the second transistor is electrically connected to a second scan signal line, a first electrode of the second transistor is electrically connected to the gate electrode of the third transistor, and a second electrode of the second transistor is electrically connected to a second electrode of the third transistor. A gate electrode of the fourth transistor is electrically connected to a third scan signal line, a first electrode of the fourth transistor is electrically connected to a data signal line, and a second electrode of the fourth transistor is electrically connected to a second end of the first capacitor. A first end of the first capacitor is electrically connected to the gate electrode of the third transistor. The first initial signal line, the first scan signal line and the second scan signal line extend in at least partially a same direction and are located at a same side of the first transistor, and the first initial signal line is located between the first scan signal line and the second scan signal line.

In the display substrate provided in this embodiment, the first transistor is configured to initialize the gate electrode of the third transistor (i.e., the first end of the first capacitor) using a first initial signal provided by the first initial signal line under control of the first scan signal line. By arranging the first initial signal line between the first scan signal line and the second scan signal line, layout wiring can be optimized, an initialization path length of the first initial signal can be reduced, which is conducive to optimizing an initialization effect.

In some exemplary implementation modes, an active layer of the first transistor may include a first region, a second region, and a channel region located between the first region and the second region, the first region of the active layer of the first transistor is connected to the first initial signal line. The drive circuit layer further includes at least one first power supply line. An orthographic projection of the at least one first power supply line on the base substrate covers an orthographic projection of the first region of the active layer of the first transistor on the base substrate. The orthographic projection of the at least one first power supply line on the base substrate may cover an orthographic projection of a position where the first region of the active layer of the first transistor is connected to the first initial signal line on the base substrate. In this example, by providing the first power supply line to shield the first region of the active layer of the first transistor connected to the first initial signal line, other signals can be avoided from influencing reception of the first initial signal by the first region of the active layer of the first transistor, thereby ensuring accuracy of transmission of the first initial signal to ensure the initialization effect.

In some exemplary implementation modes, the pixel circuit may further include a second capacitor. The second capacitor at least includes a second plate as a second end of the second capacitor and a fourth plate as a first end of the second capacitor. An orthographic projection of the second plate on the base substrate overlaps at least partially with an orthographic projection of the fourth plate on the base substrate. The first capacitor at least includes a first plate as the first end of the first capacitor and a third plate as the second end of the first capacitor. An orthographic projection of the first plate on the base substrate at least partially overlaps with an orthographic projection of the third plate on the base substrate. The fourth plate is connected to the first power supply line, the second plate is connected to the third plate, and the first plate is used as the gate electrode of the third transistor.

In some exemplary implementation modes, a second plate connection line extending towards the fourth plate is provided on the third plate, and a second groove recessed in a direction away from the third plate is provided on the fourth plate. The second plate connection line can be provided in the second groove, and an end portion of the second plate connection line away from the third plate can be connected to the second plate through a via and a connection electrode. The structural design of the third plate and the fourth plate of this example can increase a distance between a first node and a fifth node of the pixel circuit, and is conducive to increasing arrangement space of lateral traces.

In some exemplary implementation modes, the at least one circuit unit may further include a first shielding electrode. An orthographic projection of the first shielding electrode on the base substrate overlaps at least partially with an orthographic projection of a first active layer between two gate electrodes of the first transistor in the present circuit unit on the base substrate, and also overlaps at least partially with an orthographic projection of a second active layer between two gate electrodes of a second transistor in an adjacent circuit unit on the base substrate. In some examples, the first shielding electrode may include a first shielding end and a second shielding end. An orthographic projection of the first shielding end on the base substrate overlaps at least partially with the orthographic projection of the first active layer between two the gate electrodes of the first transistor in the present circuit unit on the base substrate, and the first shielding end is electrically connected to the first power supply line. An orthographic projection of the second shielding end on the base substrate overlaps at least partially with an orthographic projection of a second active layer between two gate electrodes of a second transistor in an adjacent circuit unit on the base substrate, and the second shielding end is electrically connected to the first power supply line. The structural design of the first shielding electrode of this example can improve signal crosstalk.

The display substrate of this embodiment will now be described with some examples.

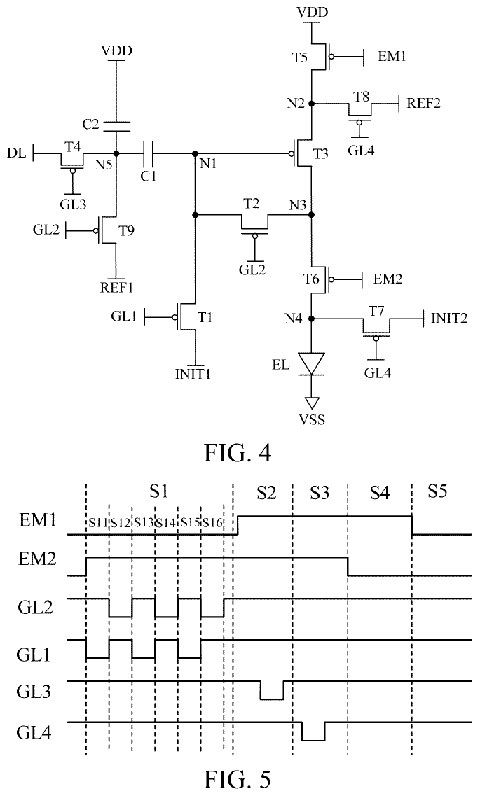

FIG. 4 is an equivalent circuit diagram of a pixel circuit according to at least one embodiment of the present disclosure. The pixel circuit according to this example may be of a 9T2C structure and may include nine transistors (e.g., a first transistor T1 to a ninth transistor T9) and two capacitors (e.g., a first capacitor C1 and a second capacitor C2). The pixel circuit may be electrically connected to 12 signal lines (including, for example, a first scan signal line GL1, a second scan signal line GL2, a third scan signal line GL3, a fourth scan signal line GL4, a first light emitting signal line EM1, a second light emitting signal line EM2, a first initial signal line INIT1, a second initial signal line INIT2, a first reference signal line REF1, a second reference signal line REF2, a data signal line DL, and a first power supply line VDD) respectively.

In some examples, as shown in FIG. 4, the pixel circuit may include a first node NI, a second node N2, a third node N3, a fourth node N4, and a fifth node N5. The first node N1 may be connected to a second electrode of the first transistor T1, a first electrode of the second transistor T2, a gate electrode of the third transistor T3, and a first end of the first capacitor C1 respectively. The second node N2 may be connected to a first electrode of the third transistor T3, a second electrode of the eighth transistor T8, and a second electrode of the fifth transistor T5 respectively. The third node N3 may be connected to a second electrode of the second transistor T2, a second electrode of the third transistor T3, and a first electrode of the sixth transistor T6 respectively. The fourth node N4 may be connected to a second electrode of the sixth transistor T6 and a second electrode of the seventh transistor T7 respectively. The fifth node N5 may be connected to a second electrode of the fourth transistor T4, a second electrode of the ninth transistor T9, a second end of the first capacitor C1, and a second end of the second capacitor C2 respectively. The fourth node N4 may also be connected to an anode of a light emitting device EL.

In some examples, the first end (a lower plate) of the first capacitor C1 is connected to the first node N1, and the second end (an upper plate) of the first capacitor Cl is connected to the fifth node N5. A first end (an upper plate) of the second capacitor C2 is connected to the first power supply line VDD, and the second end (a lower plate) of the second capacitor C2 is connected to the fifth node N5.

In some examples, a gate electrode of the first transistor T1 is connected to the first scan signal line GL1, a first electrode of the first transistor T1 is connected to the first initial signal line INIT1, and the second electrode of the first transistor is connected to the first node N1. When a turned-on signal is applied to the first scan signal line GL1, the first transistor T1 transmits a first initial voltage to the gate electrode of the third transistor T3 and the first end of the first capacitor C1, so that accumulated charges in the first capacitor C1 are released, and initialization is realized.

In some examples, a gate electrode of the second transistor T2 is connected to the second scan signal line GL2, the first electrode of the second transistor T2 is connected to the first node N1, and the second electrode of the second transistor T2 is connected to the third node N3. When a turned-on signal is applied to the second scan signal line GL2, the second transistor T2 enables the gate electrode of the third transistor T3 to be connected to the second electrode of the third transistor T3.

In some examples, the gate electrode of the third transistor T3 is connected to the first node N1, that is, the gate electrode of the third transistor T3 is connected to the first end of the first capacitor C1, the first electrode of the third transistor T3 is connected to the second node N2, and the second electrode of the third transistor T3 is connected to the third node N3. The third transistor T3 may be referred to as a drive transistor and the third transistor T3 determines a magnitude of a drive current according to a potential difference between the gate electrode and the first electrode of the third transistor T3.

In some examples, a gate electrode of the fourth transistor T4 is connected to the third scan signal line GL3, a first electrode of the fourth transistor T4 is connected to the data signal line DL, and the second electrode of the fourth transistor T4 is connected to the fifth node N5. When a turned-on signal is applied to the third scan signal line GL3, the fourth transistor T4 causes a data voltage of the data signal line DL to be input to the fifth node N5 (i.e., the second end of the first capacitor C1 and the second end of the second capacitor C2).

In some examples, a gate electrode of the fifth transistor T5 is connected to the first light emitting signal line EM1, a first electrode of the fifth transistor T5 is connected to the first power supply line VDD, and the second electrode of the fifth transistor T5 is connected to the second node N2. A gate electrode of the sixth transistor T6 is connected to the second light emitting signal line EM2, the first electrode of the sixth transistor T6 is connected to the third node N3, and the second electrode of the sixth transistor T6 is connected to the fourth node N4. When a turned-on signal is applied to the first light emitting signal line EM1 and the second light emitting signal line EM2, the fifth transistor T5 and the sixth transistor T6 form a drive current path between the first power supply line VDD and the second power supply line VSS to cause the light emitting device EL to emit light.

In some examples, a gate electrode of the seventh transistor T7 is connected to the fourth scan signal line GL4, a first electrode of the seventh transistor T7 is connected to the second initial signal line INIT2, and the second electrode of the seventh transistor T7 is connected to the fourth node N4. When a turned-on signal is applied to the fourth scan signal line GL4, the seventh transistor T7 transmits a second initial voltage to a first electrode of the light emitting device EL, so that accumulated charges in the first electrode of the light emitting device EL are released, and initialization is realized.

In some examples, a gate electrode of the eighth transistor T8 is connected to the fourth scan signal line GL4, a first electrode of the eighth transistor T8 is connected to the second reference signal line REF2, and the second electrode of the eighth transistor T8 is connected to the second node N2. When a turned-on signal is applied to the fourth scan signal line GL4, the eighth transistor T8 transmits a second reference signal to the second node N2.

In some examples, the gate electrode of the ninth transistor T9 is connected to the second scan signal line GL2, a first electrode of the ninth transistor T9 is connected to the first reference signal line REF1, and the second electrode of the ninth transistor T9 is connected to the fifth node N5. When a turned-on signal is applied to the second scan signal line GL2, the ninth transistor T9 transmits a first reference signal to the fifth node N5.

In some examples, the light emitting device EL may be an OLED including a first electrode (anode), an organic light emitting layer, and a second electrode (cathode) which are stacked, or may be a QLED including a first electrode (anode), a quantum dot light emitting layer, and a second electrode (cathode) which are stacked. The first electrode of the light emitting device EL is connected to the fourth node N4, and a second electrode of the light emitting device EL is connected to the second power supply line VSS. In some examples, a signal of the second power supply line VSS may be a low-level signal continuously supplied, and a signal of the first power supply line VDD may be a high-level signal continuously supplied.

In some examples, the first transistor T1 to the ninth transistor T9 of the pixel circuit may be P-type transistors, or may be N-type transistors. Use of a same type of transistors in the pixel circuit may simplify a process flow, reduce process difficulties of a display panel, and improve a yield of products. In some possible implementation modes, the first transistor T1 to the ninth transistor T9 may include a P-type transistor and an N-type transistor.

In some examples, the first transistor T1 to the ninth transistor T9 of the pixel circuit may be low temperature polysilicon thin film transistors, or may be oxide thin film transistors, or may be low temperature poly-silicon thin film transistors and oxide thin film transistors. Low Temperature Poly-Silicon (LTPS) is used for an active layer of a low temperature poly silicon thin film transistor and an oxide semiconductor (Oxide) is used for an active layer of an oxide thin film transistor. The low temperature poly silicon thin film transistor has advantages such as a high mobility and fast charging, and the oxide thin film transistor has advantages such a low drain current. The low temperature poly silicon thin film transistor and the oxide thin film transistor are integrated on one display substrate, that is a LTPS+Oxide (LTPO for short) display substrate, so that the advantages of both the low temperature poly silicon thin film transistor and the oxide thin film transistor may be utilized, low-frequency drive may be achieved, power consumption may be reduced, and a display quality may be improved.

FIG. 5 is an example diagram of a working timing of the pixel circuit shown in FIG. 4. In some examples, by taking a case in which the first transistor T1 to the ninth transistor T9 in the pixel circuit shown in FIG. 4 are all P-type transistors as an example, a working process of the pixel circuit may include the following stages.

In a first stage S1, a signal of the first light emitting signal line EM1 is a low-level signal, and signals of the second light emitting signal line EM2, the third scan signal line GL3, and the fourth scan signal line GL4 are high-level signals. The low-level signal of the first light emitting signal line EM1 may turn on the fifth transistor T5, and a first power supply signal of the first power supply line VDD may be provided to the second node N2. The signals of the second light emitting signal line EM2, the third scan signal line GL3, and the fourth scan signal line GL4 are high-level signals, so that the sixth transistor T6, the fourth transistor T4, the seventh transistor T7, and the eighth transistor T8 are all turned off.

The first stage S1 may at least include a first sub-stage S11, a second sub-stage S12, a third sub-stage S13, a fourth sub-stage S14, a fifth sub-stage S15, and a sixth sub-stage S16. In the first sub-stage S11, a signal of the first scan signal line GL1 is a low-level signal, so that the first transistor T1 is turned on; a signal of the second scan signal line GL2 is a high-level signal, so that the second transistor T2 and the ninth transistor T9 are turned off. The first transistor T1 is turned on, and a first initial signal of the first initial signal line INIT1 may be provided to the first node N1 to initialize the first node N1. In the second sub-stage S12, the signal of the first scan signal line GL1 is a high-level signal, so that the first transistor T1 is turned off; the signal of the second scan signal line GL2 is a low-level signal, so that the second transistor T2 and the ninth transistor T9 are turned on. The second transistor T2 is turned on, so that the first node N1 and the third node N3 can be connected to each other, a threshold value of the third transistor T3 is compensated, and a threshold voltage of the third transistor T3 is written to the first node N1. The ninth transistor T9 is turned on, so that a first reference signal of the first reference signal line REF1 may be provided to the fifth node N5 to initialize the fifth node N5. The third sub-stage S13 and the fifth sub-stage S15 are substantially the same as the first sub-stage S11, and the fourth sub-stage S14 and the sixth sub-stage S16 are substantially the same as the second sub-stage S12, which will not be repeated here.

Since electrons are captured in traps when the drive transistor (i.e., the third transistor) is in a state for a long period of time, hysteresis is caused. Therefore, the initialization and threshold voltage writing processes performed multiple times (e.g., three times) pm the first node N1 are in this stage, so that the hysteresis of the drive transistor can be reduced and potential stability of the first node N1 can be ensured.

A second stage S2 may be called a data writing stage. In this stage, signals of the first light emitting signal line EM1, the second light emitting signal line EM2, the first scan signal line GL1, the second scan signal line GL2, and the fourth scan signal line GL4 are high-level signals, so that the fifth transistor T5, the sixth transistor T6, the first transistor T1, the ninth transistor T9, the second transistor T2, the seventh transistor T7, and the eighth transistor T8 are all turned off. A signal of the third scan signal line GL3 is a low-level signal, so that the fourth transistor T4 is turned on, a data voltage provided by the data signal line DL is written to the fifth node N5, and the data voltage is written to the first node N1 through the first capacitor C1.

In a third stage S3, signals of the first light emitting signal line EM1, the second light emitting signal line EM2, the first scan signal line GL1, the second scan signal line GL2, and the third scan signal line GL3 are high-level signals, so that the fifth transistor T5, the sixth transistor T6, the first transistor T1, the second transistor T2, the ninth transistor T9, and the fourth transistor T4 are all turned off. A signal of the fourth scan signal line GL4 is a low-level signal, so that both the seventh transistor T7 and the eighth transistor T8 are turned on. The seventh transistor T7 is turned on, so that a second initial signal of the second initial signal line INIT2 can be written to the fourth node N4, and by initializing the fourth node N4, a residual signal of a previous frame can be prevented from affecting display of the present frame; the eighth transistor T8 is turned on, so that a second reference signal of the second reference signal line REF2 can be written to the second node N2, which helps to reduce the hysteresis of the drive transistor.

In a fourth stage S4, signals of the first light emitting signal line EM1, the first scan signal line GL1, the second scan signal line GL2, the third scan signal line GL3, and the fourth scan signal line GL4 are high-level signals, so that the fifth transistor T5, the first transistor T1, the second transistor T2, the ninth transistor T9, the fourth transistor T4, the seventh transistor T7, and the eighth transistor T8 are all turned off. A signal of the second light emitting signal line EM2 is a low-level signal, so that the sixth transistor T6 is turned on, and the third node N3 and the fourth node N4 are connected to each other, so that potentials of the fourth node N4 and the third node N3 are the same. By connecting the fourth node N4 to the third node N3, it helps to raise the potential of the fourth node N4, which in turn helps to reduce a time length required for subsequently reaching a light-up voltage of the light emitting device.

In a fifth stage S5, signals of the first light emitting signal line EM1 and the second light emitting signal line EM2 are low-level signals, so that the fifth transistor T5 and the sixth transistor T6 are turned on, and the first power supply signal of the first power supply line VDD can provide a drive signal to the light emitting device EL through the fifth transistor T5, third transistor T3 and sixth transistor T6 which are turned on, so as to drive the light emitting device EL to emit light. Signals of the first scan signal line GL1, the second scan signal line GL2, the third scan signal line GL3, and the fourth scan signal line GL4 are high-level signals, so that the first transistor T1, the second transistor T2, the ninth transistor T9, the fourth transistor T4, the seventh transistor T7, and the eighth transistor T8 are all turned off.

The pixel circuit of this example can improve the hysteresis of the drive transistor, which is conducive to improving the display effect.

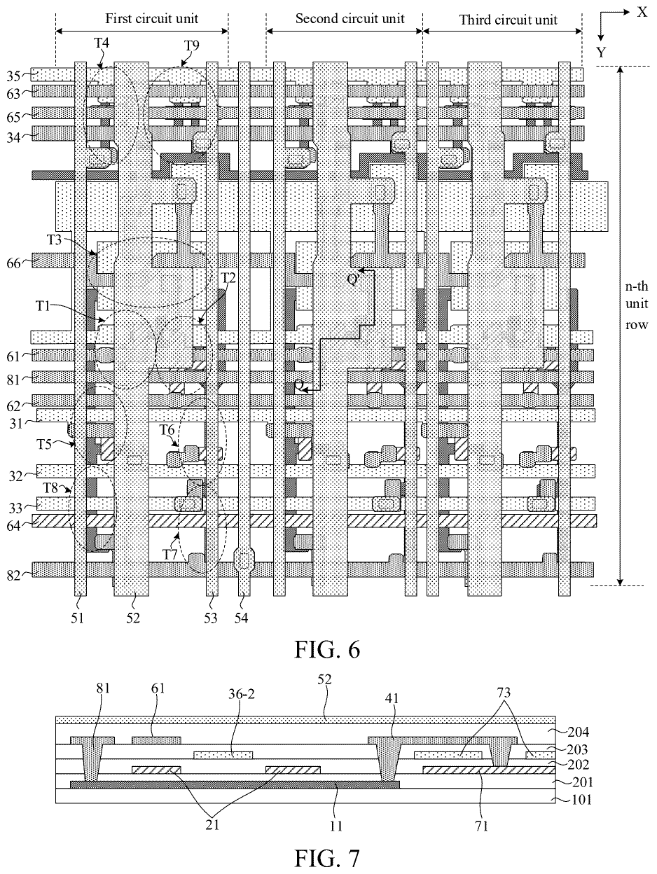

FIG. 6 is a schematic diagram of a planar structure of a display substrate according to at least one embodiment of the present disclosure. Structures of pixel circuits in three circuit units (i.e. a first circuit unit, a second circuit unit and a third circuit unit) of a display substrate are illustrated in FIG. 6. FIG. 7 is a schematic partial cross-sectional view along a Q-Q′ direction in FIG. 6.

In some examples, the display substrate may include a drive circuit layer disposed on a base substrate and a light emitting structure layer disposed on a side of the drive circuit layer away from the base substrate. The drive circuit layer may at least include a plurality of circuit units, and the light emitting structure layer may at least include a plurality of light emitting units. At least one circuit unit may include a pixel circuit, and at least one light emitting unit may include a light emitting device. The light emitting device may at least include an anode, an organic light emitting layer and a cathode, and the anode of the light emitting device may be connected to a pixel circuit in a corresponding circuit unit.

A circuit unit mentioned in the present disclosure refers to a region divided according to a pixel circuit, and a light emitting unit mentioned in the present disclosure refers to a region divided according to a light emitting device. In some examples, a position of an orthographic projection of a light emitting unit on the base substrate may correspond to a position of an orthographic projection of a circuit unit on the base substrate, or a position of an orthographic projection of a light emitting unit on the base substrate may not correspond to a position of an orthographic projection of a circuit unit on the base substrate.

In some examples, a plurality of circuit units sequentially arranged along a first direction X may be referred to as a unit row, and a plurality of circuit units sequentially arranged along a second direction Y may be referred to as a unit column, and a plurality of unit rows and a plurality of unit columns may constitute an array of circuit units arranged in a matrix. The first direction X may intersect with the second direction Y, for example, the first direction X may be perpendicular to the second direction Y.

In some examples, as shown in FIGS. 6 and 7, in a direction perpendicular to the display substrate, the drive circuit layer may include a semiconductor layer, a first conductive layer, a second conductive layer, a third conductive layer, and a fourth conductive layer sequentially disposed on the base substrate 101. A first insulation layer 201 may be provided between the semiconductor layer and the first conductive layer, a second insulation layer 202 may be provided between the first conductive layer and the second conductive layer, a third insulation layer 203 may be provided between the second conductive layer and the third conductive layer, and a fourth insulation layer 204 may be provided between the third conductive layer and the fourth conductive layer. In some examples, the first insulation layer 201, the second insulation layer 202, and the third insulation layer 203 may be inorganic insulation layers, and the fifth insulation layer 204 may be an organic insulation layer. However, the embodiment is not limited thereto. In some other examples, a buffer layer may be provided between the base substrate and the semiconductor layer. In some other examples, a passivation layer located on a side of the fourth insulation layer close to the base substrate may further be provided between the third conductive layer and the fourth conductive layer.

In some examples, as shown in FIG. 6, at least one pixel circuit may include a first transistor T1 as a first initialization transistor, a second transistor T2 as a compensation transistor, a third transistor T3 as a drive transistor, a fourth transistor T4 as a data writing transistor, a fifth transistor T5 as a first light emitting control transistor, a sixth transistor T6 as a second light emitting control transistor, a seventh transistor T7 as a second initialization transistor, an eighth transistor T8 as a second reference transistor, a ninth transistor T9 as a first reference transistor, a first capacitor, and a second capacitor.

Exemplary description is made below through a manufacturing process of a display substrate. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process.

“A and B are disposed in a same layer” in the present disclosure means that A and B are formed simultaneously through a same patterning process, and a “thickness” of a film layer is a dimension of the film layer in a direction perpendicular to a display substrate. In an exemplary embodiment of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A coincides with the boundary of the orthographic projection of B.

In some examples, taking three circuit units (i.e., a first circuit unit, a second circuit unit, and a third circuit unit) in a n-th unit row as an example, a manufacturing process of the display substrate of this embodiment may include the following operations.

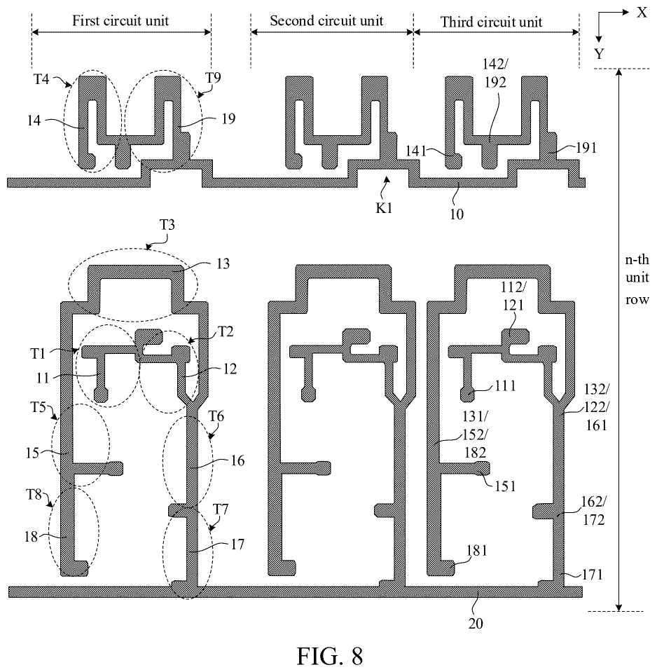

(1-1) A semiconductor layer is formed. In some examples, a semiconductor thin film is deposited on the base substrate, and the semiconductor thin film is patterned by a patterning process to form a semiconductor layer, as shown in FIG. 8. FIG. 8 is a schematic diagram of a display substrate after a semiconductor layer is formed in FIG. 6.

In some examples, a semiconductor layer of each circuit unit in the display substrate may at least include a first active layer 11 of the first transistor T1, a second active layer 12 of the second transistor T2, a third active layer 13 of the third transistor T3, a fourth active layer 14 of the fourth transistor T4, a fifth active layer 15 of the fifth transistor T5, a sixth active layer 16 of the sixth transistor T6, a seventh active layer 17 of the seventh transistor T7, an eighth active layer 18 of the eighth transistor T8, and a ninth active layer 19 of the ninth transistor T9. The first active layer 11 to the third active layer 13 and the fifth active layer 15 to the eighth active layer 18 may be interconnected to form an integral structure, and the fourth active layer 14 and the ninth active layer 19 may be interconnected to form an integral structure.

In some examples, the fourth active layer 14 and the ninth active layer 19 of the n-th unit row may be located at a side of the third active layer 13 close to an (n−1)-th unit row, that is, the fourth active layer 14 and the ninth active layer 19 may be located at a side of the third active layer 13 of the present circuit unit in an opposite direction of the second direction Y. The first active layer 11, the second active layer 12, and the fifth active layer 15 to the eighth active layer 18 of the n-th unit row may be located at a side of the third active layer 13 close to an (n+1)-th unit row, that is, the first active layer 11, the second active layer 12, and the fifth active layer 15 to the eighth active layer 18 may be located at a side of the third active layer 13 of the present circuit unit in the second direction Y.

In some examples, the first active layer 11 may be located at the side of the third active layer 13 of the present circuit unit in the second direction Y, the fifth active layer 15 may be located at a side of the first active layer 11 of the present circuit unit in the second direction Y, and the eighth active layer 18 may be located at a side of the fifth active layer 15 of the present circuit unit in the second direction Y. The second active layer 12 may be located at the side of the third active layer 13 of the present circuit unit in the second direction Y, the sixth active layer 16 may be located at a side of the second active layer 12 of the present circuit unit in the second direction Y, and the seventh active layer 17 may be located at a side of the sixth active layer 16 of the present circuit unit in the second direction Y.

In some examples, the first active layer 11, the fourth active layer 14, the fifth active layer 15, and the eighth active layer 18 may be located at a side of the present circuit unit in the first direction X (e.g., a side in an opposite direction of the first direction X), and the second active layer 12, the sixth active layer 16, the seventh active layer 17, and the ninth active layer 19 may be located at the other side of the present circuit unit in the first direction X (e.g., a side of the first direction X).

In some examples, the first active layer 11 and the second active layer 12 may each be substantially in a shape of an “L”, the third active layer 13 may be substantially in a shape of an “C”, the fourth active layer 14 and the ninth active layer 19 may each be substantially in a shape of an “n”, and the fifth active layer 15, the sixth active layer 16, the seventh active layer 17 and the eighth active layer 18 may each be substantially in a shape of an “I”.

In some examples, an active layer of each transistor may include a first region, a second region, and a channel region located between the first region and the second region. In some examples, a second region 112 of the first active layer 11 and a first region 121 of the second active layer 12 may be interconnected, and the second region 112 of the first active layer 11 may serve as the first region 121 of the second active layer 12. A first region 131 of the third active layer 13, a second region 152 of the fifth active layer 15, and a second region 182 of the eighth active layer 18 may be interconnected, and the first region 131 of the third active layer 13 may simultaneously serve as the second region 152 of the fifth active layer 15 and the second region 182 of the eighth active layer 18, constituting a second node N2 of a pixel circuit. A second region 122 of the second active layer 12, a second region 132 of the third active layer 13, and a first region 161 of the sixth active layer 16 may be interconnected, and the second region 132 of the third active layer 13 may simultaneously serve as the second region 122 of the second active layer 12 and the first region 161 of the sixth active layer 16, constituting a third node N3 of the pixel circuit. A second region 142 of the fourth active layer 14 and a second region 192 of the ninth active layer 19 may be connected to each other, and the second region 142 of the fourth active layer 14 may serve as the second region 192 of the ninth active layer 19. A second region 162 of the sixth active layer 16 and a second region 172 of the seventh active layer 17 may be interconnected, and the second region 162 of the sixth active layer 16 may serve as the second region 172 of the seventh active layer 17, constituting a fourth node N4 of the pixel circuit. A first region 111 of the first active layer 11, a first region 141 of the fourth active layer 14, a first region 151 of the fifth active layer 15 and a first region 181 of the eighth active layer 18 may be disposed separately. The first region 141 of the fourth active layer 14 may be located on a side of a channel region of the fourth active layer 14 close to the third active layer 13, and a first region 191 of the ninth active layer 19 may be located on a side of a channel region of the ninth active layer 19 close to the third active layer 13.

In some examples, in at least one unit row, semiconductor layers in circuit units adjacent in the first direction X may be interconnected. For example, the semiconductor layer of the first circuit unit of the n-th unit row may be connected to the semiconductor layer of the second circuit unit of the n-th unit row, and the semiconductor layer of the second circuit unit of the n-th unit row may be connected to the semiconductor layer of the third circuit unit of the n-th unit row. In the n-th unit row, semiconductor layers of circuit units adjacent in the first direction X may be connected by a first active connection line 10 and a second active connection line 20. For example, first regions 191 of ninth active layers 19 of ninth transistors T9 of circuit units adjacent in the first direction X may be interconnected by the first active connection line 10, and first regions 171 of seventh active layers 17 of seventh transistors T7 of circuit units adjacent in the first direction X may be interconnected by the second active connection line 20. The first active connection line 10 and the second active connection line 20 may extend at least in the first direction X. The first active connection line 10 may be located at a side of the fourth active layer 14 close to the third active layer 13, and the second active connection line 20 may be located at a side of the eighth active layer 18 away from the fifth active layer 15.

In some examples, the first active connection line 10 may be in a shape of a bending line with a main body portion extending in the first direction X. The first active connection line 10 and ninth active layers 19 of a plurality of circuit units may be interconnected to form an integral structure. Since the first regions 191 of the ninth active layers 19 are connected to a first reference signal line to be formed subsequently, the first active connection line 10 can also be used as a first reference signal line extending along the first direction X, which not only ensures that first regions 191 of a plurality of ninth active layers 19 in an unit row have a same potential, but also reduces a voltage drop of the first reference signal, which is conducive to improving uniformity of the base substrate, avoids poor display of the display substrate, and ensures a display effect of the display substrate.

In some examples, the second active connection line 20 may be in a shape of a straight line with a main body portion extending in the first direction X. The second active connection line 20 and seventh active layers 17 of a plurality of circuit units may be interconnected to form an integral structure. Since the first regions 171 of the seventh active layers 17 are connected to a second initial signal line to be formed subsequently, the second active connection line 20 can also be used as a second initial signal line extending along the first direction X, which not only ensures that first regions 171 of a plurality of seventh active layers 17 in an unit row have a same potential, but also reduces a voltage drop of the second initial signal, which is conducive to improving the uniformity of the base substrate, avoids poor display of the display substrate, and ensures the display effect of the display substrate.

In some examples, edges of two first active connection lines 10 adjacent in the first direction X that are close to each other and an edge of the first region 191 of the ninth active layer 19 may form a first groove K1. The first groove K1 may be configured to accommodate a first protrusion of a second plate of a second capacitor, which is conducive to increasing arrangement space of the second capacitor.

In some examples, in at least one unit column, semiconductor layers in circuit units adjacent in the second direction Y may be spaced apart from each other. For example, the semiconductor layer of the first circuit unit of the (n−1)-th unit row may not be connected to the semiconductor layer of the first circuit unit of the n-th unit row, and the semiconductor layer of the first circuit unit of the n-th unit row may not be connected to the semiconductor layer of the first circuit unit of the (n+1)-th unit row.

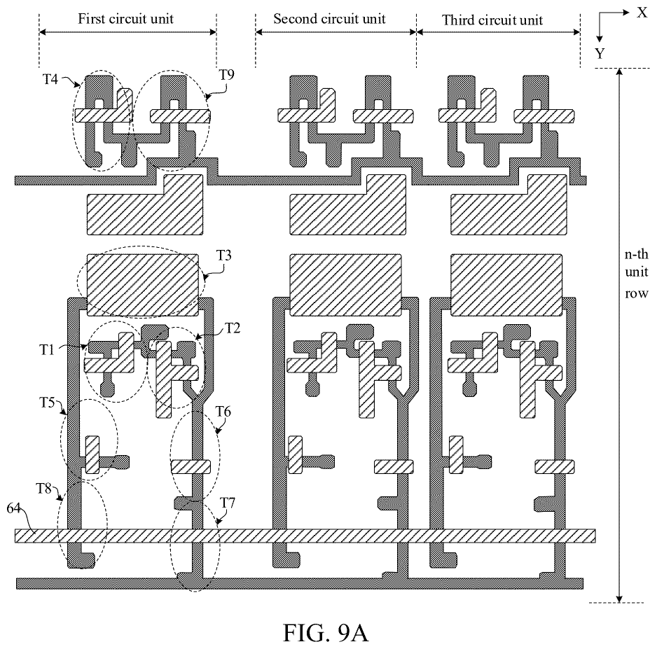

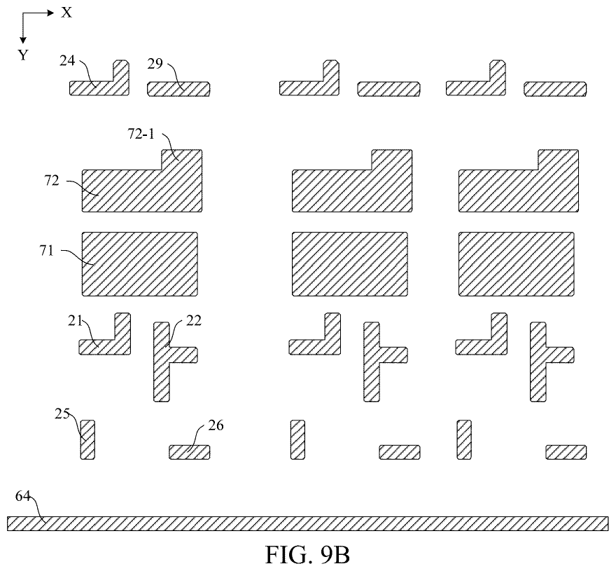

(1-2) A first conductive layer is formed. In some examples, a first insulation thin film and a first conductive thin film are sequentially deposited on the base substrate on which the above-mentioned patterns are formed, and the first conductive thin film is patterned by a patterning process to form a first insulation layer covering the semiconductor layer, and a first conductive layer disposed on the first insulation layer, as shown in FIGS. 9A and 9B. FIG. 9A is a schematic view of a display substrate after a first conductive layer is formed in FIG. 6. FIG. 9B is a schematic view of the first conductive layer in FIG. 9A. In some examples, the first conductive layer may also be referred to as a first gate metal (GATE1) layer.

In some examples, the first conductive layer of each circuit unit in the display substrate may at least include a first gate electrode 21 of the first transistor T1, a second gate electrode 22 of the second transistor T2, a fourth gate electrode 24 of the fourth transistor T4, a fifth gate electrode 25 of the fifth transistor T5, a sixth gate electrode 26 of the sixth transistor T6, a ninth gate electrode 29 of the ninth transistor T9, a fourth scan signal line 64, a first plate 71 of the first capacitor, and a second plate 72 of the second capacitor.

In some examples, the first gate electrode 21 may be substantially in a shape of an “L”, the first gate electrode 21 may be located at a side of the first plate 71 of the first capacitor in the second direction Y, and a region where the first gate electrode 21 overlaps with the first active layer may serve as a gate electrode of the first transistor T1 with a double gate structure.

In some examples, the second gate electrode 22 may be substantially in a shape of a “T”, the second gate electrode 22 may be located at a side of the first plate 71 of the first capacitor in the second direction Y, and a region where the second gate electrode 22 overlaps with the second active layer may serve as a gate electrode of the second transistor T2 with a double gate structure.

In some examples, the fourth gate electrode 24 may be substantially in a shape of an “L”, the fourth gate electrode 24 may be located at a side of the second plate 72 of the second capacitor in the opposite direction of the second direction Y, and a region where the fourth gate electrode 24 overlaps with the fourth active layer may serve as a gate electrode of the fourth transistor T4 with a double gate structure.

In some examples, the fifth gate electrode 25 may be substantially in a shape of a strip extending along the second direction Y, the fifth gate electrode 25 may be located at a side of the first gate electrode 21 in the second direction Y, and a region where the fifth gate electrode 25 overlaps with the fifth active layer may serve as a gate electrode of the fifth transistor T5.

In some examples, the sixth gate electrode 26 may be substantially in a shape of a strip extending along the first direction X, the sixth gate electrode 26 may be located at a side of the second gate electrode 22 in the second direction Y, and a region where the sixth gate electrode 26 overlaps with the sixth active layer may serve as a gate electrode of the sixth transistor T6.

In some examples, the ninth gate electrode 29 may be substantially in a shape of a strip extending along the first direction X, the ninth gate electrode 29 may be located at a side of the second plate 72 of the second capacitor in the opposite direction of the second direction Y, and a region where the ninth gate electrode 29 overlaps with the ninth active layer may serve as a gate electrode of the ninth transistor T9 with a double gate structure.

In some examples, the fourth scan signal line 64 may be in a shape of a straight line with a main body portion extending along the first direction X, and the fourth scan signal line 64 may be located at a side of the fifth gate electrode 25 and the sixth gate electrode 26 in the second direction Y. A region where the fourth scan signal line 64 overlaps with the seventh active layer may serve as a gate electrode of the seventh transistor T7, and a region where the fourth scan signal line 64 overlaps with the eighth active layer may serve as a gate electrode of the eighth transistor T8.

In some examples, the first plate 71 of the first capacitor may be in a shape of a rectangle, and corners of the rectangle may be provided with chamfers. An orthographic projection of the first plate 71 on the base substrate and an orthographic projection of the third active layer of the third transistor T3 on the base substrate may at least partially overlap, and the first plate 71 may simultaneously serve as a lower plate of the first capacitor and a gate electrode of the third transistor T3.

In some examples, the second plate 72 of the second capacitor may be in a shape of a rectangle, and corners of the rectangle may be provided with chamfers. The second plate 72 may be located at a side of the first plate 71 in the opposite direction of the second direction Y, and at a side of the fourth gate electrode 24 and the ninth gate electrode 29 in the second direction Y. That is, in the second direction Y, the second plate 72 may be located between the first plate 71 and the fourth gate electrode 24 (or the ninth gate electrode 29), and an orthographic projection of the second plate 72 on the base substrate and an orthographic projection of the semiconductor layer on the base substrate may not overlap. The second plate 72 may serve as a lower plate of the second capacitor. A first protrusion 72-1 is provided on a side of the second plate 72 close to the ninth gate electrode 29, and the first protrusion 72-1 may be substantially rectangular. The first protrusion 72-1 has a first end which is connected to the second plate 72, and a second end which extends towards the ninth gate electrode 29 and extends into the first groove K1. The second plate 72 and the first protrusion 72-1 may be interconnected to form an integral structure.

In some examples, a first side edge (e.g., a right side edge) of the first plate 71 in the first direction X and a first side edge (e.g., a right side edge) of the second plate 72 in the first direction X may be substantially aligned in the second direction Y, and a second side edge (e.g., a left side edge) of the first plate 71 in the first direction X and a second side edge (e.g., a left side edge) of the second plate 72 in the first direction X may be substantially aligned. A first side edge (e.g., a right side edge) of the first protrusion 72-1 in the first direction X and a first side edge (e.g., a right side edge) of the second plate 72 in the first direction X may be flush with each other in the second direction Y. The integral structure formed by connecting the second plate 72 and the first protrusion 72-1 to each other may be substantially in a shape of an “L”.

In some examples, areas of orthographic projections of the first plate 71 and the second plate 72 on the base substrate may be same or may be different. For example, the area of the orthographic projection of the second plate 72 on the base substrate may be smaller than the area of the orthographic projection of the first plate 71 on the base substrate.

In some examples, after the pattern of the first conductive layer is formed, the semiconductor layer may be subjected to a conductive treatment by using the first conductive layer as a shield. The semiconductor layer in a region, which is shielded by the first conductive layer, forms channel regions of the first transistor T1 to the ninth transistor T9, and the semiconductor layer in a region, which is not shielded by the first conductive layer, is made to be conductive, that is, first regions and second regions of the first active layer 11 to the ninth active layer 19, the first active connection line 10 and the second active connection line 20 may be all made to be conductive.

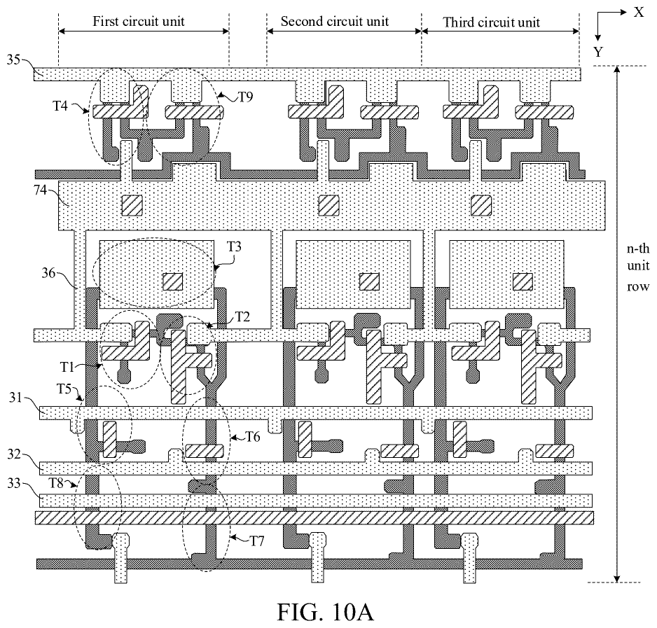

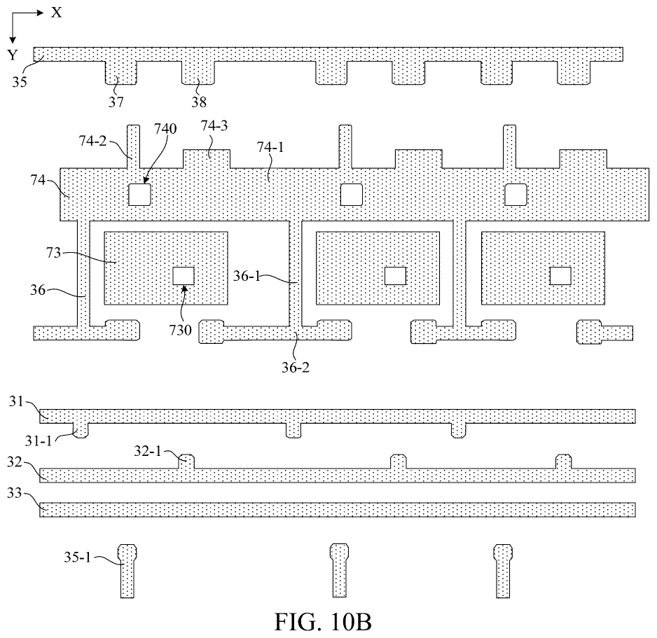

(1-3) A second conductive layer is formed. In some examples, a second insulation thin film and a second conductive thin film are sequentially deposited on the base substrate on which the above-mentioned patterns are formed, and the second conductive thin film is patterned using a patterning process to form a second insulation layer covering the first conductive layer and a second conductive layer disposed on the second insulation layer, as shown in FIGS. 10A and 10B. FIG. 10A is a schematic diagram of a display substrate after a second conductive layer is formed in FIG. 10. FIG. 10B is a schematic view of the second conductive layer in FIG. 10A. In some examples, the second conductive layer may be referred to as a second gate metal (GATE2) layer.

In some examples, the second conductive layer of each circuit unit in the display substrate may at least include a first light emitting signal line 31, a second light emitting signal line 32, a repair line 33, a second reference signal line 35, a first shielding electrode 36, a second shielding electrode 37, a third shielding electrode 38, a third plate 73 of the first capacitor, and a fourth plate 74 of the second capacitor.

In some examples, the first light emitting signal line 31, the second light emitting signal line 32, the repair line 33, and the second reference signal line 35 may each be in a shape of a straight line with a main body portion extending in the first direction X. The first light emitting signal line 31, the second light emitting signal line 32, and the repair line 33 may be located between the first gate electrode 21 and the fourth scan signal line 64, and the second reference signal line 35 may be located at a side of the fourth gate electrode 24 in the opposite direction of the second direction Y.

In some examples, the first light emitting signal line 31 may be located at a side of the first gate electrode 21 of the present circuit unit in the second direction Y, the second light emitting signal line 32 may be located at a side of the first light emitting signal line 31 in the second direction Y, and the repair line 33 may be located at a side of the second light emitting signal line 32 in the second direction Y, that is, the second light emitting signal line 32 may be located between the first light emitting signal line 31 and the repair line 33.

In some examples, a first light emitting connection block 31-1 may be provided on a side of the first light emitting signal line 31 close to the second light emitting signal line 32, and the first light emitting connection block 31-1 may be provided in each circuit unit. A first end of the first light emitting connection block 31-1 is connected to the first light emitting signal line 31, a second end of the first light emitting connection block 31-1 extends towards the second light emitting signal line 32, and the first light emitting connection block 31-1 may be configured to be connected to the fifth gate electrode 25 by a seventh connection electrode to be formed subsequently. In some examples, the first light emitting signal line 31 and a plurality of first light emitting connection blocks 31-1 may be interconnected to form an integral structure.

In some examples, a second light emitting connection block 32-1 may be provided on a side of the second light emitting signal line 32 close to the first light emitting signal line 31, and the second light emitting connection block 32-1 may be provided in each circuit unit. A first end of the second light emitting connection block 32-1 is connected to the second light emitting signal line 32, a second end of the second light emitting connection block 32-1 extends towards the first light emitting signal line 31, and the second light emitting connection block 32-1 may be configured to be connected to the sixth gate electrode 26 by an eighth connection electrode to be formed subsequently. In some examples, the second light emitting signal line 32 and a plurality of second light emitting connection blocks 32-1 may be interconnected to form an integral structure.

In some examples, a second reference connection block 35-1 may be provided on a side of the second reference signal line 35 of the n-th unit row away from the second plate 72 of the n-th unit row, and the second reference connection block 35-1 may be provided in each circuit unit. A first end of the second reference connection block 35-1 may be connected to the second reference signal line 35, and a second end of the second reference connection block 35-1 may extend in a direction away from the second plate 72, that is, extend towards the (n−1)-th unit row. In some examples, the second reference connection block 35-1 of the second reference signal line 35 in the n-th unit row is configured to be connected to the first region of the eighth active layer in the (n−1)-th unit row by a sixth connection electrode to be formed subsequently and provide a second reference signal to a first electrode of the eighth transistor T8 in the (n−1)-th unit row. In some examples, the second reference signal line 35 and a plurality of second reference connection blocks 35-1 may be interconnected to form an integral structure.

In some examples, a contour of the third plate 73 of the first capacitor may be in a shape of a rectangle, corners of the rectangle may be provided with chamfers, and the third plate 73 may be located between the first light emitting signal line 31 and the second reference signal line 35 of the present circuit unit. An orthographic projection of the third plate 73 on the base substrate may at least partially overlap with the orthographic projection of the first plate 71 on the base substrate. The third plate 73 may serve as an upper plate of the first capacitor (i.e., a second end of the first capacitor C1), and the first plate 71 and the third plate 73 may constitute the first capacitor C1 of the pixel circuit.

In some examples, a contour of the fourth plate 74 of the second capacitor may be in a shape of a rectangle, corners of the rectangle may be provided with chamfers, and the fourth plate 74 may be located between the second reference signal line 35 and the third plate 73 of the present circuit unit. An orthographic projection of the fourth plate 74 on the base substrate and the orthographic projection of the second plate 72 on the base substrate may at least partially overlap, the fourth plate 74 may serve as an upper plate of the second capacitor (i.e., a first end of the second capacitor C2), and the second plate 72 and the fourth plate 74 may constitute the second capacitor C2 of the pixel circuit.

In some examples, areas of orthographic projections of the third plate 73 and the fourth plate 74 on the base substrate may be the same or different. For example, the area of the orthographic projection of the fourth plate 74 on the base substrate may be smaller than the area of the orthographic projection of the third plate 73 on the base substrate.

In some examples, the fourth plate 74 may be provided with a first plate connection line 74-1 on a side in the first direction X or in an opposite direction of the first direction X. A first end of the first plate connection line 74-1 is connected to the fourth plate 74 of the present circuit unit, and a second end of the first plate connection line 74-1, after extending in the first direction X or in an opposite direction of the first direction X, is connected to a fourth plate 74 in an adjacent circuit unit, so that fourth plates 74 of adjacent circuit units on a unit row can be connected to each other. In some examples, a plurality of fourth plates 74 and a plurality of first plate connection lines 74-1 may be interconnected to form an integral structure. For example, a length of the first plate connection line 74-1 in the second direction Y may be substantially the same as a length of the fourth plate 74 in the second direction Y. Since the fourth plate 74 is connected to a first power supply line to be formed subsequently, fourth plates 74 of an integral structure of a plurality of circuit units can also be used as a lateral power supply line extending along the first direction X, which not only ensures that the plurality of fourth plates 74 in one unit row have a same potential, but also reduces a voltage drop of the first power supply signal, which is conducive to improving uniformity of the display substrate, avoiding poor display of the display substrate, and ensuring the display effect of the display substrate.

In some examples, a first opening 730 may be provided in the third plate 73 of each circuit unit, the first opening 730 may be located in the middle of the third plate 73, and the first opening 730 may be rectangular so that the third plate 73 forms an annular structure. The first opening 730 may expose the second insulation layer covering the first plate 71, and the orthographic projection of the first plate 71 on the base substrate may include an orthographic projection of the first opening 730 on the base substrate. In some examples, the first opening 730 may be configured to accommodate a tenth via to be formed subsequently, which may be located within the first opening 730 and expose a portion of a surface of the first plate 71, so that a first connection electrode to be formed subsequently is connected to the first plate 71.

In some examples, a second opening 740 may be provided in the fourth plate 74 of each circuit unit, the second opening 740 may be located in the middle of the fourth plate 74, and the second opening 740 may be rectangular so that the fourth plate 74 forms an annular structure. The second opening 740 may expose the second insulation layer covering the second plate 72, and the orthographic projection of the second plate 72 on the base substrate may include an orthographic projection of the second opening 740 on the base substrate. In some examples, the second opening 740 may be configured to accommodate an eleventh via to be formed subsequently, which may be located within the second opening 740 and expose a portion of a surface of the second plate 72, so that a third connection electrode to be formed subsequently is connected to the second plate 72. In some examples, the second opening 740 is not aligned with the first opening 730 in the second direction Y.

In some examples, a second protrusion 74-2 may be provided on a side of the fourth plate 74 close to the second reference signal line 35, and the second protrusion 74-2 may be provided in each circuit unit. The second protrusion 74-2 may be located at a side of the second opening 740 in the opposite direction of the second direction Y. A first end of the second protrusion 74-2 is connected to the fourth plate 74, and a second end of the second protrusion 74-2 extends towards the second reference signal line 35. An orthographic projection of the second protrusion 74-2 on the base substrate may be located between the first region and the second region of the fourth active layer of the present circuit unit. The second protrusion 74-2 of this example may be configured to shield an influence of data voltage jump on the fifth node, thereby preventing the data voltage jump from affecting normal operation of the pixel circuit, and improving the display effect. In some examples, the fourth plate 74 and the second protrusion 74-2 may be interconnected to form an integral structure.

In some examples, a third protrusion 74-3 may be provided on a side of the fourth plate 74 close to the second reference signal line 35. The third protrusion 74-3 may be provided in each circuit unit. The second protrusion 74-2 and the third protrusion 74-3 may be adjacent in the first direction X. For example, the third protrusion 74-3 may be located at a side of the second protrusion 74-2 in the first direction X. A first end of the third protrusion 74-3 is connected to the fourth plate 74, and a second end of the third protrusion 74-3 extends towards the second reference signal line 35 and extends into the first groove K1. An orthographic projection of the third protrusion 74-3 on the base substrate and an orthographic projection of the first protrusion 72-1 of the second plate 72 on the base substrate may at least partially overlap, for example, the two orthographic projections may coincide with each other. For example, a length of the second protrusion 74-2 in the second direction Y may be greater than a length of the third protrusion 74-3 in the second direction Y, and a length of the second protrusion 74-2 in the first direction X may be less than a length of the third protrusion 74-3 in the first direction X. In this example, by setting the third protrusion 74-3 at least partially overlapping with the first protrusion 72-1, an area of the second capacitor can be increased, and total capacity of the second capacitor can be effectively increased, thereby improving working performance of the pixel circuit and improving the display effect. In some examples, the fourth plate 74 and the third protrusion 74-3 may be interconnected to form an integral structure.

In some examples, the first shielding electrode 36 may be substantially in a shape of a “T”, the first shielding electrode 36 may be located on a side of the fourth plate 74 close to the first light emitting signal line 31, and the first shielding electrode 36 may be disposed in each circuit unit. The first shielding electrode 36 in a shape of a “T” may include a first extension segment 36-1 and a first shielding segment 36-2. A first end of the first extension segment 36-1 is connected to the fourth plate 74, and a second end of the first extension segment 36-1 is connected to the first shielding segment 36-2 after extending toward the first light emitting signal line 31. The first shielding segment 36-2 may be in a shape of a strip extending in the first direction X. The first shielding segment 36-2 may include a first shielding end located on a side of the first extension segment 36-1 in the first direction X and a second shielding end located on a side of the first extension segment 36-1 in an opposite direction of the first direction X. An orthographic projection of the first shielding end on the base substrate overlaps at least partially with an orthographic projection of the first active layer between the two gate electrodes of the first transistor T1 in the present circuit unit on the base substrate, and an orthographic projection of the second shielding end on the base substrate overlaps at least partially with an orthographic projection of a second active layer between two gate electrodes of the second transistor T2 in an adjacent circuit unit on the base substrate. In some examples, the first shielding electrode 36 may be configured to shield an influence of data voltage jump on the first transistor T1 and the second transistor T2, to prevent the data voltage jump from affecting normal operation of the pixel circuit, and to improve the display effect. In some examples, the fourth plate 74 and the first shielding electrode 36 may be interconnected to form an integral structure.

In some examples, the orthographic projection of the first shielding end of the first shielding segment 36-2 on the base substrate overlaps with an orthographic projection of the first region of the third active layer 13 of the third transistor (also the second region of the fifth active layer and the second region of the eighth active layer) in the present circuit unit on the base substrate. Since the first region of the third active layer 13 (also the second region of the fifth active layer and the second region of the eighth active layer) is a conductor layer on which the conductorization treatment has been performed, and the first shielding segment 36-2 is also a conductor layer, the first region of the third active layer 13 (also the second region of the fifth active layer and the second region of the eighth active layer) in one circuit unit and the first shielding end of the first shielding segment 36-2 of the first shielding electrode 36 of the present circuit unit can form a first voltage stabilizing capacitor. Since the first shielding electrode 36 can subsequently be connected to the first power supply connection line to receive a stabilized first power supply signal with a constant voltage, the first voltage stabilizing capacitor can be configured to stabilize a potential of the second node N2, thereby preventing signal crosstalk and avoiding an influence of data voltage jump on the second node N2, thereby ensuring the normal operation of the pixel circuit and improving the display effect.

In some examples, an orthographic projection of the second shielding end of the first shielding segment 36-2 on the base substrate partially overlaps with an orthographic projection of a second region of a third active layer 13 of a third transistor (also the first region of the sixth active layer and the second region of the second active layer) in an adjacent circuit unit on the base substrate. Since the second region of the third active layer 13 (also the first region of the sixth active layer and the second region of the second active layer) is a conductor layer on which the conductorization treatment has been performed, and the first shielding segment 36-2 is also a conductor layer, the second region of the third active layer 13 (also the first region of the sixth active layer and the second region of the second active layer) in one circuit unit and the second shielding end of the first shielding segment 36-2 of the first shielding electrode 36 in an adjacent circuit unit can form a second voltage stabilizing capacitor. Since the first shielding electrode 36 can subsequently be connected to the first power supply connection line to receive a stabilized first power supply signal with a constant voltage, the second voltage stabilizing capacitor can be configured to stabilize a potential of the third node N3, thereby preventing signal crosstalk and avoiding an influence of data voltage jump on the third node N3, thereby ensuring the normal operation of the pixel circuit and improving the display effect.

In some examples, the second shielding electrode 37 and the third shielding electrode 38 may each have a shape of a rectangle, may be located on a side of the second reference signal line 35 close to the fourth plate 74, and the second shielding electrode 37 and the third shielding electrode 38 may be provided in each circuit unit. First ends of the second shielding electrode 37 and the third shielding electrode 38 are connected to the second reference signal line 35, and second ends of the second shielding electrode 37 and the third shielding electrode 38 may extend towards the fourth plate 74. An orthographic projection of the second shielding electrode 37 on the base substrate may at least partially overlap with an orthographic projection of a fourth active layer between two gate electrodes of the fourth transistor T4 in the present circuit unit on the base substrate. An orthographic projection of the third shielding electrode 38 on the base substrate may at least partially overlap with an orthographic projection of the ninth active layer between two gate electrodes of the ninth transistor T9 in the present circuit unit on the base substrate. In some examples, the second shielding electrode 37 may be configured to shield an influence of data voltage jump on the fourth transistor T4, and the third shielding electrode 38 may be configured to shield an influence of the data voltage jump on the ninth transistor T9, so as to prevent the data voltage jump from affecting the normal operation of the pixel circuit and improve the display effect.

In some examples, the repair line 33 may be located at a side of the second light emitting control line 32 away from the first light emitting control line 31. For example, the repair line 33 may be configured to repair a sub-pixel that has a bad bright spot to a dark spot by inputting a signal to an anode of the sub-pixel that has a bad bright spot via the repair line 33 when the display substrate has a bad bright spot.

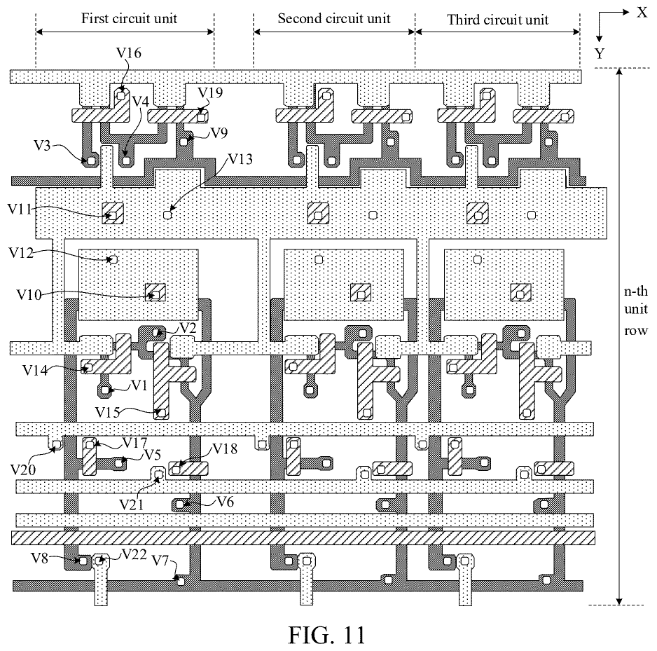

(1-4) A third insulation layer is formed. In some examples, a third insulation thin film is deposited on the base substrate on which the above-mentioned patterns are formed, and the third insulation thin film is patterned using a patterning process to form a third insulation layer. A plurality of vias are provided in the third insulation layer of each circuit unit, as shown in FIG. 11. FIG. 11 is a schematic view of a display substrate after a third insulation layer is formed in FIG. 6.

In some examples, the plurality of vias of each circuit unit in the display substrate may at least include a first via V1, a second via V2, a third via V3, a fourth via V4, a fifth via V5, a sixth via V6, a seventh via V7, an eighth via V8, a ninth via V9, a tenth via V10, an eleventh via V11, a twelfth via V12, a thirteenth via V13, a fourteenth via V14, a fifteenth via V15, a sixteenth via V16, a seventeenth via V17, an eighteenth via V18, a nineteenth via V19, a twentieth via V20, a twenty-first via V21, and a twenty-second via V22.

In some examples, an orthographic projection of the first via V1 on the base substrate may be within a range of an orthographic projection of the first region of the first active layer on the base substrate. The third insulation layer, the second insulation layer, and the first insulation layer within the first via V1 may be etched away to expose a portion of a surface of the first region of the first active layer, and the first via V1 may be configured such that a first initial signal line to be formed subsequently is connected to the first region of the first active layer through the first via V1.

In some examples, an orthographic projection of the second via V2 on the base substrate may be within a range of an orthographic projection of the second region of the first active layer (also the first region of the second active layer) on the base substrate. The third insulation layer, the second insulation layer, and the first insulation layer within the second via V2 may be etched away to expose a portion of a surface of the second region of the first active layer (also the first region of the second active layer), and the second via V2 may be configured such that a first connection electrode to be formed subsequently is connected to the second region of the first active layer (also the first region of the second active layer) through the second via V2.

In some examples, an orthographic projection of the third via V3 on the base substrate may be within a range of an orthographic projection of the first region of the fourth active layer on the base substrate. The third insulation layer, the second insulation layer, and the first insulation layer within the third via V3 may be etched away to expose a portion of a surface of the first region of the fourth active layer, and the third via V3 may be configured such that a second connection electrode to be formed subsequently is connected to the first region of the fourth active layer through the third via V3.

In some examples, an orthographic projection of the fourth via V4 on the base substrate may be within a range of an orthographic projection of the second region of the fourth active layer (also the second region of the ninth active layer) on the base substrate. The third insulation layer, the second insulation layer, and the first insulation layer within the fourth via V4 may be etched away to expose a portion of a surface of the second region of the fourth active layer (also the second region of the ninth active layer), and the fourth via V4 may be configured such that a third connection electrode to be formed subsequently is connected to the second region of the fourth active layer (also the second region of the ninth active layer) through the fourth via V4.

In some examples, an orthographic projection of the fifth via V5 on the base substrate may be within a range of an orthographic projection of the first region of the fifth active layer on the base substrate. The third insulation layer, the second insulation layer, and the first insulation layer within the fifth via V5 may be etched away to expose a portion of a surface of the first region of the fifth active layer, and the fifth via V5 may be configured such that a fourth connection electrode to be formed subsequently is connected to the first region of the fifth active layer through the fifth via V5.

In some examples, an orthographic projection of the sixth via V6 on the base substrate may be within a range of an orthographic projection of the second region of the sixth active layer (also the second region of the seventh active layer) on the base substrate. The third insulation layer, the second insulation layer, and the first insulation layer within the sixth via V6 may be etched away to expose a portion of a surface of the second region of the sixth active layer (also the second region of the seventh active layer), and the sixth via V6 may be configured such that a fifth connection electrode to be formed subsequently is connected to the second region of the sixth active layer (also the second region of the seventh active layer) through the sixth via V6.

In some examples, an orthographic projection of the seventh via V7 on the base substrate may be within a range of an orthographic projection of the first region of the seventh active layer on the base substrate. The third insulation layer, the second insulation layer, and the first insulation layer within the seventh via V7 may be etched away to expose a portion of a surface of the first region of the seventh active layer, and the seventh via V7 may be configured such that a second initial signal line to be formed subsequently is connected to the first region of the seventh active layer through the seventh via V7.

In some examples, an orthographic projection of the eighth via V8 on the base substrate may be within a range of an orthographic projection of the first region of the eighth active layer on the base substrate. The third insulation layer, the second insulation layer, and the first insulation layer within the eighth via V8 may be etched away to expose a portion of a surface of the first region of the eighth active layer, and the eighth via V8 may be configured such that a sixth connection electrode to be formed subsequently is connected to the first region of the eighth active layer through the eighth via V8.

In some examples, an orthographic projection of the ninth via V9 on the base substrate may be within a range of an orthographic projection of the first region of the ninth active layer on the base substrate. The third insulation layer, the second insulation layer, and the first insulation layer within the ninth via V9 may be etched away to expose a portion of a surface of the first region of the ninth active layer, and the ninth via V9 may be configured such that a first reference signal line to be formed subsequently is connected to the first region of the ninth active layer through the ninth via V9.

In some examples, an orthographic projection of the tenth via V10 on the base substrate may be within a range of the orthographic projection of the first opening 730 of the third plate 73 on the base substrate. The third insulation layer and the second insulation layer within the tenth via V10 may be etched away to expose a portion of the surface of the first plate 71, and the tenth via V10 may be configured such that a first connection electrode to be formed subsequently is connected to the first plate 71 through the tenth via V10.

In some examples, an orthographic projection of the eleventh via V11 on the base substrate may be within a range of the orthographic projection of the second opening 740 of the fourth plate 74 on the base substrate. The third insulation layer and the second insulation layer within the eleventh via V11 may be etched away to expose a portion of a surface of the second plate 72, and the eleventh via V11 is configured such that a third connection electrode to be formed subsequently is connected to the second plate 72 through the eleventh via V11.

In some examples, an orthographic projection of the twelfth via V12 on the base substrate may be within a range of the orthographic projection of the third plate 73 on the base substrate. The third insulation layer within the twelfth via V12 may be etched away to expose a portion of a surface of the third plate 73, and the twelfth via V12 may be configured such that a third connection electrode to be formed subsequently is connected to the third plate 73 through the twelfth via V12.

In some examples, an orthographic projection of the thirteenth via V13 on the base substrate may be within a range of the orthographic projection of the fourth plate 74 on the base substrate. The third insulation layer within the thirteenth via V13 may be etched away to expose a portion of a surface of the fourth plate 74, and the thirteenth via V13 may be configured such that a first power supply connection line to be formed subsequently is connected to the fourth plate 74 through the thirteenth via V13.

In some examples, an orthographic projection of the fourteenth via V14 on the base substrate may be within a range of an orthographic projection of the first gate electrode 21 on the base substrate. The third insulation layer and the second insulation layer within the fourteenth via V14 may be etched away to expose a portion of a surface of the first gate electrode 21, and the fourteenth via V14 may be configured such that a first scan signal line to be formed subsequently is connected to the first gate electrode 21 through the fourteenth via V14.

In some examples, an orthographic projection of the fifteenth via V15 on the base substrate may be within a range of an orthographic projection of the second gate electrode 22 on the base substrate. The third insulation layer and the second insulation layer within the fifteenth via V15 may be etched away to expose a portion of a surface of the second gate electrode 22, and the fifteenth via V15 may be configured such that a second scan signal line to be formed subsequently is connected to the second gate electrode 22 through the fifteenth via V15.

In some examples, an orthographic projection of the sixteenth via V16 on the base substrate may be within a range of an orthographic projection of the fourth gate electrode 24 on the base substrate. The third insulation layer and the second insulation layer within the sixteenth via V16 may be etched away to expose a portion of a surface of the fourth gate electrode 24, and the sixteenth via V16 may be configured such that a third scan signal line to be formed subsequently is connected to the fourth gate electrode 24 through the sixteenth via V16.

In some examples, an orthographic projection of the seventeenth via V17 on the base substrate may be within a range of an orthographic projection of the fifth gate electrode 25 on the base substrate. The third insulation layer and the second insulation layer within the seventeenth via V17 may be etched away to expose a portion of a surface of the fifth gate electrode 25, and the seventeenth via V17 may be configured such that a seventh connection electrode to be formed subsequently is connected to the fifth gate electrode 25 through the seventeenth via V17.

In some examples, an orthographic projection of the eighteenth via V18 on the base substrate may be within a range of an orthographic projection of the sixth gate electrode 26 on the base substrate. The third insulation layer and the second insulation layer within the eighteenth via V18 may be etched away to expose a portion of a surface of the sixth gate electrode 26, and the eighteenth via V18 may be configured such that an eighth connection electrode to be formed subsequently is connected to the sixth gate electrode 26 through the eighteenth via V18.

In some examples, an orthographic projection of the nineteenth via V19 on the base substrate may be within a range of an orthographic projection of the ninth gate electrode 29 on the base substrate. The third insulation layer and the second insulation layer within the nineteenth via V19 may be etched away to expose a portion of a surface of the ninth gate electrode 29, and the nineteenth via V19 may be configured such that a fifth scan signal line to be formed subsequently is connected to the ninth gate electrode 29 through the nineteenth via V19.

In some examples, an orthographic projection of the twentieth via V20 on the base substrate may be within a range of an orthographic projection of the first light emitting connection block 31-1 of the first light emitting signal line 31 on the base substrate. The third insulation layer within the twentieth via V20 may be etched away to expose at least a portion of a surface of the first light emitting connection block 31-1, and the twentieth via V20 may be configured such that a seventh connection electrode to be formed subsequently is connected to the first light emitting connection block 31-1 through the twentieth via V20.

In some examples, an orthographic projection of the twenty-first via V21 on the base substrate may be within a range of an orthographic projection of the second light emitting connection block 32-1 of the second light emitting signal line 32 on the base substrate. The third insulation layer within the twenty-first via V21 may be etched away to expose at least a portion of a surface of the second light emitting connection block 32-1, and the twenty-first via V21 may be configured such that an eighth connection electrode to be formed subsequently is connected to the second light emitting connection block 32-1 through the twenty-first via V21.

In some examples, an orthographic projection of the twenty-second via V22 on the base substrate may be within a range of an orthographic projection of the second reference connection block 35-1 of the second reference signal line 35 on the base substrate. The third insulation layer within the twenty-second via V22 is etched away to expose a surface of the second reference connection block 35-1, and the twenty-second via V22 may be configured such that a sixth connection electrode to be formed subsequently is connected to the second reference connection block 35-1 through the twenty-second via V22.

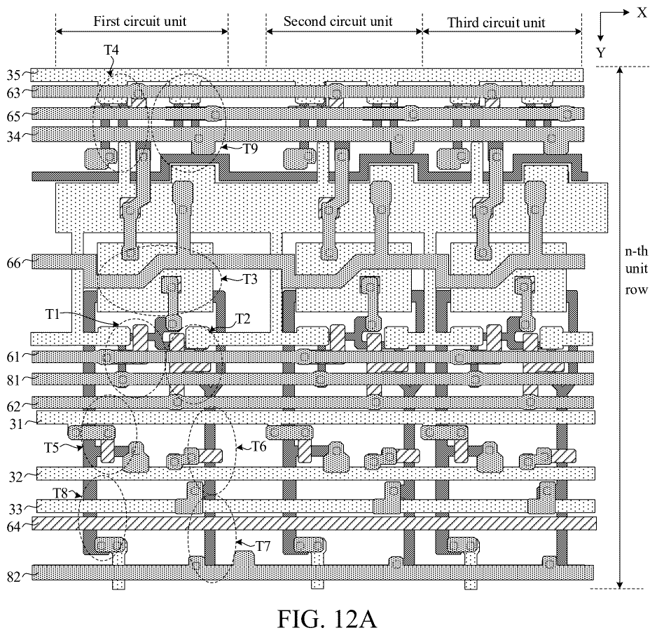

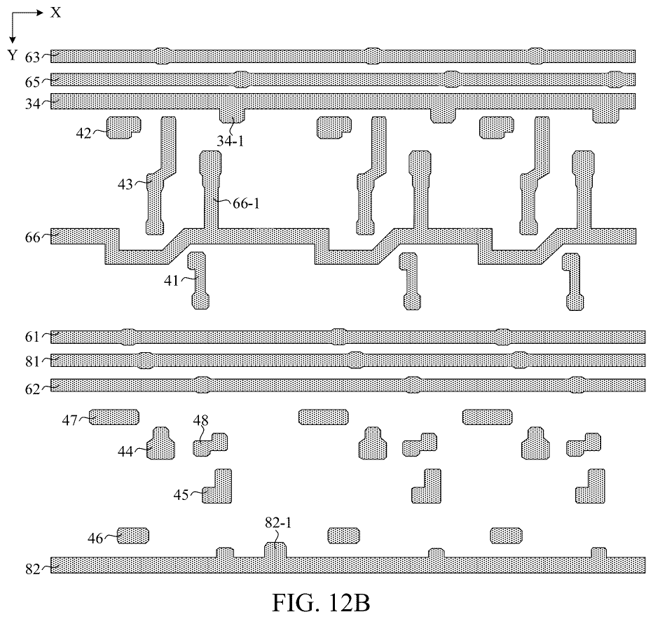

(1-5) A third conductive layer is formed. In some examples, a third conductive thin film is deposited on the base substrate on which the above-mentioned patterns are formed, and the third conductive thin film is patterned using a patterning process to form a third conductive layer disposed on the third insulation layer, as shown in FIGS. 12A and 12B. FIG. 12A is a schematic diagram of a display substrate after a third conductive layer is formed in FIG. 6. FIG. 12B is a schematic view of the third conductive layer in FIG. 12A. In some examples, the third conductive layer may be referred to as a first source-drain metal (SD1) layer.

In some examples, third conductive layers of the plurality of circuit units in the display substrate may each include a first connection electrode 41, a second connection electrode 42, a third connection electrode 43, a fourth connection electrode 44, a fifth connection electrode 45, a sixth connection electrode 46, a seventh connection electrode 47, an eighth connection electrode 48, a first scan signal line 61, a second scan signal line 62, a third scan signal line 63, a fifth scan signal line 65, a first power supply connection line 66, a first initial signal line 81, a second initial signal line 82, and a first reference signal line 34.

In some examples, the first scan signal line 61, the second scan signal line 62, the third scan signal line 63, the fifth scan signal line 65, the first initial signal line 81, the second initial signal line 82, and the first reference signal line 34 may be in a shape of a straight line with a main body portion extending in the first direction X. The first power supply connection line 66 may be in a shape of a bending line with a main body portion extending in the first direction X. The third scan signal line 63, the fifth scan signal line 65, and the first reference signal line 34 may be located at a side of the fourth plate 74 in the opposite direction of the second direction Y. The first scan signal line 61, the second scan signal line 62, the first initial signal line 81, and the second initial signal line 82 may be located at a side of the third plate 73 in the second direction Y. The first power supply connection line 66 may be located in a region where the third plate 73 is located.

In some examples, the first reference signal line 34 may be located at a side of the fourth plate 74 in the opposite direction of the second direction Y, the fifth scan signal line 65 may be located at a side of the first reference signal line 34 in the opposite direction of the second direction Y, and the third scan signal line 63 may be located at a side of the fifth scan signal line 65 in the opposite direction of the second direction Y.

In some examples, the first scan signal line 61 may be located at a side of the third plate 73 in the second direction Y, the first initial signal line 81 may be located at a side of the first scan signal line 61 in the second direction Y, the second scan signal line 62 may be located at a side of the first initial signal line 81 in the second direction Y, and the second initial signal line 82 may be located at a side of the second scan signal line 62 in the second direction Y. The first initial signal line 81 may be located between the first scan signal line 61 and the second scan signal line 62.

In this example, by arranging the first initial signal line 81 in the third conductive layer, a resistance of the first initial signal line 81 can be reduced, and a transmission effect of the first initial signal can be ensured. By arranging the first initial signal line 81 between the first scan signal line 61 and the second scan signal line 62, a distance between the first initial signal line 81 and the channel region of the first active layer of the first transistor T1 can be reduced. The first initial signal line 81 can provide the first initial signal to the first transistor T1 for initialization processing through a shortest path, thereby facilitating reducing a length of the first region of the first active layer, so that load of the first initial signal line can be reduced, and the initialization effect can be optimized.

In this example, by disposing the second scan signal line 62 and the first initial signal line 81 in a same layer and disposing the second scan signal line 62 at a side of the first initial signal line 81 away from the first scan signal line 61, an overlapping capacitance between the second scan signal line 62 and the first initial signal line 81 can be reduced, and load of the second scan signal line 62 can be reduced, thereby reducing driving load of a scan driver to which the second scan signal line 62 is connected.

The first light emitting signal line 31 of this example may be located at a side of the second scan signal line 62 and the first initial signal line 81 in the second direction Y, and an orthographic projection of the second light emitting signal line 31 on the base substrate may not overlap with orthographic projections of the second scan signal line 62 and the first initial signal line 81 on the base substrate, which can reduce an overlapping capacitance between the first light emitting signal line 31 and the first initial signal line 81, and reduce load of the first light emitting signal line 31, thereby reducing driving load of a light emitting driver to which the first light emitting signal line 31 is connected.

In some examples, the first power supply connection line 66 may be located at a side of the fourth plate 74 close to the third plate 73, an orthographic projection of the first power supply connection line 66 on the base substrate and an orthographic projection of the third plate 73 on the base substrate may partially overlap, the first power supply connection line 66 may be configured to be connected to a first power supply line to be formed subsequently to form a high-voltage power supply grid structure of a mesh communication structure on the display substrate.

In some examples, the fifth scan signal line 65 may be connected to the ninth gate electrode 29 in each circuit unit through the nineteenth via V19, thereby realizing that the fifth scan signal line 65 is connected to the ninth gate electrode 29 of the ninth transistor T9, and the fifth scan signal line 65 may control turn-on and turn-off of the ninth transistor T9.

In some examples, the second scan signal line 62 may be connected to the second gate electrode 22 in each circuit unit through the fifteenth via V15, thereby realizing that the second scan signal line 62 is connected to the second gate electrode 22 of the second transistor T2, and the second scan signal line 62 may control turn-on and turn-off of the second transistor T2.

In some examples, the second scan signal line 62 and the fifth scan signal line 65 may be connected to a same gate drive circuit after extending to the bezel area, so as to output a same scan signal, that is, the second scan signal line 62 and the fifth scan signal line 65 output the same second scan signal.

In some examples, the first scan signal line 61 can be connected to the first gate electrode 21 in each circuit unit through the fourteenth via V14, thereby realizing that the first scan signal line 61 is connected to the first gate electrode 21 of the first transistor T1, and the first scan signal line 61 can control turn-on and turn-off of the first transistor T1.

In some examples, the third scan signal line 63 can be connected to the fourth gate electrode 24 in each circuit unit through the sixteenth via V16, thereby realizing that the third scan signal line 63 is connected to the fourth gate electrode 24 of the fourth transistor T4, and the third scan signal line 63 can control turn-on and turn-off of the fourth transistor T4.

In some examples, the first initial signal line 81 may be connected to the first region of the first active layer in each circuit unit through the first via V1, thereby realizing that the first initial signal line 81 is connected to the first electrode of the first transistor T1, and the first initial signal line 81 may write the first initial signal to the first electrode of the first transistor T1.

In some examples, the second initial signal line 82 may be connected to the first region of the seventh active layer in each circuit unit through the seventh via V7, thereby realizing that the second initial signal line 82 is connected to the first electrode of the seventh transistor T7, and the second initial signal line 82 may write the second initial signal to the first electrode of the seventh transistor T7.

In some examples, a second initial connection block 82-1 may be provided on a side of the second initial signal line 82 close to the second scan signal line 62, and the second initial connection block 82-1 may be located between two adjacent circuit units within at least one unit row. A first end of the second initial connection block 82-1 is connected to the second initial signal line 82, a second end of the second initial connection block 82-1 extends towards the second scan signal line 62, and the second initial connection block 82-1 may be configured to be connected to an initial signal connection line to be formed subsequently.

In some examples, the first reference signal line 34 may be connected to the first region of the ninth active layer in each circuit unit through the ninth via V9, thereby realizing that the first reference signal line 34 is connected to the first electrode of the ninth transistor T9, and the first reference signal line 34 may write the first reference signal to the first electrode of the ninth transistor T9.

In some examples, a first reference connection block 34-1 may be provided on a side of the first reference signal line 34 close to the first power supply connection line 66. A first end of the first reference connection block 34-1 is connected to the first reference signal line 34, a second end of the first reference connection block 34-1 extends towards the first power supply connection line 66, and the first reference connection block 34-1 may be configured to be connected to a reference signal connection line to be formed subsequently.

In some examples, the first power supply connection line 66 may be connected to the fourth plate 74 in each circuit unit through the thirteenth via V13, thereby realizing that the first power supply connection line 66 is connected to the fourth plate 74. Since the first power supply connection line 66 is connected to a first power supply line to be formed subsequently, the first power supply connection line 66 can write the first power supply signal to the upper plate of the second capacitor (i.e., the first end of the second capacitor).

In some examples, a first power supply connection block 66-1 may be provided on a side of the first power supply connection line 66 away from the first scan signal line 61. A first end of the first power supply connection block 66-1 is connected to the first power supply connection line 66, and a second end of the first power supply connection block 66-1 extends in a direction away from the first scan signal line 61. In some examples, the first power supply connection block 66-1 may be configured to be connected to the fourth plate 74 through the thirteenth via V13 on the one hand, and to be connected to a first power supply line to be formed subsequently on the other hand.

In some examples, the first connection electrode 41 may be in a shape of a strip with a main body portion extending in the second direction Y, and the first connection electrode 41 may be located between the first scan signal line 61 and the first power supply connection line 66. A first end of the first connection electrode 41 can be connected to the second region of the first active layer (also the first region of the second active layer) through the second via V2, and a second end of the first connection electrode 41 can be connected to the first plate 71 through the tenth via V10. In some examples, the first connection electrode 41 may cause the second electrode of the first transistor T1, the first electrode of the second transistor T2, the gate electrode of the third transistor T3, and the first plate 71 of the first capacitor (i.e., the first end of the first capacitor) to have a same potential, and the first connection electrode 41 may serve as a first node N1 of the pixel circuit.

In some examples, the second connection electrode 42 may be substantially rectangular, and the second connection electrode 42 may be located between the first reference signal line 34 and the first power supply connection line 66. The second connection electrode 42 may be connected to the first region of the fourth active layer through the third via V3. In some examples, the second connection electrode 42 may serve as the first electrode of the fourth transistor T4 and be configured to be connected to a data signal line to be formed subsequently.

In some examples, the third connection electrode 43 may be in a shape of a bending line with a main body portion extending in the second direction Y, and the third connection electrode 43 may be located between the first reference signal line 34 and the first power supply connection line 66. A first end of the third connection electrode 43 may be connected to the second region of the fourth active layer (also the second region of the ninth active layer) through the fourth via V4, a second end of the third connection electrode 43 may be connected to the third plate 73 through the twelfth via V12, and a third end of the third connection electrode 43 between the first end and the second end thereof may be connected to the second plate 72 through the eleventh via V11. In some examples, the third connection electrode 43 may cause the second electrode of the fourth transistor T4, the second electrode of the ninth transistor T9, the third plate 73 of the first capacitor (i.e., the second end of the first capacitor), and the second plate 72 of the second capacitor (i.e., the second end of the second capacitor) to have a same potential, and the third connection electrode 43 may serve as a fifth node N5 of the pixel circuit.

In some examples, the fourth connection electrode 44 may be substantially rectangular, and the fourth connection electrode 44 may be located between the second scan signal line 62 and the second initial signal line 82. The fourth connection electrode 44 may be connected to the first region of the fifth active layer through the fifth via V5. In some examples, the fourth connection electrode 44 may serve as the first electrode of the fifth transistor T5, and be configured to be connected to a first power supply line to be formed subsequently.

In some examples, the fifth connection electrode 45 may be substantially in a shape of an “L”, and the fifth connection electrode 45 may be located between the second scan signal line 62 and the second initial signal line 82. The fifth connection electrode 45 may be connected to the second region of the sixth active layer (also the second region of the seventh active layer) through the sixth via V6. In some examples, the fifth connection electrode 45 may serve as the second electrode of the sixth transistor T6 and the second electrode of the seventh transistor T7, and be configured to be connected to an anode connection electrode to be formed subsequently. In some examples, the sixth connection electrode 46 may be in a shape of a strip with a main body portion extending in the first direction X, and the sixth connection electrode 46 may be located between the second scan signal line 62 and the second initial signal line 82. A first end of the sixth connection electrode 46 may be connected to the first region of the eighth active layer through the eighth via V8, and a second end of the sixth connection electrode 46 may be connected to the second reference connection block 35-1 through the twenty-second via V22. In some examples, the sixth connection electrode 46 may serve as the first electrode of the eighth transistor T8, and since the second reference connection block 35-1 is connected to the second reference signal line 35, it is realized that the second reference signal line 35 is connected to the first electrode of the eighth transistor T8, and the second reference signal line 35 in the n-th unit row may write the second reference signal to the first electrode of the eighth transistor T8 in the (n−1)-th unit row.

In some examples, the seventh connection electrode 47 may be in a shape of a strip with a main body portion extending in the first direction X, and the seventh connection electrode 47 may be located between the second scan signal line 62 and the second initial signal line 82. A first end of the seventh connection electrode 47 may be connected to the fifth gate electrode 25 through the seventeenth via V17, and a second end of the seventh connection electrode 47 may be connected to the first light emitting connection block 31-1 through the twentieth via V20. Since the first light emitting connection block 31-1 is connected to the first light emitting signal line 31, it is realized that the first light emitting signal line 31 is connected to the fifth gate electrode 25 of the fifth transistor T5, and the first light emitting signal line 31 can control turn-on and turn-off of the fifth transistor T5.

In some examples, the eighth connection electrode 48 may be in a shape of a strip with a main body portion extending in the first direction X, and the eighth connection electrode 48 may be located between the second scan signal line 62 and the second initial signal line 82. A first end of the eighth connection electrode 48 may be connected to the sixth gate electrode 26 through the eighteenth via V18, and a second end of the eighth connection electrode 48 may be connected to the second light emitting connection block 32-1 through the twenty-first via V21. Since the second light emitting connection block 32-1 is connected to the second light emitting signal line 32, it is realized that the second light emitting signal line 32 is connected to the sixth gate electrode 26 of the sixth transistor T6, and the second light emitting signal line 32 can control turn-on and turn-off of the sixth transistor T6.

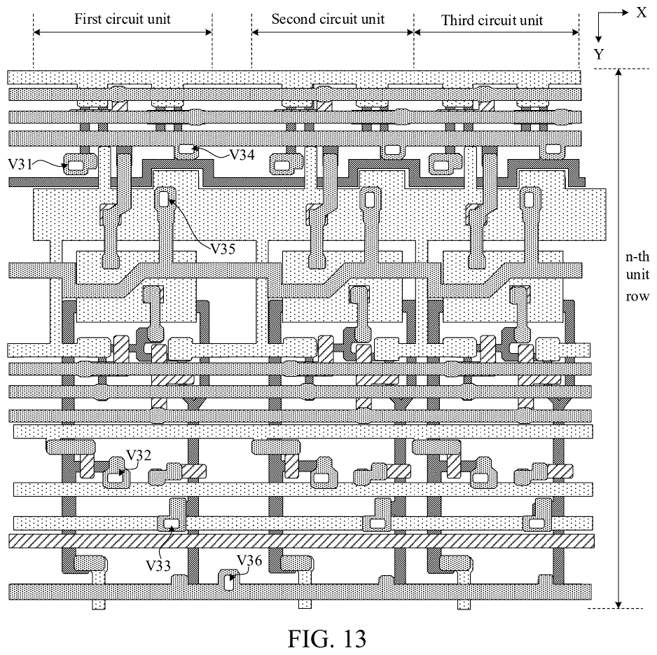

(1-6) A fourth insulation layer is formed. In some examples, a fourth insulation thin film is coated on the base substrate on which the above-mentioned patterns are formed, and the fourth insulation thin film is patterned using a patterning process to form a fourth insulation layer covering the third conductive layer. The fourth insulation layer in each circuit unit may be provided with a plurality of vias, as shown in FIG. 13. FIG. 13 is a schematic view of a display substrate after a fourth insulation layer is formed in FIG. 6. In some examples, the fourth insulation layer may also be referred to as a first planarization layer.

In some examples, the plurality of vias of each circuit unit in the display substrate may at least include a thirty-first via V31, a thirty-second via V32, a thirty-third via V33, a thirty-fourth via V34, and a thirty-fifth via V35.

In some examples, an orthographic projection of the thirty-first via V31 on the base substrate may be within a range of an orthographic projection of the second connection electrode 42 on the base substrate. The fourth insulation layer within the thirty-first via V31 may be removed to expose a portion of a surface of the second connection electrode 42, and the thirty-first via V31 may be configured such that a data signal line to be formed subsequently is connected to the second connection electrode 42 through the thirty-first via V31.

In some examples, an orthographic projection of the thirty-second via V32 on the base substrate may be within a range of an orthographic projection of the fourth connection electrode 44 on the base substrate. The fourth insulation layer within the thirty-second via V32 may be removed to expose a portion of a surface of the fourth connection electrode 44, and the thirty-second via V32 may be configured such that a first power supply line to be formed subsequently is connected to the fourth connection electrode 44 through the thirty-second via V32.

In some examples, an orthographic projection of the thirty-third via V33 on the base substrate may be within a range of an orthographic projection of the fifth connection electrode 45 on the base substrate. The fourth insulation layer within the thirty-third via V33 may be removed to expose a portion of a surface of the fifth connection electrode 45, and the thirty-third via V33 may be configured such that an anode connection electrode to be formed subsequently is connected to the fifth connection electrode 45 through the thirty-third via V33.

In some examples, an orthographic projection of the thirty-fourth via V34 on the base substrate may be within a range of an orthographic projection of the first reference connection block 34-1 of the first reference signal line 34 on the base substrate. The fourth insulation layer within the thirty-fourth via V34 may be removed to expose a portion of a surface of the first reference connection block 34-1, and the thirty-fourth via V34 may be configured such that a reference signal connection line to be formed subsequently is connected to the first reference connection block 34-1 through the thirty-fourth via V34.

In some examples, an orthographic projection of the thirty-fifth via V35 on the base substrate may be within a range of an orthographic projection of the first power supply connection block 66-1 of the first power supply connection line 66 on the base substrate. The fourth insulation layer within the thirty-fifth via V35 may be removed to expose a portion of a surface of the first power supply connection block 66-1, and the thirty-fifth via V35 may be configured such that a first power supply line to be formed subsequently is connected to the first power supply connection block 66-1 through the thirty-fifth via V35.

In some examples, the at least one circuit unit may further include a thirty-sixth via V36. An orthographic projection of the thirty-sixth via V36 on the base substrate may be within a range of an orthographic projection of the second initial connection block 82-1 of the second initial signal line 82 on the base substrate, the fourth insulation layer within the thirty-sixth via V36 is removed to expose a portion of a surface of the second initial connection block 82-1, and the thirty-sixth via V36 may be configured such that an initial signal connection line to be formed subsequently is connected to the second initial connection block 82-1 through the thirty-sixth via V36. In some examples, the thirty-sixth via V36 may be located between the first circuit unit and the second circuit unit.

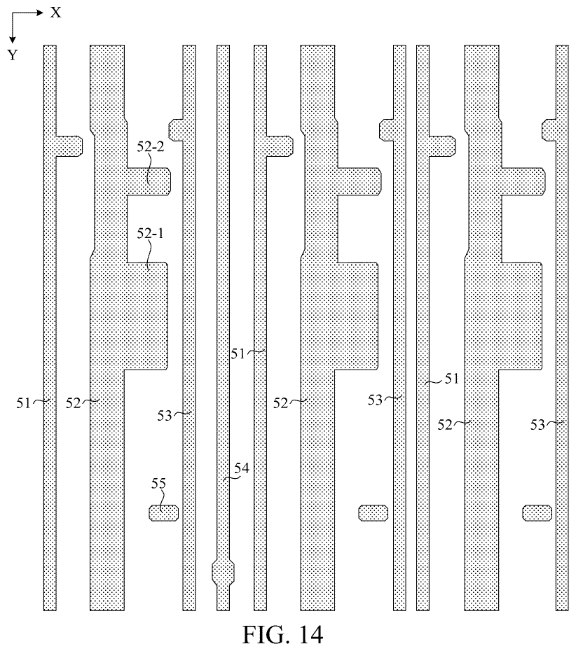

(1-7) A fourth conductive layer is formed. In some examples, a fourth conductive thin film is deposited on the base substrate on which the above-mentioned patterns are formed, and the fourth conductive thin film is patterned using a patterning process to form a fourth conductive layer disposed on the fourth insulation layer, as shown in FIG. 14. FIG. 14 is a schematic view of a fourth conductive layer in FIG. 6. In some examples, the fourth conductive layer may be referred to as a second source-drain metal (SD2) layer.

In some examples, fourth conductive layers of the plurality of circuit units in the display substrate may each include a data signal line 51, a first power supply line 52, a reference signal connection line 53, and an anode connection electrode 55.

In some examples, the data signal line 51, the first power supply line 52, and the reference signal connection line 53 may each be in a shape of a strip with a main body portion extending in the second direction Y. The first power supply line 52 may be located at a side of the data signal line 51 in the first direction X, and the reference signal connection line 53 may be located at a side of the first power supply line 52 in the first direction X, that is, the first power supply line 52 may be located between the data signal line 51 and the reference signal connection line 53.

In some examples, the data signal line 51 may be in a shape of a straight line with a main body portion extending in the second direction Y, and the data signal line 51 may be connected to the second connection electrode 42 through the thirty-first via V31. Since the second connection electrode 42 may be connected to the first region of the fourth active layer through a via, it is achieved that the data signal line 51 writes a data signal to the first electrode of the fourth transistor T4.

In some examples, the first power supply line 52 may be in a shape of a bending line with a main body portion extending in the second direction Y. The first power supply line 52 can be connected to the fourth connection electrode 44 through the thirty-second via V32 on the one hand, and connected to the first power supply connection block 66-1 through the thirty-fifth via V35 on the other hand. Since the fourth connection electrode 44 is connected to the first region of the fifth active layer through a via, it is realized that the first power supply line 52 writes the first power supply signal to the first electrode of the fifth transistor T5. Since the first power supply connection block 66-1 is connected to the first power supply connection line 66, it is realized that the first power supply connection line 66 with a main body portion extending along the first direction X and the first power supply line 52 with a main body portion extending along the second direction Y are connected to each other, so that the first power supply line 52 and the first power supply connection line 66 form a mesh structure for transmitting the first power supply signal on the display substrate, which not only can effectively reduce a resistance of the first power supply line 52, reduce a voltage drop of the first power supply signal, but also can effectively improve uniformity of the first power supply signal in the display substrate, effectively improve display uniformity of the, and improve display attribute and display quality.

In some examples, a power supply shield block 52-1 is provided on a side of the first power supply line 52 close to the reference signal connection line 53. A first end of the power supply shield block 52-1 is connected to the first power supply line 52, and a second end of the power supply shield block 52-1 extends towards the reference signal connection line 53. The power supply shield block 52-1 may be substantially rectangular, and an orthographic projection of the power supply shield block 52-1 on the base substrate may cover an orthographic projection of the first connection electrode 41 on the base substrate. Since the first connection electrode 41 serves as the first node N1 in the pixel circuit, the power supply shield block 52-1 with a constant voltage can effectively shield an influence of other signals in the pixel circuit on the first node N1, prevent other signals (such as data voltage jumps) from affecting a potential of the first node N1 of the pixel circuit, and improve the display effect. In some examples, the first power supply line 52 and the power supply shield block 52-1 may be interconnected to form an integral structure.

In some examples, a second power supply connection block 52-2 is provided on a side of the first power supply line 52 close to the reference signal connection line 53. The second power supply connection block 52-2 may be located at a side of the power supply shield block 52-1 in the opposite direction of the second direction Y. The second power supply connection block 52-2 may be substantially rectangular, and an orthographic projection of the second power supply connection block 52-2 on the base substrate and the orthographic projection of the fourth plate 74 on the base substrate may at least partially overlap. The second power supply connection block 52-2 can be connected to the first power supply connection block 66-1 through the thirty-fifth via V35 to realize connection between the first power supply line 52 and the first power supply connection line 66. A length of the second power supply connection block 52-2 in the second direction Y may be smaller than a length of the power supply shield block 52-1 in the second direction Y, and the length of the second power supply connection block 52-2 in the first direction X may be substantially the same as a length of the power supply shield block 52-1 in the first direction X. This embodiment is not limited thereto.

In some examples, an orthographic projection of the first power supply line 52 on the base substrate and an orthographic projection of the third connection electrode 43 on the base substrate may at least partially overlap. For example, the orthographic projection of the first power supply line 52 on the base substrate may cover the orthographic projection of the third connection electrode 43 on the base substrate. Since the third connection electrode 43 serves as the fifth node N5 in the pixel circuit, the first power supply line 52 with a constant voltage can effectively shield an influence of other signals in the pixel circuit on the fifth node N5, prevent other signals from affecting the potential of the fifth node N5 in the pixel circuit, and improve the display effect.

In some examples, the orthographic projection of the first power supply line 52 on the base substrate may cover the orthographic projection of the first region of the first active layer of the first transistor T1 on the base substrate. The orthographic projection of the first power supply line 52 on the base substrate may cover an orthographic projection of a position where the first region of the first active layer of the first transistor T1 is connected to the first initial signal line 81 on the base substrate. By providing the first power supply line 52 to shield the first region of the first active layer of the first transistor T1 connected to the first initial signal line 81, other signals can be prevented from affecting reception of the first initial signal by the first region of the first active layer of the first transistor T1, thereby a transmission accuracy of the first initial signal can be guaranteed, to ensure the initialization effect.

In some examples, the first power supply line 52 may have an unequal width design, and the first power supply line 52 with the unequal width design may not only facilitate a layout of the pixel structure, but also reduce a parasitic capacitance between the first power supply line 52 and the data signal line 51.

In some examples, the reference signal connection line 53 may be in a shape of a straight line with a main body portion extending in the second direction Y, and the reference signal connection line 53 may be connected to the first reference connection block 34-1 through the thirty-fourth via V34. Since the first reference connection block 34-1 is connected to the first reference signal line 34, it is realized that the first reference signal line 34 with the main body portion extending along the first direction X and the reference signal connection line 53 with the main body portion extending along the second direction Y are connected to each other, so that the first reference signal line 34 and the reference signal connection line 53 form a mesh structure for transmitting the first reference signal on the display substrate, which not only can effectively reduce a resistance of the first reference signal line and reduce a voltage drop of the first reference signal, but also can effectively improve uniformity of the first reference signal in the display substrate, effectively improve the display uniformity, and improve the display attribute and the display quality.

In some examples, the anode connection electrode 55 may be substantially rectangular. The anode connection electrode 55 may be located between the first power supply line 52 and the reference signal connection line 53. The anode connection electrode 55 may be connected to the fifth connection electrode 45 through the thirty-third via V33. Since the fifth connection electrode 45 is connected to the second region of the sixth active layer (also the second region of the seventh active layer) through a via, it is realized that the anode connection electrode 55 is connected to the second electrode of the sixth transistor T6 and the second electrode of the seventh transistor T7. In some examples, the anode connection electrode 55 may be configured to be connected to an anode to be formed subsequently, so it may be realized that the pixel circuit drives the light emitting device.

In some examples, an orthographic projection of the anode connection electrode 55 on the base substrate and an orthographic projection of the anode repair line 33 on the base substrate may at least partially overlap.

In some examples, an initial signal connection line 54 may further be included in the at least one circuit unit. The initial signal connection line 54 may be in a shape of a straight line with a main body portion extending in the second direction Y, and the initial signal connection line 54 may be connected to the second initial connection block 82-1 through the thirty-sixth via V36. Since the second initial connection block 82-1 is connected to the second initial signal line 82, it is realized that the second initial signal line 82 with the main body portion extending along the first direction X and the initial signal connection line 54 with the main body portion extending along the second direction Y are connected to each other, so that the initial signal connection line 54 and the second initial signal line 82 form a mesh structure for transmitting a second initial signal on the display substrate, which not only can effectively reduce a resistance of the second initial signal line 82, reduce a voltage drop of the second initial signal, but also can effectively improve uniformity of the second initial signal in the display substrate, effectively improve the display uniformity, and improve the display attribute and the display quality. In some examples, the initial signal connection line 54 may be located between the reference signal connection line 53 of the first circuit unit and the data signal line 51 of the second circuit unit.

In some examples, the first power supply connection line 66 of the third conductive layer may be provided in each unit row, the first power supply line 52 of the fourth conductive layer may be provided in each unit column, and a plurality of first power supply lines 52 may be connected to a plurality of first power supply connection lines 66 respectively, to form a mesh structure for transmitting the first power supply signal.

In some examples, the first reference signal line 34 of the third conductive layer may be provided in each unit row, the reference signal connection line 53 of the fourth conductive layer may be provided in each unit column, and a plurality of first reference signal lines 34 are connected to a plurality of reference signal connection lines 53 respectively to form a mesh structure for transmitting the first reference signal.

In some examples, the second initial signal line 82 of the third conductive layer may be provided in each unit row, the initial signal connection line 54 of the fourth conductive layer may be provided for every three unit columns, and a plurality of second initial signal lines 82 are connected to a plurality of initial signal connection lines 54 to form a mesh structure for transmitting the second initial signal.

A subsequent manufacturing process may include forming a pattern of a second planarization layer. The second planarization layer is provided with a plurality of anode vias, an orthographic projection of an anode via on the base substrate may be within a range of an orthographic projection of an anode connection electrode on the base substrate. The second planarization layer within the anode via is removed to expose at least a portion of a surface of the anode connection electrode, the anode via is configured such that an anode to be formed subsequently is connected to the anode connection electrode through the anode via.

Hereto, manufacturing of the drive circuit layer of this embodiment on the base substrate is completed. In some exemplary implementation modes, after manufacturing of the drive circuit layer is completed, a light emitting structure layer and an encapsulation structure layer may be sequentially manufactured on the drive circuit layer, which will not be repeated herein.

In some examples, the base substrate may be a flexible substrate, or may be a rigid substrate. The rigid substrate may be made of, but is not limited to, one or more of glass and quartz. The flexible substrate may be made of, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fiber. In some examples, the flexible substrate may include a first flexible material layer, a first inorganic material layer, a semiconductor layer, a second flexible material layer and a second inorganic material layer which are stacked. The first flexible material layer and the second flexible material layer may be made of polyimide (PI), polyethylene terephthalate (PET) or a surface-treated polymer soft film, or the like; and the first inorganic material layer and the second inorganic material layer may be made of silicon nitride (SiNₓ) or silicon oxide (SiOₓ), etc., thereby improving the water-resistance and oxygen-resistance of the substrate. The material of the semiconductor layer may be amorphous silicon (a-si).

In some examples, the first conductive layer, the second conductive layer, the third conductive layer, and the fourth conductive layer may be made of a metal material, such as any one or more of Argentum (Ag), Copper (Cu), Aluminum (Al), and Molybdenum (Mo), or an alloy material of the aforementioned metals, such as an Aluminum Neodymium alloy (AlNd) or a Molybdenum Niobium alloy (MoNb), and may be of a single-layer structure or a multi-layer composite structure, such as Mo/Cu/Mo and Ti/Al/Ti. For example, the first conductive layer and the second conductive layer may be made of a single layer of molybdenum metal, and the third conductive layer and the fourth conductive layer may be made of a three-layer laminated structure of Ti/Al/Ti. A resistivity of wirings of the third conductive layer and the fourth conductive layer may be smaller than a resistivity of wirings of the first conductive layer and the second conductive layer.

In some examples, the first insulation layer 201, the second insulation layer 202, and the third insulation layer 203 may be made of any one or more of Silicon Oxide (SiOₓ), Silicon Nitride (SiNₓ), and Silicon Oxynitride (SiON), and may be a single layer, a multi-layer, or a composite layer. The first insulation layer 201 and the second insulation layer 202 may also be referred to as Gate Insulation (GI) layers, and the third insulation layer 203 may also be referred to as an Interlayer Dielectric (ILD) layer. The fourth insulation layer 204 may also be referred to as a first planarization layer. The fourth insulation layer 204 and the second planarization layer may be made of an organic material, such as polyimide, acrylic, polyethylene terephthalate, etc. An active layer may be made of a material such as amorphous Indium Gallium Zinc Oxide (a-IGZO), Zinc Oxynitride (ZnON), Indium Zinc Tin Oxide (IZTO), amorphous Silicon (a-Si), poly-crystalline Silicon (p-Si), hexathiophene, or polythiophene. That is, the present disclosure is applicable to a transistor that is manufactured based on an oxide technology, a silicon technology, or an organic matter technology.

The structure and the manufacturing process of the display substrate of this embodiment are merely illustrative. In some examples, a corresponding structure may be changed and a patterning process may be added or reduced according to actual needs. The manufacturing process of this example may be implemented using an existing mature manufacturing equipment, and may be compatible well with an existing manufacturing process, simple in process implementation, easy to implement, high in production efficiency, low in production cost, and high in yield.

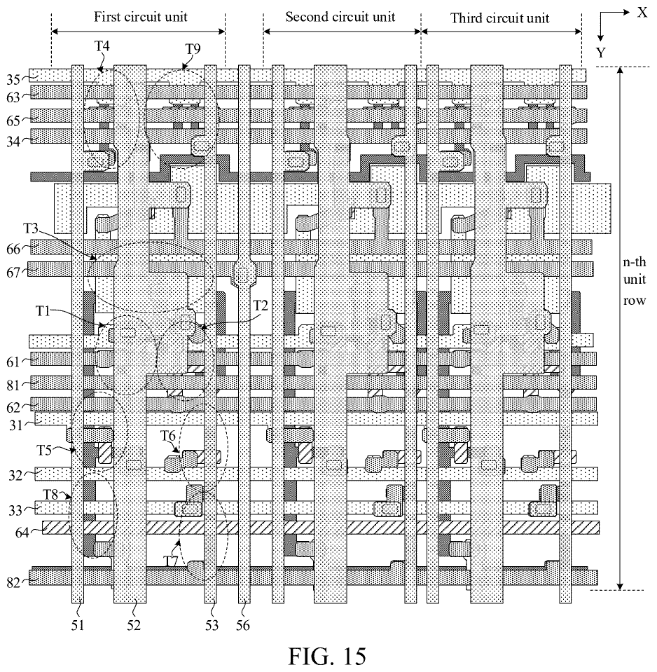

FIG. 15 is a schematic diagram of a planar structure of another display substrate according to at least one embodiment of the present disclosure. Structures of pixel circuits in three circuit units (i.e. a first circuit unit, a second circuit unit and a third circuit unit) in the display substrate are illustrated in FIG. 15.

In some examples, a first power supply line 52 extending in a second direction Y and a first power supply connection line 66 extending in a first direction X are interconnected to form a mesh structure for transmitting a first power supply signal. A second power supply line 56 extending in the second direction Y and a second power supply connection line 67 extending in the first direction X are interconnected to form a mesh structure for transmitting a second power supply signal. A reference signal connection line 53 extending in the second direction Y and a first reference signal line 34 extending in the first direction X are interconnected to form a mesh structure for transmitting a first reference signal.

In some examples, a third plate 73 of a first capacitor is provided with a second plate connection line 73-1 extending towards a fourth plate 74 of a second capacitor. The fourth plate 74 is provided with a second groove K2 recessed in a direction away from the third plate 73. The second plate connection line 73-1 is provided in the second groove K2, and an end portion of the second plate connection line 73-1 away from the third plate 73 can be connected to a second plate 72 through a via and a connection electrode. The plate structure design of the first capacitor and the second capacitor in this example can widen a distance between the first node N1 and the fifth node N5, and can increase arrangement space of lateral traces.

In some examples, at least one circuit unit may further include a first shielding electrode 36. The first shielding electrode 36 may include a first shielding end and a second shielding end. An orthographic projection of the first shielding end on the base substrate overlaps at least partially with an orthographic projection of a first active layer between two gate electrodes of a first transistor in the present circuit unit on the base substrate, and the first shielding end is electrically connected to a first power supply line 52 to which the pixel circuit of the present circuit unit is connected. An orthographic projection of the second shielding end on the base substrate overlaps at least partially with an orthographic projection of a second active layer between two gate electrodes of a second transistor in an adjacent circuit unit on the base substrate, and the second shielding end is electrically connected to the first power supply line 52 to which the pixel circuit of the adjacent circuit unit is connected.

In some examples, the manufacturing process of the display substrate of this example may include the following operations.

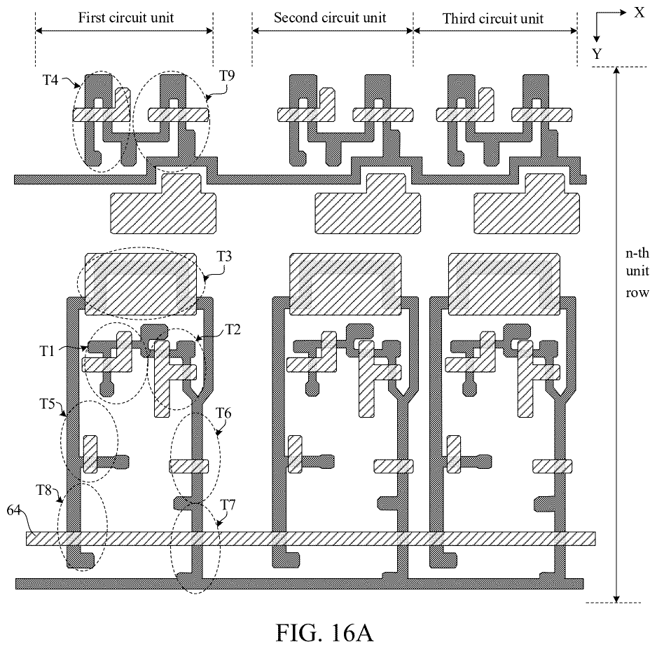

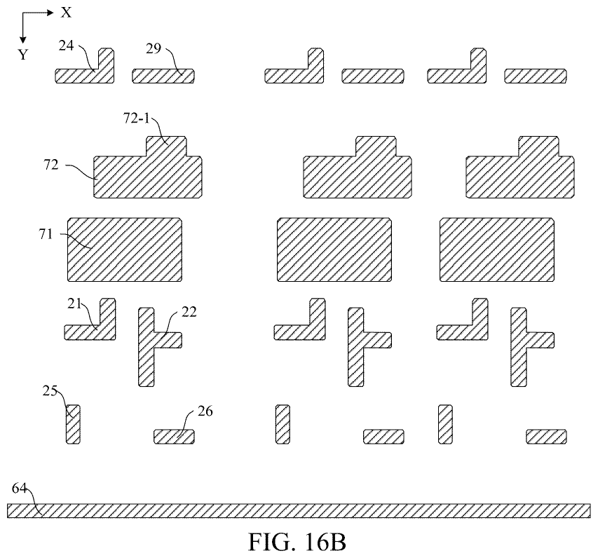

(2-1) A semiconductor layer is formed. In some examples, a semiconductor thin film is deposited on a base substrate, and the semiconductor thin film is patterned by a patterning process to form a semiconductor layer, as shown in FIG. 16A. FIG. 16A is a schematic view of a display substrate after a first conductive layer is formed in FIG. 15. The structure of the semiconductor layer of the display substrate of this example is the same as that of the semiconductor layer of the display substrate of the aforementioned embodiment, and will not be repeated here.

(2-2) A first conductive layer is formed. In some examples, a first insulation thin film and a first conductive thin film are sequentially deposited on the base substrate on which the above-mentioned patterns are formed, and the first conductive thin film is patterned by a patterning process to form a first insulation layer covering the semiconductor layer, and a first conductive layer disposed on the first insulation layer, as shown in FIGS. 16A and 16B. FIG. 16B is a schematic view of the first conductive layer in FIG. 16A.

In some examples, the first conductive layer of each circuit unit in the display substrate may at least include a first gate electrode 21 of the first transistor T1, a second gate electrode 22 of the second transistor T2, a fourth gate electrode 24 of a fourth transistor T4, a fifth gate electrode 25 of a fifth transistor T5, a sixth gate electrode 26 of a sixth transistor T6, a ninth gate electrode 29 of a ninth transistor T9, a fourth scan signal line 64, a first plate 71 of the first capacitor, and a second plate 72 of the second capacitor.

In some examples, the second plate 72 of the second capacitor 72 may be in a shape of a rectangle, corners of the rectangle may be provided with chamfers. A first protrusion 72-1 may be provided on a side of the second plate 72 close to the ninth gate electrode 29, the first protrusion 72-1 has a first end which is connected to the second plate 72, and a second end extending towards the ninth gate electrode 29 and extending into a first groove formed by the semiconductor layer. A first side edge (e.g., a right side edge) of the first plate 71 in the first direction X and a first side edge (e.g., a right side edge) of the second plate 72 in the first direction X may be misaligned in the second direction Y, for example, the right side edge of the second plate 72 in the first direction X may be located at a side of the right side edge of the first plate 71 in the first direction X in the first direction X. A second side edge (e.g., a left side edge) of the first plate 71 in the first direction X and a second side edge (e.g., a left side edge) of the second plate 72 in the first direction X may be misaligned, for example, the left side edge of the second plate in the first direction X may be located at a side of the left side edge of the first plate 71 in the first direction X in the first direction X. A first side edge (e.g., a right side edge) of the first protrusion 72-1 in the first direction X may be misaligned in the second direction Y with the first side edge (e.g., the right side edge) of the second plate 72 in the first direction X. For example, the right edge of the second plate 72 in the first direction X may be located at a side of the right edge of the first protrusion 72-1 in the first direction X in the first direction X. An integral structure formed by connecting the second plate 72 and the first protrusion 72-1 to each other may be substantially in a shape of an “T”.

The rest of the structure of the first conductive layer of the display substrate of this example is substantially the same as the structure of the first conductive layer of the display substrate of the aforementioned embodiment, and will not be repeated here.

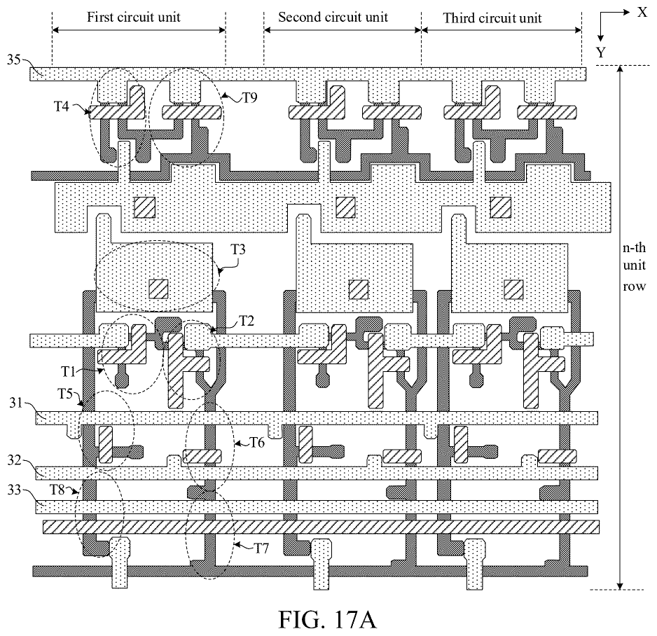

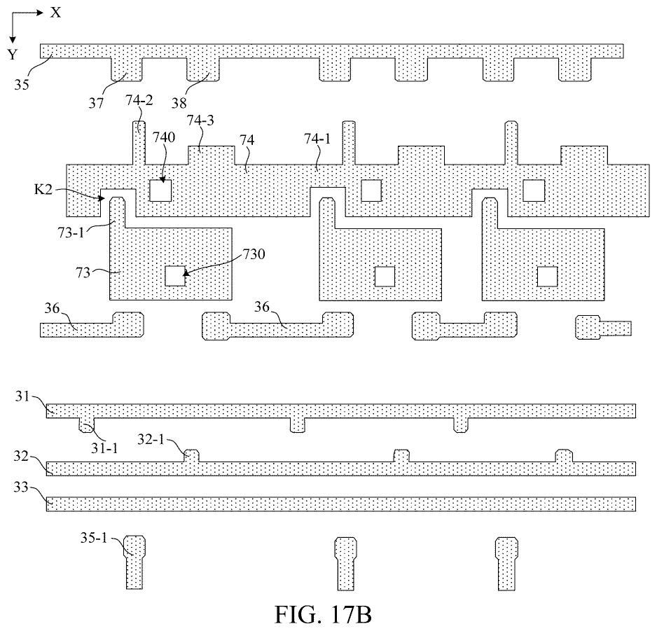

(2-3) A second conductive layer is formed. In some examples, a second insulation thin film and a second conductive thin film are sequentially deposited on the base substrate on which the above-mentioned patterns are formed, and the second conductive thin film is patterned using a patterning process to form a second insulation layer covering the first conductive layer and a second conductive layer disposed on the second insulation layer, as shown in FIGS. 17A and 17B. FIG. 17A is a schematic diagram of a display substrate after a second conductive layer is formed in FIG. 15. FIG. 17B is a schematic view of the second conductive layer in FIG. 17A.

In some examples, the second conductive layer of each circuit unit in the display substrate may at least include a first light emitting signal line 31, a second light emitting signal line 32, a repair line 33, a second reference signal line 35, a first shielding electrode 36, a second shielding electrode 37, a third shielding electrode 38, a third plate 73 of the first capacitor, and a fourth plate 74 of the second capacitor.

In some examples, a contour of the third plate 73 of the first capacitor may be in a shape of a rectangle, corners of the rectangle may be provided with chamfers, and the third plate 73 may be located between the second reference signal line 35 and the first shielding electrode 36 of the present circuit unit. A second plate connection line 73-1 may be provided on a side of the third plate 73 close to the fourth plate 74, a first end of the second plate connection line 73-1 is connected to the third plate 73, and a second end of the second plate connection line 73-1 extends towards the second reference signal line 35. The second plate connection line 73-1 may be configured to be connected to a second region of the fourth active layer (also the second region of the ninth active layer) by a third connection electrode to be formed subsequently, such that a second electrode of the fourth transistor T4, a second electrode of the ninth transistor T9, and the third plate 73 have the same potential.

In some examples, the fourth plate 74 may be provided with a first plate connection line 74-1 on a side in the first direction X or on a side in an opposite direction of the first direction X. A first end of the first plate connection line 74-1 is connected to the fourth plate 74 of the present circuit unit, and a second end of the first plate connection line 74-1 extends along the first direction X or in an opposite direction of the first direction X, and is connected to the fourth plate 74 in an adjacent circuit unit, so that fourth plates 74 of adjacent circuit units on a unit row are connected to each other. In some examples, a length of the first plate connection line 74-1 in the second direction Y may be smaller than a length of the fourth plate 74 in the second direction Y.

In some examples, edges of two fourth plates 74 adjacent in the first direction X that are close to each other and an edge of the first plate connection line 74-1 may form a second groove K2. The second groove K2 may be configured to accommodate the second plate connection line 73-1. The second plate connection line 73-1 on the third plate 73 extends towards the second reference signal line 35 in the second groove K2, so that an twelfth via to be formed subsequently can be moved as much as possible upwards as possible, as close as possible to the second region of the fourth active layer (i.e., the second region of the ninth active layer), the twelfth via can be configured so that a third connection electrode to be formed subsequently is connected to the second plate connection line 73-1 through the via, and the third connection electrode can be simultaneously connected to the second region of the fourth active layer (i.e., the second region of the ninth active layer) and the second plate 72 through the via, so that the second electrode of the fourth transistor T4, the second electrode of the ninth transistor T9, the second plate 72 and the third plate 73 have a same potential.

In some examples, the first shielding electrode 36 may be in a shape of a strip extending in the first direction X, and the first shielding electrode 36 may be located at a side of the third plate 73 close to the first light emitting signal line 31. The first shielding electrode 36 may be provided in each circuit unit. The first shielding electrode 36 may include a first shielding end and a second shielding end. An orthographic projection of the first shielding end on the base substrate overlaps at least partially with an orthographic projection of a first active layer between two gate electrodes of the first transistor T1 in the present circuit unit on the base substrate, and an orthographic projection of the second shielding end on the base substrate overlaps at least partially with an orthographic projection of a second active layer between two gate electrodes of the second transistor T2 in an adjacent circuit unit on the base substrate. In an exemplary implementation mode, the first shielding electrode 36 may be configured to shield an influence of data voltage jump on the first transistor T1 and the second transistor T2, to prevent the data voltage jump from affecting the normal operation of the pixel circuit, and to improve the display effect.

In some examples, the orthographic projection of the first shielding end of the first shielding electrode 36 on the base substrate partially overlaps with an orthographic projection of the first region of the third active layer 13 of the third transistor (also the second region of the fifth active layer and the second region of the eighth active layer) in the present circuit unit on the base substrate. Since the first region of the third active layer 13 (also the second region of the fifth active layer and the second region of the eighth active layer) is a conductor layer on which the conductorization treatment has been performed, and the first shielding electrode 36 is also a conductor layer, the first region of the third active layer 13 (also the second region of the fifth active layer and the second region of the eighth active layer) in one circuit unit and the first shielding end of the first shielding electrode 36 of the present circuit unit may form a first voltage stabilizing capacitor. Since the first shielding electrode 36 can subsequently be connected to the first power supply connection line to receive a stabilized first power supply signal with constant voltage, the first voltage stabilizing capacitor can be configured to stabilize a potential of the second node N2, thereby preventing signal crosstalk and avoiding an influence of data voltage jump on the second node N2, thereby ensuring the normal operation of the pixel circuit and improving the display effect.

In some examples, the orthographic projection of the second shielding end of the first shielding electrode 36 on the base substrate partially overlaps with an orthographic projection of the second region of the third active layer 13 of the third transistor (also the first region of the sixth active layer and the second region of the second active layer) in an adjacent circuit unit on the base substrate. Since the second region of the third active layer 13 (also the first region of the sixth active layer and the second region of the second active layer) is a conductor layer on which the conductorization treatment has been performed, and the first shielding electrode 36 is also a conductor layer, the second region of the third active layer 13 (also the first region of the sixth active layer and the second region of the second active layer) within one circuit unit and the second shielding end of the first shielding electrodes 36 in an adjacent circuit unit may form a second voltage stabilizing capacitor. Since the first shielding electrode 36 can subsequently be connected to the first power supply connection line to receive a stabilized first power supply signal with a constant voltage, the second voltage stabilizing capacitor can be configured to stabilize a potential of the third node N3, thereby preventing signal crosstalk and avoiding an influence of data voltage jump on the third node N3, thereby ensuring the normal operation of the pixel circuit and improving the display effect.

In some examples, the fourth plate 74 and the first shielding electrode 36 are spaced apart from each other, i.e., there may be no direct connection between the fourth plate 74 and the first shielding electrode 36. Adjacent first shielding electrodes 36 may be disposed to be spaced apart from each other.

Compared with the previous embodiment, this example eliminates the design in which the fourth plate 74 and the first shielding electrode 36 are of an interconnected integral structure, so that parasitic capacitance between the second node N2 and the third node N3 and the first power supply signal can be reduced, and signal crosstalk can be improved. Moreover, it may be advantageous for the shape of the fourth plate 74 to be flexibly designed to increase a distance between the first node and the fifth node, thereby increasing arrangement space of lateral traces.

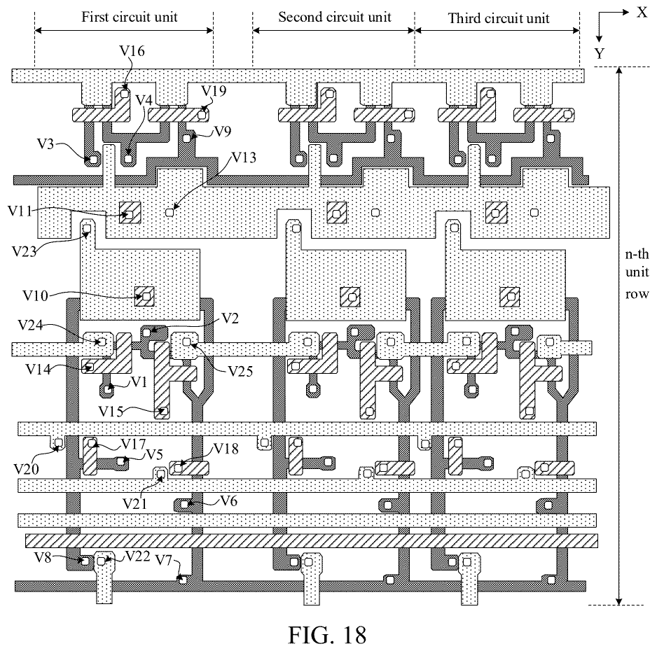

The rest of the structure of the second conductive layer of the display substrate of this example is substantially the same as the structure of the second conductive layer of the display substrate of the aforementioned embodiment, and will not be repeated here. (2-4) A third insulation layer is formed. In some examples, a third insulation thin film is deposited on the base substrate on which the above-mentioned patterns are formed, and the third insulation thin film is patterned using a patterning process to form a third insulation layer. A plurality of vias are provided in the third insulation layer of each circuit unit, as shown in FIG. 18. FIG. 18 is a schematic diagram of a display substrate after a third insulation layer is formed in FIG. 15.

In some examples, the plurality of vias of each circuit unit in the display substrate may at least include a first via V1, a second via V2, a third via V3, a fourth via V4, a fifth via V5, a sixth via V6, a seventh via V7, an eighth via V8, a ninth via V9, a tenth via V10, an eleventh via V11, a thirteenth via V13, a fourteenth via V14, a fifteenth via V15, a sixteenth via V16, a seventeenth via V17, an eighteenth via V18, a nineteenth via V19, a twentieth via V20, a twenty-first via V21, a twenty-second via V22, a twenty-third via V23, a twenty-fourth via V24, and a twenty-fifth via V25.

In some examples, an orthographic projection of the twenty-third via V23 on the base substrate may be within a range of an orthographic projection of the second plate connection line 73-1 of the third plate 73 on the base substrate. The third insulation layer within the twenty-third via V23 may be etched away to expose a portion of a surface of the second plate connection line 73-1, and the twenty-third via V23 may be configured such that a third connection electrode to be formed subsequently is connected to the third plate 73 through the twenty-third via V23.

In some examples, an orthographic projection of the twenty-fourth via V24 on the base substrate may be within the orthographic projection of the first shielding end of the first shielding electrode 36 of the present circuit unit on the base substrate. The third insulation layer within the twenty-fourth via V24 may be etched away to expose a portion of a surface of the first shielding end of the first shielding electrode 36, and the twenty-fourth via V24 may be configured such that a ninth connection electrode to be formed subsequently is connected to the first shielding electrode 36 of the present circuit unit through the twenty-fourth via V24.

In some examples, an orthographic projection of the twenty-fifth via V25 on the base substrate may be within the orthographic projection of the second shielding end of the first shielding electrode 36 of in an adjacent circuit unit on the base substrate. The third insulation layer within the twenty-fifth via V25 may be etched away to expose a portion of a surface of the second shielding end of the first shielding electrode 36 in the adjacent circuit unit, and the twenty-fifth via V25 may be configured such that a tenth connection electrode to be formed subsequently is connected to the first shielding electrode 36 in the adjacent circuit unit through the twenty-fifth via V25.

The rest of the structure of the third insulation layer of the display substrate of this example is substantially the same as the structure of the third insulation layer of the display substrate of the aforementioned embodiment, and will not be repeated here.

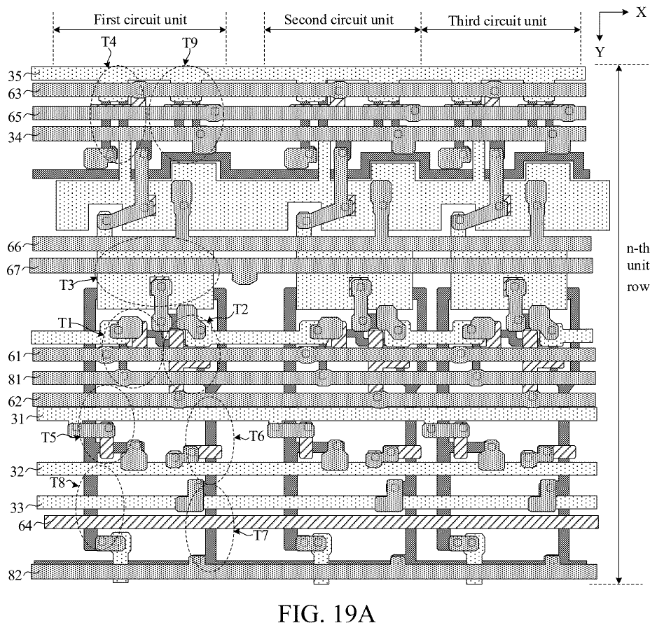

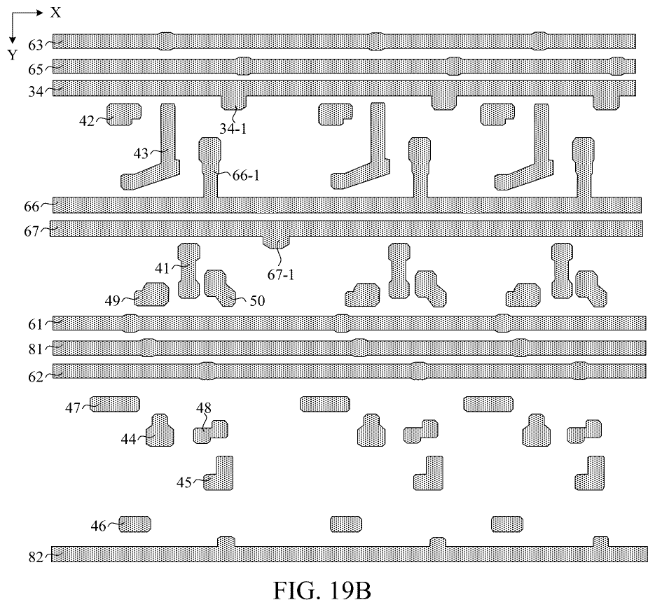

(2-5) A third conductive layer is formed. In some examples, a third conductive thin film is deposited on the base substrate on which the above-mentioned patterns are formed, and the third conductive thin film is patterned using a patterning process to form a third conductive layer disposed on the third insulation layer, as shown in FIGS. 19A and 19B. FIG. 19A is a schematic view of a display substrate after a third conductive layer is formed in FIG. 15. FIG. 19B is a schematic view of the third conductive layer in FIG. 19A. In some examples, the third conductive layer may be referred to as a first source-drain metal (SD1) layer.

In some examples, third conductive layers of the plurality of circuit units in the display substrate may each include a first connection electrode 41, a second connection electrode 42, a third connection electrode 43, a fourth connection electrode 44, a fifth connection electrode 45, a sixth connection electrode 46, a seventh connection electrode 47, an eighth connection electrode 48, a ninth connection electrode 49, a tenth connection electrode 50, a first scan signal line 61, a second scan signal line 62, a third scan signal line 63, a fifth scan signal line 65, a first power supply connection line 66, a second power supply connection line 67, a first initial signal line 81, a second initial signal line 82, and a first reference signal line 34.

In some examples, the first power supply connection line 66 and the second power supply connection line 67 may each be in a shape of a straight line with a main body portion extending in the first direction X. The second power supply connection line 67 may be located at a side of the first power supply connection line 66 away from the fourth plate 74. The first power supply connection line 66 may be located at a side of the fourth plate 74 close to the third plate 73, and an orthographic projection of the first power supply connection line 66 on the base substrate and an orthographic projection of the third plate 73 on the base substrate may partially overlap. The first power supply connection line 66 may be configured to be connected to a first power supply line to be formed subsequently to form a high-voltage power supply grid structure of a mesh communication structure on the display substrate. An orthographic projection of the second power supply connection line 67 on the base substrate and the orthographic projection of the third plate 73 on the base substrate may partially overlap. The second power supply connection line 67 may be configured to be connected to a second power supply line to be formed subsequently to form a low-voltage power supply grid structure of a mesh communication structure on the display substrate. In this example, the fourth plate 74 is connected to the first power supply connection line 66, and by providing the second power supply connection line 67 at the side of the first power supply connection line 66 away from the fourth plate 74, not only is it conducive to realizing connection wiring between the first power supply connection line 66 and the fourth plate 74, but also the first power supply connection line 66 can shield the second power supply connection line 67 from interfering with the second capacitor, so as to ensure performance of the second capacitor.

In some examples, a first power supply connection block 66-1 may be provided on a side of the first power supply connection line 66 away from the second power supply connection line 67. A first end of the first power supply connection block 66-1 is connected to the first power supply connection line 66, and a second end of the first power supply connection block 66-1 extends in a direction away from the second power supply connection line 67. An extension direction of the first power supply connection block 66-1 may be substantially perpendicular to an extension direction of the first power supply connection line 66. The first power supply connection line 66 can be connected to the fourth plate 74 in each circuit unit through the thirteenth via V13, thereby realizing that the first power supply connection line 66 is connected to the fourth plate 74.

In some examples, a third power supply connection block 67-1 may be provided on a side of the second power supply connection line 67 away from the first power supply connection line 66, and the third power supply connection block 67-1 may be located between two adjacent circuit units within at least one unit row. A first end of the third power supply connection block 67-1 is connected to the second power supply connection line 67, and a second end of the second power supply connection block 67-1 extends in a direction away from the first power supply connection line 66. The second power supply connection block 67-1 may be configured to be connected to a second power supply line to be formed subsequently.

In some examples, the third connection electrode 43 may be substantially in a shape of a “V”. The third connection electrode 43 may be located between the first reference signal line 34 and the first power supply connection line 66. A first end of the third connection electrode 43 can be connected to the second region of the fourth active layer (also the second region of the ninth active layer) through the fourth via V4, a second end of the third connection electrode 43 can be connected to the second plate connection line 73-1 of the third plate 73 through the twenty-third via V23, and a third end of the third connection electrode 43 between the first end and the second end thereof can be connected to the second plate 72 through the eleventh via V11. In some examples, the third connection electrode 43 may cause the second electrode of the fourth transistor T4, the second electrode of the ninth transistor T9, the third plate 73 of the first capacitor (i.e., a second end of the first capacitor), and the second plate 72 of the second capacitor (i.e., a second end of the second capacitor) to have a same potential, and the third connection electrode 43 may serve as the fifth node N5 of the pixel circuit.

In some examples, the ninth connection electrode 49 may be substantially rectangular, and the ninth connection electrode 49 may be located between the second power supply connection line 67 and the first scan signal line 61. The ninth connection electrode 49 may be connected to the first shielding electrode 36 of the present circuit unit through the twenty-fourth via V24. The ninth connection electrode 49 may be configured to be connected to a first power supply line to be formed subsequently to which the pixel circuit of the present circuit unit is connected.

In some examples, the tenth connection electrode 50 may be substantially in a shape of a strip with a main body portion extending in the second direction Y, and the tenth connection electrode 50 may be located between the second power supply connection line 67 and the first scan signal line 61. The tenth connection electrode 50 may be connected to the first shielding electrode 36 of in an adjacent circuit unit through the twenty-fifth via V25. The tenth connection electrode 50 may be configured to be connected to a first power supply line to be formed subsequently to which the pixel circuit of the present circuit unit is connected.

The rest of the structure of the third conductive layer of the display substrate of this example is substantially the same as the structure of the third conductive layer of the display substrate of the aforementioned embodiment, and will not be repeated here.

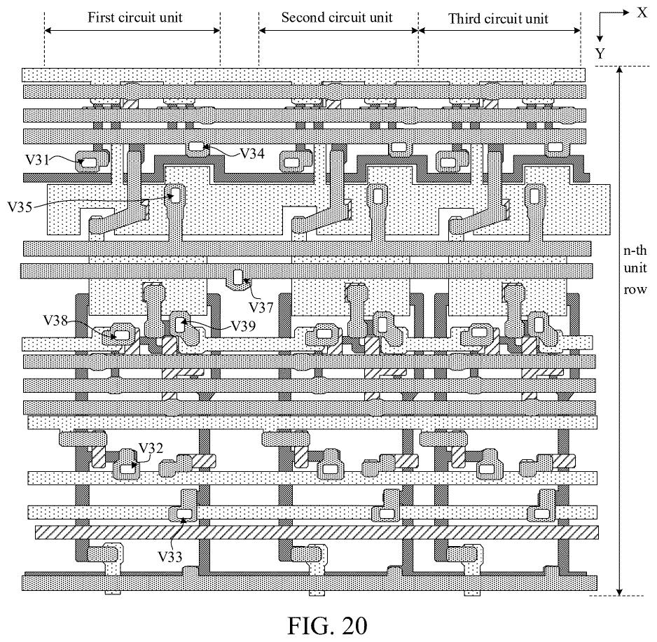

(2-6) A fourth insulation layer is formed. In some examples, a fourth insulation thin film is coated on the base substrate on which the above-mentioned patterns are formed, and the fourth insulation thin film is patterned using a patterning process to form a fourth insulation layer covering the third conductive layer. The fourth insulation layer in each circuit unit may be provided with a plurality of vias, as shown in FIG. 20. FIG. 20 is a schematic diagram of a display substrate after a fourth insulation layer is formed in FIG. 15.

In some examples, the plurality of vias of each circuit unit in the display substrate may at least include a thirty-first via V31, a thirty-second via V32, a thirty-third via V33, a thirty-fourth via V34, a thirty-fifth via V35, a thirty-eighth via V38, and a thirty-ninth via V39.

In some examples, an orthographic projection of the thirty-eighth via V38 on the base substrate may be within an orthographic projection of the ninth connection electrode 49 on the base substrate. The fourth insulation layer within the thirty-eighth via V38 may be removed to expose a portion of a surface of the ninth connection electrode 49, and the thirty-eighth via V38 may be configured such that a first power supply line to be formed subsequently is connected to the ninth connection electrode 49 through the thirty-eighth via V38.

In some examples, an orthographic projection of the thirty-ninth via V39 on the base substrate may be within the orthographic projection range of the tenth connection electrode 50 on the base substrate. The fourth insulation layer within the thirty-ninth via V39 may be removed to expose a portion of a surface of the tenth connection electrode 50, and the thirty-ninth via V39 may be configured such that a first power supply line to be formed subsequently is connected to the tenth connection electrode 50 through the thirty-ninth via V39.

In some examples, the at least one circuit unit may further include a thirty-seventh via V37. An orthographic projection of the thirty-seventh via V37 on the base substrate may be within a range of an orthographic projection of the third power supply connection block 67-1 of the second power supply connection line 67 on the base substrate. The fourth insulation layer within the thirty-seventh via V37 is removed to expose a portion of a surface of the third power supply connection block 67-1, and the thirty-seventh via V37 may be configured such that a second power supply line to be formed subsequently is connected to the third power supply connection block 67-1 through the thirty-seventh via V37. In some examples, the thirty-seventh via V37 may be located between the first circuit unit and the second circuit unit.

The rest of the structure of the fourth insulation layer of the display substrate of this example is substantially the same as the structure of the fourth insulation layer of the display substrate of the aforementioned embodiment, and will not be repeated here.

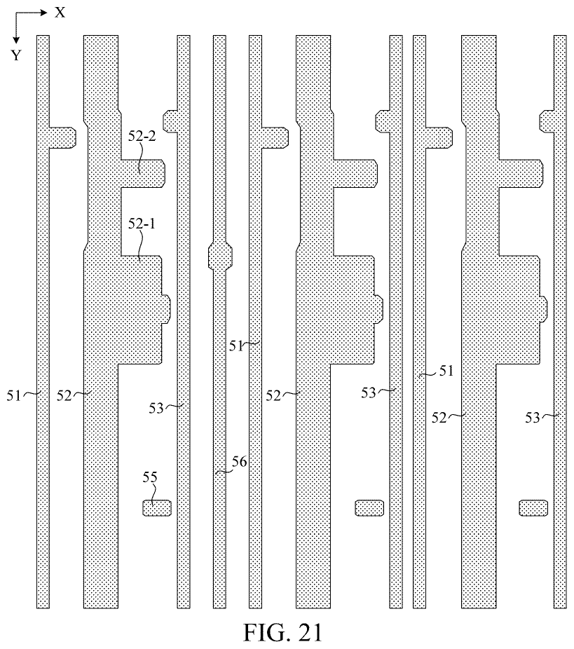

(2-7) A fourth conductive layer is formed. In some examples, a fourth conductive thin film is deposited on the base substrate on which the above-mentioned patterns are formed, and the fourth conductive thin film is patterned using a patterning process to form a fourth conductive layer disposed on the fourth insulation layer, as shown in FIG. 21. FIG. 21 is a schematic view of a fourth conductive layer in FIG. 15.

In some examples, fourth conductive layers of the plurality of circuit units in the display substrate may each include a data signal line 51, a first power supply line 52, a reference signal connection line 53, and an anode connection electrode 55.

In some examples, the first power supply line 52 may be in a shape of a bending line with a main body portion extending in the second direction Y, and the first power supply line 52 may be connected to the fourth connection electrode 44 through the thirty-second via V32 on the one hand, may be connected to the first power supply connection block 66-1 through the thirty-fifth via V35 on the other hand, may also be connected to the ninth connection electrode 49 through the thirty-eighth via V38, and may also be connected to the tenth connection electrode 50 through the thirty-ninth via V39. Since the fourth connection electrode 44 is connected to the first region of the fifth active layer through a via, it is achieved that the first power supply line 52 writes a first power supply signal to a first electrode of the fifth transistor T5. Since the first power supply connection block 66-1 is connected to the first power supply connection line 66, it is realized that the first power supply connection line 66 with the main body portion extending along the first direction X and the first power supply line 52 with the main body portion extending along the second direction Y are connected to each other, so that the first power supply line 52 and the first power supply connection line 66 form a mesh structure for transmitting the first power supply signal on the display substrate, which not only can effectively reduce a resistance of the first power supply line 52, reduce a voltage drop of the first power supply signal, but also can effectively improve uniformity of the first power supply signal in the display substrate, effectively improve display uniformity, and improve display attribute and display quality. Since the ninth connection electrode 49 is connected to the first shielding electrode 36 of the present circuit unit through a via, it is achieved that the first power supply line 52 provides the first power supply signal to the first shielding electrode 36 of the present circuit unit. Since the tenth connection electrode 50 is connected to the first shielding electrode 36 of in an adjacent circuit unit through a via, it is achieved that the first power supply line 52 connected to the present circuit unit provides a first power supply signal to the first shielding electrode 36 in an adjacent circuit unit.

In some examples, the at least one circuit unit may further include a second power supply line 56. The second power supply line 56 may be in a shape of a straight line with a main body portion extending in the second direction Y, and the second power supply line 56 may be connected to the third power supply connection block 67-1 through the thirty-seventh via V37. Since the third power supply connection block 67-1 is connected to the second power supply connection line 67, it is achieved that the second power supply connection line 67 with the main body portion extending along the first direction X and the second power supply line 56 with the main body portion extending along the second direction Y are connected to each other, so that the second power supply connection line 67 and the second power supply line 56 form a mesh structure for transmitting a second power supply signal on the display substrate, which not only effectively reduces a resistance of the second power supply line 56, reduces a voltage drop of the second power supply signal, but also effectively improves uniformity of the second power supply signal in the display substrate, effectively improves the display uniformity, and improves the display attribute and the display quality. In some examples, the second power supply line 56 may be located between the reference signal connection line 53 of the first circuit unit and the data signal line 51 of the second circuit unit.

In some examples, the second power supply connection line 67 of the third conductive layer may be provided in each unit row, the second power supply connection line 56 of the fourth conductive layer may be provided every three unit columns, and a plurality of second power supply connection lines 67 may be connected to a plurality of second power supply lines 56 respectively to form a mesh structure for transmitting the second power supply signal.

The rest of the structure of the fourth conductive layer of the display substrate of this example is substantially the same as the structure of the fourth conductive layer of the display substrate of the aforementioned embodiment, and will not be repeated here.

Hereto, manufacturing of the drive circuit layer of this embodiment on the base substrate is completed. In some exemplary implementation modes, after manufacturing of the drive circuit layer is completed, a light emitting structure layer and an encapsulation structure layer may be sequentially manufactured on the drive circuit layer, which will not be repeated herein.

In this example, by disposing the first initial signal line between the first scan signal line and the second scan signal line, a distance between the first initial signal line and the channel region of the first active layer of the first transistor can be reduced, and the first initial signal line can provide a first initial signal to the first transistor for initialization processing through a shortest path, which is conducive to reducing a length of the first region of the first active layer, reducing load of the first initial signal line, and optimizing the initialization effect. Further, compared with the previous embodiment, the display substrate of this example, by eliminating the design in which the fourth plate 74 and the first shielding electrode 36 are of an interconnected integral structure, can reduce parasitic capacitance between the second node N2 and the third node N3 and the first power supply signal, and can improve signal crosstalk. Moreover, it may be advantageous for the shape of the fourth plate 74 to be flexibly designed to increase the distance between the first node and the fifth node, thereby increasing arrangement space of lateral traces.

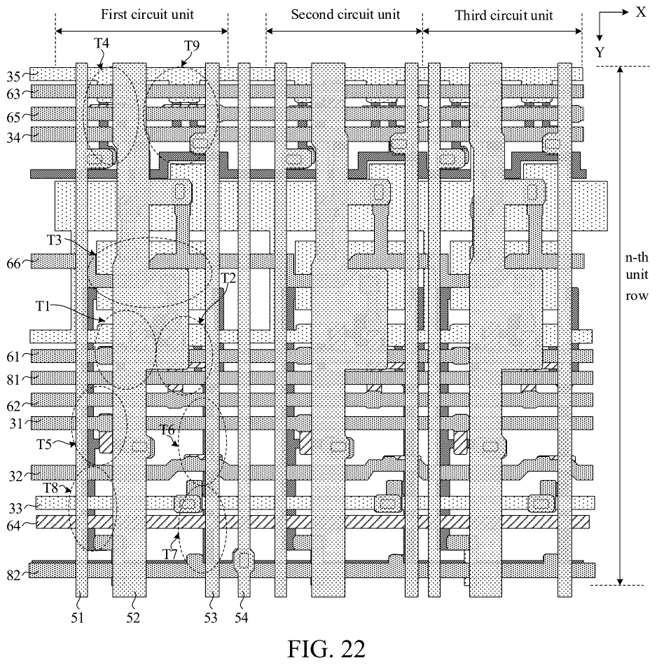

FIG. 22 is a schematic diagram of a planar structure of another display substrate according to at least one embodiment of the present disclosure. Structures of pixel circuits in three circuit units (i.e. a first circuit unit, a second circuit unit and a third circuit unit) of the display substrate are illustrated in FIG. 22.

In some examples, a first light emitting signal line 31 and a first initial signal line 81 may disposed in a same layer, for example, both in a third conductive layer. This example can not only reduce a resistance of the first light emitting signal line 31, but also reduce transfer vias provided in the third insulation layer, and optimize wiring space.

In some examples, a second light emitting signal line 32 and the first initial signal line 81 may be disposed in a same layer, for example, both in the third conductive layer. This example can not only reduce a resistance of the second light emitting signal line 32, but also reduce transfer vias provided in the third insulation layer, and optimize the wiring space.

In some examples, the manufacturing process of the display substrate of this example may include the following operations.

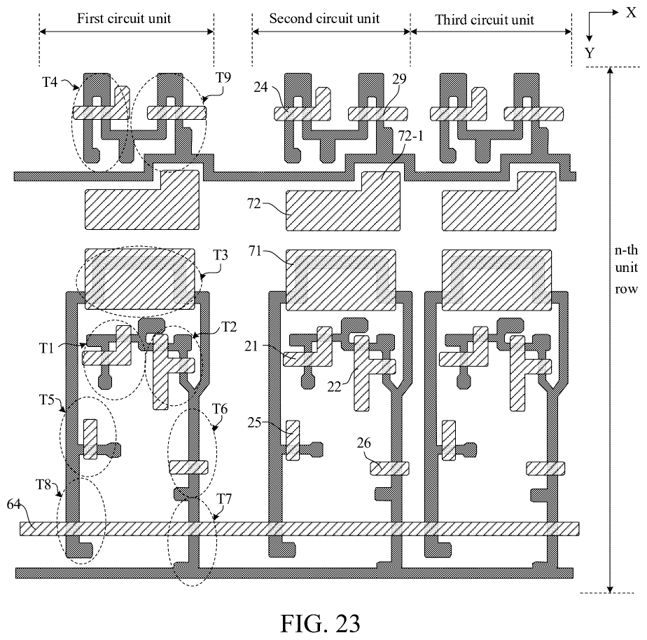

(3-1) A semiconductor layer is formed. In some examples, a semiconductor thin film is deposited on a base substrate, and the semiconductor thin film is patterned by a patterning process to form a semiconductor layer, as shown in FIG. 23. FIG. 23 is a schematic diagram of a display substrate after a first conductive layer is formed in FIG. 22. The structure of the semiconductor layer of the display substrate of this example is the same as that of the semiconductor layer of the display substrate of the embodiment shown in FIG. 6, and will not be repeated here.

(3-2) A first conductive layer is formed. In some examples, a first insulation thin film and a first conductive thin film are sequentially deposited on the base substrate on which the above-mentioned patterns are formed, and the first conductive thin film is patterned by a patterning process to form a first insulation layer covering the semiconductor layer, and a first conductive layer disposed on the first insulation layer, as shown in FIG. 23. The structure of the first conductive layer of the display substrate of this example is the same as that of the first conductive layer of the display substrate of the embodiment shown in FIG. 6, which will not be described here in detail.

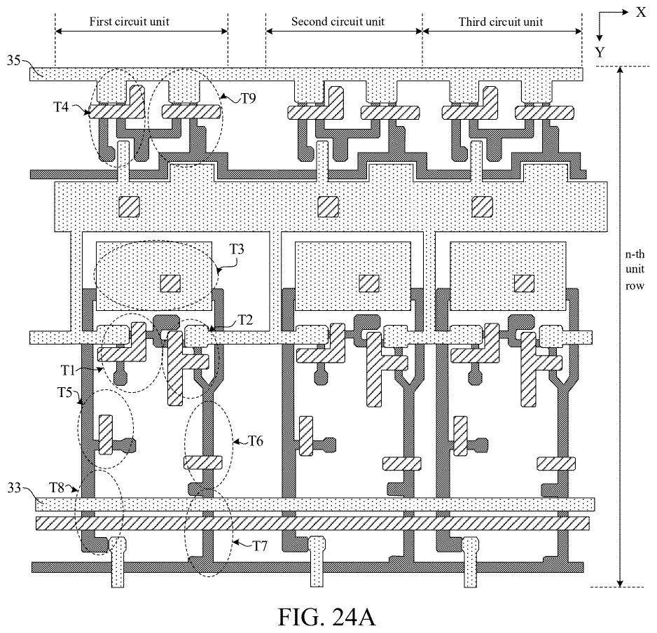

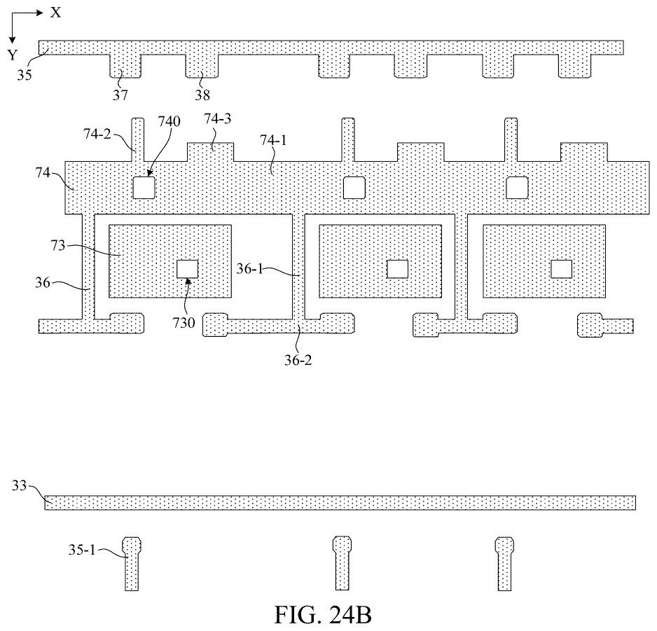

(3-3) A second conductive layer is formed. In some examples, a second insulation thin film and a second conductive thin film are sequentially deposited on the base substrate on which the above-mentioned patterns are formed, and the second conductive thin film is patterned using a patterning process to form a second insulation layer covering the first conductive layer and a second conductive layer disposed on the second insulation layer, as shown in FIGS. 24A and 24B. FIG. 24A is a schematic diagram of a display substrate after a second conductive layer is formed in FIG. 22. FIG. 24B is a schematic view of the second conductive layer in FIG. 24A.

In some examples, the second conductive layer of each circuit unit in the display substrate may at least include a repair line 33, a second reference signal line 35, a first shielding electrode 36, a second shielding electrode 37, a third shielding electrode 38, a third plate 73 of a first capacitor, and a fourth plate 74 of a second capacitor.

The description of the structure of the second conductive layer of the display substrate in this example can be referred to the description of the structure of the second conductive layer of the display substrate in the embodiment shown in FIG. 6, and will not be repeated here.

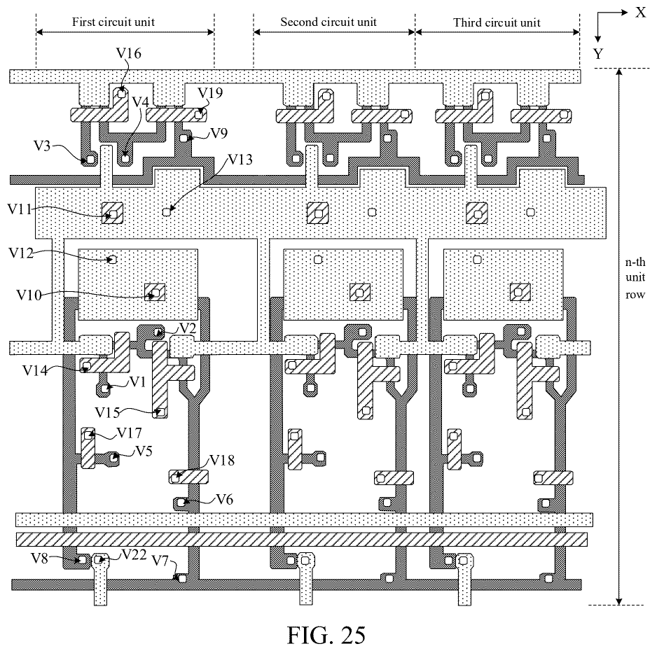

(3-4) A third insulation layer is formed. In some examples, a third insulation thin film is deposited on the base substrate on which the above-mentioned patterns are formed, and the third insulation thin film is patterned using a patterning process to form a third insulation layer. A plurality of vias are provided in the third insulation layer of each circuit unit, as shown in FIG. 25. FIG. 25 is a schematic diagram of a display substrate after a third insulation layer is formed in FIG. 22.

In some examples, the plurality of vias of each circuit unit in the display substrate may at least include a first via V1, a second via V2, a third via V3, a fourth via V4, a fifth via V5, a sixth via V6, a seventh via V7, an eighth via V8, a ninth via V9, a tenth via V10, an eleventh via V11, a twelfth via V12, a thirteenth via V13, a fourteenth via V14, a fifteenth via V15, a sixteenth via V16, a seventeenth via V17, an eighteenth via V18, a nineteenth via V19, and a twenty-second via V22.

The description of the structure of the third insulation layer of the display substrate in this example can be referred to the description of the structure of the third insulation layer of the display substrate in the embodiment shown in FIG. 6, and will not be repeated here.

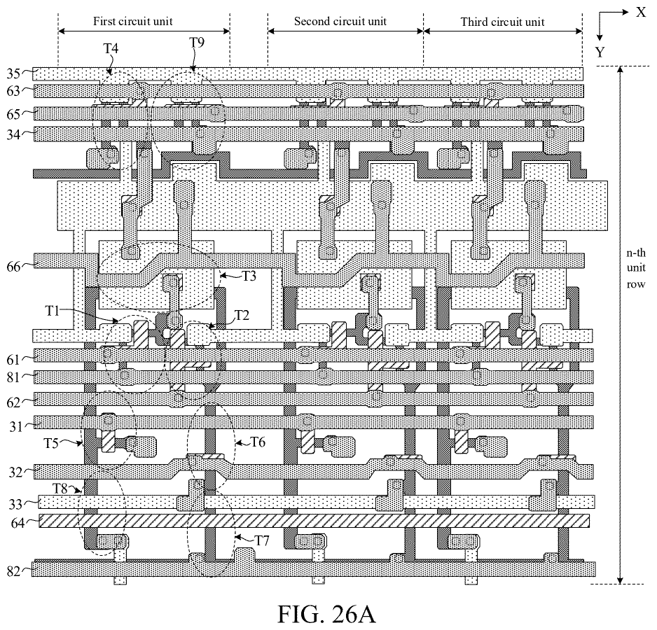

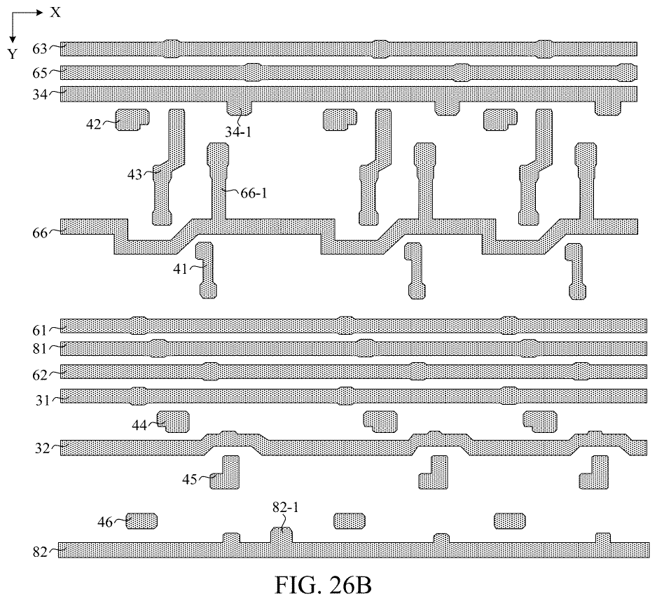

(3-5) A third conductive layer is formed. In some examples, a third conductive thin film is deposited on the base substrate on which the above-mentioned patterns are formed, and the third conductive thin film is patterned using a patterning process to form a third conductive layer disposed on the third insulation layer, as shown in FIGS. 26A and 26B. FIG. 26A is a schematic view of a display substrate after a third conductive layer is formed in FIG. 22. FIG. 26B is a schematic view of the third conductive layer in FIG. 26A.

In some examples, third conductive layers of the plurality of circuit units in the display substrate may each include a first connection electrode 41, a second connection electrode 42, a third connection electrode 43, a fourth connection electrode 44, a fifth connection electrode 45, a sixth connection electrode 46, a first scan signal line 61, a second scan signal line 62, a third scan signal line 63, a fifth scan signal line 65, a first power supply connection line 66, a first initial signal line 81, a second initial signal line 82, a first reference signal line 34, a first light emitting signal line 31, and a second light emitting signal line 32.

In some examples, the first light emitting signal line 31 may be in a shape of a straight line with a main body portion extending along the first direction X, and the second light emitting signal line 32 may be in a shape of a bending line with a main body portion extending along the first direction X. The first light emitting signal line 31 may be located at a side of the second scan signal line 62 in the second direction Y, and the second light emitting signal line 32 may be located at a side of the first light emitting signal line 31 in the second direction Y. The first light emitting signal line 31 may be located between the second scan signal line 62 and the second light emitting signal line 32.

In some examples, the first light emitting signal line 31 can be connected to the fifth gate electrode 25 in each circuit unit through the seventeenth via V17, thereby realizing that the first light emitting signal line 31 is connected to the fifth gate electrode 25 of the fifth transistor T5, and the first light emitting signal line 31 can control turn-on and turn-off of the fifth transistor T5.

In some examples, the second light emitting signal line 32 can be connected to the sixth gate electrode 26 in each circuit unit through the eighteenth via V18, thereby realizing that the second light emitting signal line 32 is connected to the sixth gate electrode 26 of the sixth transistor T6, and the second light emitting signal line 32 can control turn-on and turn-off of the sixth transistor T6.

The description of the rest of the structure of the third conductive layer of the display substrate of this example can be referred to the description of the structure of the third conductive layer of the display substrate of the embodiment shown in FIG. 6, and will not be repeated here.

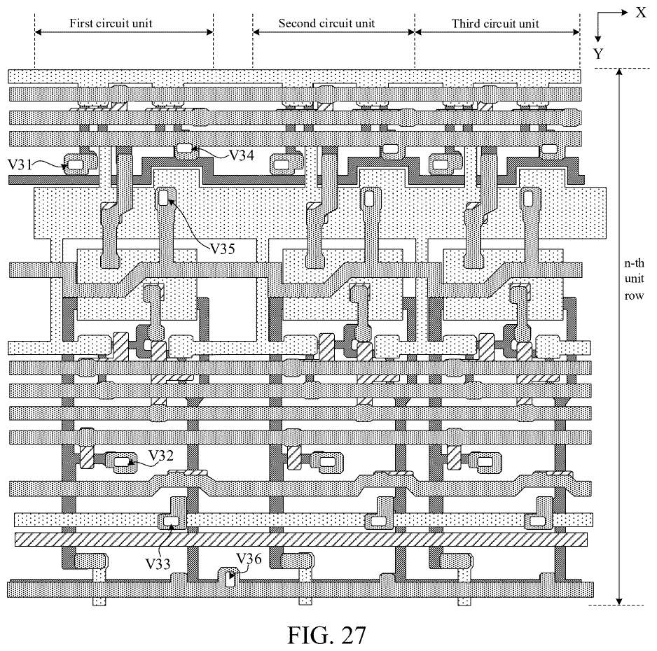

(3-6) A fourth insulation layer is formed. In some examples, a fourth insulation thin film is coated on the base substrate on which the above-mentioned patterns are formed, and the fourth insulation thin film is patterned using a patterning process to form a fourth insulation layer covering the third conductive layer. The fourth insulation layer in each circuit unit may be provided with a plurality of vias, as shown in FIG. 27. FIG. 27 is a schematic diagram of a display substrate after a fourth insulation layer is formed in FIG. 22.

In some examples, the plurality of vias of each circuit unit in the display substrate may at least include a thirty-first via V31, a thirty-second via V32, a thirty-third via V33, a thirty-fourth via V34, and a thirty-fifth via V35.

In some examples, the at least one circuit unit may further include a thirty-sixth via V36. An orthographic projection of the thirty-sixth via V36 on the base substrate may be within a range of an orthographic projection of a second initial connection block 82-1 of the second initial signal line 82 on the base substrate, the fourth insulation layer within the thirty-sixth via V36 is removed to expose a portion of a surface of the second initial connection block 82-1, and the thirty-sixth via V36 may be configured such that an initial signal connection line to be formed subsequently is connected to the second initial connection block 82-1 through the thirty-sixth via V36. In some examples, the thirty-sixth via V36 may be located between the first circuit unit and the second circuit unit.

The description of the rest of the structure of the fourth insulation layer of the display substrate of this example can be referred to the description of the structure of the fourth insulation layer of the display substrate of the embodiment shown in FIG. 6, and will not be repeated here.

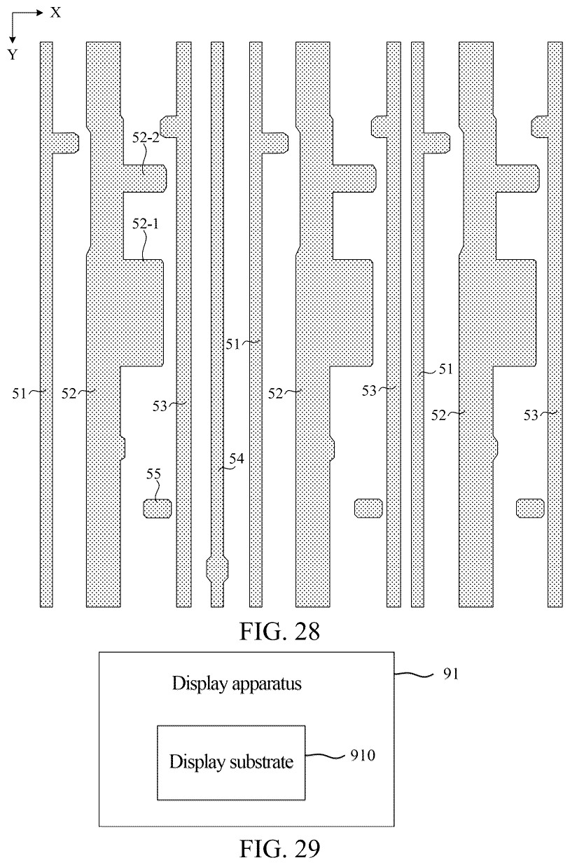

(3-7) A fourth conductive layer is formed. In some examples, a fourth conductive thin film is deposited on the base substrate on which the above-mentioned patterns are formed, and the fourth conductive thin film is patterned using a patterning process to form a fourth conductive layer disposed on the fourth insulation layer, as shown in FIG. 28. FIG. 28 is a schematic view of a fourth conductive layer in FIG. 22.

In some examples, fourth conductive layers of the plurality of circuit units in the display substrate may each include a data signal line 51, a first power supply line 52, a reference signal connection line 53, and an anode connection electrode 55.

In some examples, an initial signal connection line 54 may further be included in the at least one circuit unit. The initial signal connection line 54 may be in a shape of a straight line with a main body portion extending in the second direction Y, and the initial signal connection line 54 may be connected to the second initial connection block 82-1 through the thirty-sixth via V36. Since the second initial connection block 82-1 is connected to the second initial signal line 82, it is realized that the second initial signal line 82 with the main body portion extending along the first direction X and the initial signal connection line 54 with the main body portion extending along the second direction Y are connected to each other, so that the initial signal connection line 54 and the second initial signal line 82 form a mesh structure for transmitting a second initial signal on the display substrate, which not only can effectively reduce a resistance of the second initial signal line 82, reduce a voltage drop of the second initial signal, but also can effectively improve uniformity of the second initial signal in the display substrate, effectively improve display uniformity, and improve display attribute and display quality. In some examples, the initial signal connection line 54 may be located between the reference signal connection line 53 of the first circuit unit and the data signal line 51 of the second circuit unit.

The description of the rest of the structure of the fourth conductive layer of the display substrate of this example can be referred to the description of the structure of the fourth conductive layer of the display substrate of the embodiment shown in FIG. 6, and will not be repeated here.

Hereto, manufacturing of the drive circuit layer of this embodiment on the base substrate is completed. In some exemplary implementation modes, after manufacturing of the drive circuit layer is completed, a light emitting structure layer and an encapsulation structure layer may be sequentially manufactured on the drive circuit layer, which will not be repeated herein.

In this example, by disposing the first initial signal line between the first scan signal line and the second scan signal line, a distance between the first initial signal line and the channel region of the first active layer of the first transistor can be reduced, and the first initial signal line can provide a first initial signal to the first transistor for initialization processing through a shortest path, which is conducive to reducing a length of the first region of the first active layer, reducing load of the first initial signal line, and optimizing the initialization effect. Moreover, in this embodiment, by providing the first light emitting signal line 31 and the second light emitting signal line 32 in the third conductive layer, the resistances of the first light emitting signal line 31 and the second light emitting signal line 32 can be reduced, and transfer vias provided by the third insulation layer can be reduced, thereby optimizing wiring space. In some other examples, one of the first light emitting signal line and the second light emitting signal line may be provided in the third conductive layer.

In some other examples, the structures of the display substrates of the above embodiments may be combined with each other, for example, in the display substrate shown in FIG. 15, at least one of the first light emitting signal line and the second light emitting signal line may be provided in the third conductive layer. This embodiment is not limited thereto.

By arranging the first initial signal line between the first scan signal line and the second scan signal line, the display substrate according to this embodiment can optimize the layout wiring, reduce an initialization path length of the first initial signal, which is conducive to optimizing the initialization effect.

In the display substrate according to this embodiment, by independently arranging the fourth plate of the second capacitor and the first shielding electrode, the parasitic capacitance between the second node and the third node and the first power supply signal can be reduced and the signal crosstalk can be improved. Moreover, it may be advantageous for the shape of the fourth plate to be flexibly designed to increase the distance between the first node and the fifth node, thereby increasing the arrangement space of lateral traces.

The display substrate according to this embodiment is provided with a first power supply connection line extending with a main body portion along the first direction X and a first power supply line with a main body portion extending along the second direction Y, and the first power supply line and the first power supply connection line are connected to each other, so that the first power supply line and the first power supply connection line form a mesh structure for transmitting a first power supply signal on the display substrate, which can not only effectively reduce a resistance of the first power supply line, reduce a voltage drop of the first power supply signal, but also effectively improve uniformity of the first power supply signal in the display substrate, effectively improve the display uniformity, and improve the display attribute and the display quality.

The display substrate according to this embodiment is provided with a second power supply connection line with a main body portion extending along the first direction X and a second power supply line with a main body portion extending along the second direction Y, and the second power supply connection line and the second power supply connection line are connected to each other, so that the second power supply line and the second power supply connection line form a mesh structure for transmitting a second power supply signal on the display substrate, which can not only effectively reduce a resistance of the second power supply signal line, reduce a voltage drop of the second power supply signal, but also effectively improve uniformity of the second power supply signal in the display substrate, effectively improve the display uniformity, and improve the display attribute and the display quality.

The display substrate according to this embodiment is provided with a first reference signal line with a main body portion extending along the first direction X and a reference signal connection line with a main body portion extending along the second direction Y, and the first reference signal line and the reference signal connection line are connected to each other, so that the first reference signal line and the reference signal connection line form a mesh structure for transmitting a first reference signal on the display substrate, which can not only effectively reduce a resistance of the first reference signal line, reduce a voltage drop of the first reference signal, but also effectively improve uniformity of the first reference signal in the display substrate, effectively improve the display uniformity, and improve the display attribute and the display quality.

By providing the first shielding electrode, the display substrate according to this embodiment can shield an influence of data voltage jump on the first transistor T1 and the second transistor T2, so as to prevent the data voltage jump from affecting the normal operation of the pixel circuit, and improve the display effect.

By providing the second shielding electrode and the third shielding electrode, the display substrate according to this embodiment can shield an influence of data voltage jump on the fourth transistor T4, the ninth transistor T9 and the fifth node N5, so as to prevent the data voltage jump from affecting the normal operation of the pixel circuit, and improve the display effect.

By providing a power supply shield block on the first power supply line, the display substrate according to this embodiment can effectively shield an influence of other signals in the pixel circuit on the first node N1, prevent other signals from affecting a potential of the first node N1 of the pixel circuit, and improve the display effect.

By providing the first power supply line to shield the first region of the active layer of the first transistor connected to the first initial signal line, the display substrate according to this embodiment can avoid other signals from influencing reception of the first initial signal by the first region of the active layer of the first transistor, thereby ensuring accuracy of transmission of the first initial signal to ensure the initialization effect.

In the display substrate according to this embodiment, the second power supply connection line is configured to be located at a side of the first power supply connection line away from the fourth plate, which is not only conducive to realizing connection wiring between the first power supply connection line and the fourth plate, but also the first power supply connection line can shield interference of the second power supply connection line to the second capacitor, so as to ensure performance of the second capacitor.

This embodiment further provides a method for manufacturing a display substrate, which is used for manufacturing the display substrate according to the foregoing embodiments.

In some exemplary implementation modes, a method for manufacturing a display substrate may include forming a drive circuit layer on a base substrate. The drive circuit layer at least includes a plurality of circuit units, and at least one circuit unit includes a pixel circuit; the pixel circuit at least includes a first transistor, a second transistor, a third transistor, a fourth transistor, and a first capacitor. A gate electrode of the first transistor is electrically connected to a first scan signal line, a first electrode of the first transistor is electrically connected to a first initial signal line, and a second electrode of the first transistor is electrically connected to a gate electrode of the third transistor; a gate electrode of the second transistor is electrically connected to a second scan signal line, a first electrode of the second transistor is electrically connected to the gate electrode of the third transistor, and a second electrode of the second transistor is electrically connected to a second electrode of the third transistor. A gate electrode of the fourth transistor is electrically connected to a third scan signal line, a first electrode of the fourth transistor is electrically connected to a data signal line, and a second electrode of the fourth transistor is electrically connected to a second end of the first capacitor; a first end of the first capacitor is electrically connected to the gate electrode of the third transistor. The first initial signal line, the first scan signal line, and the second scan signal line extend in at least partially the same direction and are located at a same side of the first transistor, and the first initial signal line is located between the first scan signal line and the second scan signal line.

For the method for manufacturing the display substrate in this embodiment, reference may be made to descriptions of the aforementioned embodiments, and thus will not be repeated here.

This embodiment further provides a display substrate, which includes a base substrate and a drive circuit layer provided on the base substrate. The drive circuit layer at least includes a plurality of circuit units, and at least one circuit unit includes a pixel circuit at least including a first transistor, a second transistor, a third transistor, a fourth transistor and a first capacitor. A gate electrode of the first transistor is electrically connected to a first scan signal line, a first electrode of the first transistor is electrically connected to a first initial signal line, and a second electrode of the first transistor is electrically connected to a gate electrode of the third transistor; a gate electrode of the second transistor is electrically connected to a second scan signal line, a first electrode of the second transistor is electrically connected to the gate electrode of the third transistor, and a second electrode of the second transistor is electrically connected to a second electrode of the third transistor. A gate electrode of the fourth transistor is electrically connected to a third scan signal line, a first electrode of the fourth transistor is electrically connected to a data signal line, and a second electrode of the fourth transistor is electrically connected to a second end of the first capacitor; a first end of the first capacitor is electrically connected to the gate electrode of the third transistor. The second transistor is located at a side of the first transistor in the first direction, and the third transistor and the fourth transistor are located at a same side of the first transistor and the second transistor in a second direction, the first direction intersects the second direction. The first initial signal line, the first scan signal line, and the second scan signal line all extend in the first direction and are located at a side of the first transistor away from the third transistor in the second direction. The first initial signal line is located between the first scan signal line and the second scan signal line.

In some exemplary implementation modes, an orthographic projection of the first scan signal line on the base substrate partially overlaps with orthographic projections of the gate electrode of the first transistor and the gate electrode of the second transistor on the base substrate.

In some exemplary implementation modes, the pixel circuit further includes a second capacitor; the second capacitor at least includes a second plate as a second end of the second capacitor and a fourth plate as a first end of the second capacitor, an orthographic projection of the second plate on the base substrate overlaps at least partially with an orthographic projection of the fourth plate on the base substrate. The first capacitor at least includes a first plate as a first end of the first capacitor and a third plate as a second end of the first capacitor, an orthographic projection of the first plate on the base substrate overlaps at least partially with an orthographic projection of the third plate on the base substrate. The fourth plate is connected to a first power supply line, the second plate is connected to the third plate, and the first plate serves as the gate electrode of the third transistor.

In some exemplary implementation modes, the third plate is provided with a second plate connection line extending towards the fourth plate, and the fourth plate is provided with a second groove recessed in a direction away from the third plate; the second plate connection line is provided in the second groove, and an end portion of the second plate connection line away from the third plate is connected to the second plate through a via and a connection electrode.

In some exemplary implementation modes, the at least one circuit unit further includes: a first shielding electrode; the first shielding electrode includes a first shielding end and a second shielding end; an orthographic projection of the first shielding end on the base substrate overlaps at least partially with an orthographic projection of a first active layer between two gate electrodes of the first transistor in the present circuit unit on the base substrate, and the first shielding end is electrically connected to the first power supply line. An orthographic projection of the second shielding end on the base substrate overlaps at least partially with an orthographic projection of a second active layer between two gate electrodes of the second transistor in an adjacent circuit unit on the base substrate, the second shielding end is electrically connected to the first power supply line.

In some exemplary implementation modes, the pixel circuit further includes a fifth transistor and a sixth transistor. A gate electrode of the fifth transistor is electrically connected to a first light emitting signal line, a first electrode of the fifth transistor is electrically connected to the first power supply line, and a second electrode of the fifth transistor is electrically connected to a first electrode of the third transistor. A gate electrode of the sixth transistor is electrically connected to a second light emitting signal line, a first electrode of the sixth transistor is electrically connected to the second electrode of the third transistor, and a second electrode of the sixth transistor is electrically connected to a light emitting device. The first light emitting signal line is located at a side of the second scan signal line in the second direction, and the second light emitting signal line is located at a side of the first light emitting signal line in the second direction.

In some exemplary implementation modes, the first light emitting signal line, the second light emitting signal line, and the first initial signal line are disposed in a same layer.

The description of the display substrate of this example may refer to the description of the foregoing embodiment, and will not be repeated here.

FIG. 29 is a schematic diagram of a display apparatus according to at least one embodiment of the present disclosure. In some examples, as shown in FIG. 29, this embodiment provides a display apparatus 91, including the display substrate 910 in the aforementioned embodiments. In some examples, the display substrate 910 may include an OLED display substrate, a QLED display substrate, a Micro-LED display substrate, or a Mini-LED display substrate. The display apparatus 91 may be any product or component with a display function, such as a mobile phone, a tablet computer, a television, a display, a laptop computer, a digital photo frame, and a navigator. However, the embodiment is not limited thereto.

The drawings of the present disclosure only involve structures involved in the present disclosure, and other structures may refer to conventional designs. The embodiments of the present disclosure and features in the embodiments may be combined to each other to obtain new embodiments if there is no conflict. Those of ordinary skills in the art should understand that modifications or equivalent replacements may be made to the technical solutions of the present disclosure without departing from the essence and scope of the technical solutions of the present disclosure, and shall all fall within the scope of the claims of the present disclosure.

1. A display substrate, comprising:
a base substrate and a drive circuit layer provided on the base substrate, the drive circuit layer at least comprising a plurality of circuit units, at least one circuit unit of the plurality of circuit units comprising a pixel circuit which at least comprises a first transistor, a second transistor, a third transistor, a fourth transistor and a first capacitor;
wherein a gate electrode of the first transistor is electrically connected to a first scan signal line, a first electrode of the first transistor is electrically connected to a first initial signal line, and a second electrode of the first transistor is electrically connected to a gate electrode of the third transistor; a gate electrode of the second transistor is electrically connected to a second scan signal line, a first electrode of the second transistor is electrically connected to the gate electrode of the third transistor, and a second electrode of the second transistor is electrically connected to a second electrode of the third transistor; a gate electrode of the fourth transistor is electrically connected to a third scan signal line, a first electrode of the fourth transistor is electrically connected to a data signal line, and a second electrode of the fourth transistor is electrically connected to a second end of the first capacitor; a first end of the first capacitor is electrically connected to the gate electrode of the third transistor;
the first initial signal line, the first scan signal line, and the second scan signal line extend in at least partially a same direction and are located at a same side of the first transistor, and the first initial signal line is located between the first scan signal line and the second scan signal line.

2. The display substrate according to claim 1, wherein the first initial signal line, the first scan signal line, and the second scan signal line are disposed in a same layer.

3. The display substrate according to claim 1, wherein an active layer of the first transistor comprises a first region, a second region, and a channel region located between the first region and the second region, the first region of the active layer of the first transistor is connected to the first initial signal line; and
the drive circuit layer further comprises: at least one first power supply line; an orthographic projection of the at least one first power supply line on the base substrate covers an orthographic projection of the first region of the active layer of the first transistor on the base substrate.

4. The display substrate according to 1, wherein the pixel circuit further comprises a second capacitor; the second capacitor at least comprises a second plate as a second end of the second capacitor and a fourth plate as a first end of the second capacitor, an orthographic projection of the second plate on the base substrate overlaps at least partially with an orthographic projection of the fourth plate on the base substrate;
the first capacitor at least comprises a first plate as the first end of the first capacitor and a third plate as a second end of the first capacitor, an orthographic projection of the first plate on the base substrate overlaps at least partially with an orthographic projection of the third plate on the base substrate; and
the fourth plate is connected to a first power supply line, the second plate is connected to the third plate, and the first plate is used as the gate electrode of the third transistor.

5. The display substrate according to claim 4, wherein the first plate and the second plate are disposed in a same layer, and the third plate and the fourth plate are disposed in a same layer.

6. The display substrate according to claim 5, wherein the third plate is provided with a second plate connection line extending towards the fourth plate, and the fourth plate is provided with a second groove recessed in a direction away from the third plate; the second plate connection line is provided in the second groove, and an end portion of the second plate connection line away from the third plate is connected to the second plate through a via and a connection electrode.

7. The display substrate according to claim 6, wherein the drive circuit layer further comprises at least one first power supply connection line extending in a first direction, and at least one first power supply line extending in a second direction, the first direction intersects the second direction; the at least one first power supply line is connected to the at least one first power supply connection line to form a mesh structure for transmitting a first power supply signal.

8. The display substrate according to claim 7, wherein the drive circuit layer further comprises at least one second power supply connection line extending in the first direction, and at least one second power supply line extending in the second direction, the first direction intersects the second direction; the at least one second power supply line is connected to the at least one second power supply connection line to form a mesh structure for transmitting a second power supply signal; the at least one second power supply connection line is located at a side of the at least one first power supply connection line away from the second capacitor.

9. The display substrate according to claim 8, wherein the at least one first power supply connection line and the at least one second power supply connection line are disposed in a same layer, the at least one first power supply line and the at least one second power supply line are disposed in a same layer, and the at least one first power supply line is located at a side of the at least one first power supply connection line away from the base substrate.

10. The display substrate according to claim 4, wherein the first capacitor and the second capacitor are located at a same side of the first transistor and the second transistor, the second capacitor is located at a side of the first capacitor away from the first transistor and the second transistor, and an orthographic projection of the third transistor on the base substrate overlaps at least partially with an orthographic projection of the first capacitor on the base substrate; or
wherein fourth plates of second capacitors of pixel circuits of circuit units adjacent in a first direction are interconnected to form an integral structure; or
wherein the at least one circuit unit further comprises a first shielding electrode, an orthographic projection of the first shielding electrode on the base substrate overlaps at least partially with an orthographic projection of a first active layer between two gate electrodes of the first transistor in the present circuit unit on the base substrate, and also overlaps at least partially with an orthographic projection of a second active layer between two gate electrodes of a second transistor in an adjacent circuit unit on the base substrate.

11. (canceled)

12. (canceled)

13. The display substrate according to claim 10, wherein the first shielding electrode comprises a first shielding end and a second shielding end; an orthographic projection of the first shielding end on the base substrate overlaps at least partially with the orthographic projection of the first active layer between the two gate electrodes of the first transistor in the present circuit unit on the base substrate, the first shielding end is electrically connected to a first power supply line; and
an orthographic projection of the second shielding end on the base substrate overlaps at least partially with the orthographic projection of the second active layer between the two gate electrodes of the second transistor in the adjacent circuit unit on the base substrate, and the second shielding end is electrically connected to the first power supply line; or
wherein the first shielding electrode and the fourth plate of the second capacitor are interconnected to form an integral structure.

14. (canceled)

15. The display substrate according to claim 4, wherein the pixel circuit further comprises a fifth transistor, a gate electrode of the fifth transistor is electrically connected to a first light emitting signal line, a first electrode of the fifth transistor is electrically connected to a first power supply line, and a second electrode of the fifth transistor is electrically connected to a first electrode of the third transistor; the first light emitting signal line is located at a side of the second scan signal line away from the first initial signal line;
or,
wherein the pixel circuit further comprises a ninth transistor; a gate electrode of the ninth transistor is electrically connected to a fifth scan signal line, a first electrode of the ninth transistor is electrically connected to a first reference signal line, and a second electrode of the ninth transistor is electrically connected to the second plate of the second capacitor and the third plate of the first capacitor; the fifth scan signal line and the second scan signal line output a same scan signal;
the fourth transistor and the ninth transistor are located at a side of the second capacitor away from the first capacitor; and
an active layer of the fourth transistor and an active layer of the ninth transistor are interconnected to form an integral structure:
or,
wherein the pixel circuit further comprises a seventh transistor and an eighth transistor; a gate electrode of the seventh transistor is electrically connected to a fourth scan signal line, a first electrode of the seventh transistor is electrically connected to a second initial signal line, and a second electrode of the seventh transistor is electrically connected to a light emitting device; and
a gate electrode of the eighth transistor is electrically connected to the fourth scan signal line, a first electrode of the eighth transistor is electrically connected to a second reference signal line, and a second electrode of the eighth transistor is electrically connected to a first electrode of the third transistor;
or,
wherein in a direction perpendicular to the display substrate, the drive circuit layer comprises a semiconductor layer, a first conductive layer, a second conductive layer, a third conductive layer, and a fourth conductive layer sequentially disposed on the base substrate;
active layers of the first transistor, the second transistor, and the third transistor are located in the semiconductor layer;
gate electrodes of the first transistor, the second transistor, and the third transistor, the first plate, and the second plate are located in the first conductive layer;
the third plate and the fourth plate are located in the second conductive layer; and
the first initial signal line, the first scan signal line, and the second scan signal line are located in the third conductive layer.

16. The display substrate according to claim 15, wherein a film layer where the first light emitting signal line is located is on a side of a film layer where the first initial signal line is located close to the base substrate; or, the first light emitting signal line and the first initial signal line are disposed in a same layer; or
wherein the pixel circuit further comprises a sixth transistor, a gate electrode of the sixth transistor is electrically connected to a second light emitting signal line, a first electrode of the sixth transistor is electrically connected to the second electrode of the third transistor, and a second electrode of the sixth transistor is electrically connected to a light emitting device;
the second light emitting signal line is located at a side of the first light emitting signal line away from the first initial signal line; and
the second light emitting signal line and the first light emitting signal line are disposed in a same layer.

17. (canceled)

18. (canceled)

19. The display substrate according to claim 15, wherein active layers of at least two ninth transistors adjacent in a first direction are connected by a first active connection line into an integral structure.

20. (canceled)

21. (canceled)

22. A display apparatus, comprising the display substrate according to claim 1.

23. A method for manufacturing a display substrate, comprising:
forming a drive circuit layer on a base substrate; wherein the drive circuit layer at least comprises a plurality of circuit units, and at least one circuit unit of the plurality of circuit units comprises a pixel circuit; the pixel circuit at least comprises: a first transistor, a second transistor, a third transistor, a fourth transistor, and a first capacitor; a gate electrode of the first transistor is electrically connected to a first scan signal line, a first electrode of the first transistor is electrically connected to a first initial signal line, and a second electrode of the first transistor is electrically connected to a gate electrode of the third transistor; a gate electrode of the second transistor is electrically connected to a second scan signal line, a first electrode of the second transistor is electrically connected to the gate electrode of the third transistor, and a second electrode of the second transistor is electrically connected to a second electrode of the third transistor; a gate electrode of the fourth transistor is electrically connected to a third scan signal line, a first electrode of the fourth transistor is electrically connected to a data signal line, and a second electrode of the fourth transistor is electrically connected to a second end of the first capacitor; a first end of the first capacitor is electrically connected to the gate electrode of the third transistor; and
the first initial signal line, the first scan signal line, and the second scan signal line extend in at least partially a same direction and are located at a same side of the first transistor, and the first initial signal line is located between the first scan signal line and the second scan signal line.

24. A display substrate, comprising:
a base substrate and a drive circuit layer provided on the base substrate, the drive circuit layer at least comprising a plurality of circuit units, at least one circuit unit of the plurality of circuit units comprising a pixel circuit which at least comprises a first transistor, a second transistor, a third transistor, a fourth transistor and a first capacitor;
wherein a gate electrode of the first transistor is electrically connected to a first scan signal line, a first electrode of the first transistor is electrically connected to a first initial signal line, and a second electrode of the first transistor is electrically connected to a gate electrode of the third transistor; a gate electrode of the second transistor is electrically connected to a second scan signal line, a first electrode of the second transistor is electrically connected to the gate electrode of the third transistor, and a second electrode of the second transistor is electrically connected to a second electrode of the third transistor; a gate electrode of the fourth transistor is electrically connected to a third scan signal line, a first electrode of the fourth transistor is electrically connected to a data signal line, and a second electrode of the fourth transistor is electrically connected to a second end of the first capacitor; a first end of the first capacitor is electrically connected to the gate electrode of the third transistor;
the second transistor is located at a side of the first transistor in a first direction, the third transistor and the fourth transistor are located at a same side of the first transistor and the second transistor in a second direction, and the first direction intersects the second direction;
the first initial signal line, the first scan signal line, and the second scan signal line all extend in the first direction and are located at a side of the first transistor away from the third transistor in the second direction; and
the first initial signal line is located between the first scan signal line and the second scan signal line.

25. The display substrate according to claim 24, wherein an orthographic projection of the first scan signal line on the base substrate partially overlaps with orthographic projections of the gate electrode of the first transistor and the gate electrode of the second transistor on the base substrate;
or,
wherein the pixel circuit further comprises a second capacitor; the second capacitor at least comprises a second plate as a second end of the second capacitor and a fourth plate as a first end of the second capacitor, an orthographic projection of the second plate on the base substrate overlaps at least partially with an orthographic projection of the fourth plate on the base substrate;
the first capacitor at least comprises a first plate as the first end of the first capacitor and a third plate as a second end of the first capacitor, an orthographic projection of the first plate on the base substrate overlaps at least partially with an orthographic projection of the third plate on the base substrate; and
the fourth plate is connected to a first power supply line, the second plate is connected to the third plate, and the first plate is used as the gate electrode of the third transistor;
or,
wherein the at least one circuit unit further comprises a first shielding electrode; the first shielding electrode comprises: a first shielding end and a second shielding end; an orthographic projection of the first shielding end on the base substrate overlaps at least partially with an orthographic projection of a first active layer between two gate electrodes of the first transistor in the present circuit unit on the base substrate; and
an orthographic projection of the second shielding end on the base substrate overlaps at least partially with an orthographic projection of a second active layer between two gate electrodes of a second transistor in an adjacent circuit unit on the base substrate, and both the first shielding end and the second shielding end are electrically connected to a first power supply line;
or,
wherein the pixel circuit further comprises a fifth transistor and a sixth transistor;
a gate electrode of the fifth transistor is electrically connected to a first light emitting signal line, a first electrode of the fifth transistor is electrically connected to a first power supply line, and a second electrode of the fifth transistor is electrically connected to a first electrode of the third transistor;
a gate electrode of the sixth transistor is electrically connected to a second light emitting signal line, a first electrode of the sixth transistor is electrically connected to the second electrode of the third transistor, and a second electrode of the sixth transistor is electrically connected to a light emitting device; and
the first light emitting signal line is located at a side of the second scan signal line in the second direction, and the second light emitting signal line is located at a side of the first light emitting signal line in the second direction.

26. (canceled)

27. The display substrate according to claim 25, wherein the third plate is provided with a second plate connection line extending towards the fourth plate, and the fourth plate is provided with a second groove recessed in a direction away from the third plate; the second plate connection line is provided in the second groove, and an end portion of the second plate connection line away from the third plate is connected to the second plate through a via and a connection electrode.

28. (canceled)

29. (canceled)

30. The display substrate according to claim 25, wherein the first light emitting signal line, the second light emitting signal line, and the first initial signal line are disposed in a same layer.
